(19) United States
(12) Patent Application Publication
(10) Pub. No.: US 2019/0074432 A1
(43) Pub. Date: Mar. 7, 2019

(54) Si-BASED SPINTRONICS DEVICES

(71) Applicant: The Regents of the University of California, Oakland, CA (US)

(72) Inventors: Sandeep Kumar, Riverside, CA (US); Paul C. Lou, Riverside, CA (US); Ravindra Bhardwaj, Riverside, CA (US); Anand Katailiha, Riverside, CA (US)

(21) Appl. No.: 16/120,214

(22) Filed: Aug. 31, 2018

Related U.S. Application Data
(60) Provisional application No. 62/638,836, filed on Mar. 5, 2018.
(60) Provisional application No. 62/633,766, filed on Feb. 22, 2018.
(60) Provisional application No. 62/599,464, filed on Dec. 15, 2017.
(60) Provisional application No. 62/554,915, filed on Sep. 6, 2017.
(60) Provisional application No. 62/552,960, filed on Aug. 31, 2017.

(51) Int. Cl. H01L 43/06; H01L 43/04; H01L 43/10; H01L 43/14

(52) U.S. Cl. CPC H01L 43/065; H01L 43/14; H01L 43/10; H01L 43/04

(57) ABSTRACT

Multi-layer n- and p-type Si thin film structures are presented which are configured with through-thickness strain gradients in order to take advantage of flexoelectric polarization and achieve Rashba SOC at Si interfaces. In freestanding thin films, through-thickness strain gradients can be achieved due to differential thermal expansion. In on-substrate thin films, through-thickness strain gradients can be achieved by use of a thick insulating layer. The residual stress due to the insulating layer will give rise to through-thickness strain gradients as shown in FIG. 1B. The residual stresses can be controlled using layer thickness, deposition parameters and layer material. Examples systems include MgO/(p-Si), Pd/Ni₈₁Fe₁₉/MgO/p-Si, Pd/Ni₈₀Fe₂₀/MgO/n-Si, Pd/Ni₈₀Fe₂₀/MgO/p-Si, and Ni₈₀Fe₂₀/p-Si.

### CROSS-REFERENCE TO RELATED APPLICATIONS

This application claims the benefit of priority of U.S. Provisional Patent Application No. 62/552,960, filed Aug. 31, 2017, entitled “Spin Mediated Thermoelectric Effects in Ni80Fe20/p-Si bilayers,” U.S. Provisional Patent Application No. 62/554,915, filed Sep. 6, 2017, entitled “Spin Seebeck Tunneling Induced Antiferromagnetic Phase Transformation in p-Si,” U.S. Provisional Patent Application No. 62/599,464, filed Dec. 15, 2017, entitled “Interfacial Inverse Spin Hall Effect and Antiferromagnetic Phase Transformation in n-Si,” U.S. Provisional Patent Application No. U.S. Provisional Patent Application No. 62/633,766, filed Feb. 22, 2018, entitled “Generation and Detection of Spin Current in MgO/Si Bilayer,” and U.S. Provisional Patent Application No. 62/638,836, filed Mar. 5, 2018, entitled “Giant Enhancement in Rashba Spin-Seebeck Effect in NiFe/p-Si.” The entirety of each of these applications is incorporated by reference.

### STATEMENT OF GOVERNMENT SUPPORT

This invention was made with government support under Contract No. 1550986 awarded by the National Science Foundation. The government has certain rights in the invention.

### BACKGROUND

Angular momentum is a fundamental property of motion. For elementary particles such as electrons, the total angular momentum is given by the sum of orbital angular momentum and spin angular momentum. Orbital angular momentum arises from the orbit of the electron about a nucleus. Spin angular momentum, also referred to as spin, is the remaining angular momentum of the electron not associated with orbital motion of the electron. Spin can be likened to a vector quantity, with a direction and a quantized magnitude given by n/2, where n is a non-negative integer.

Spintronics is the study of the spin of electrons and its associated magnetic moment in solid state devices, amongst other properties, and involves manipulation of spins by magnetic and electrical fields. There exists an ongoing need for improved systems and methods for manipulating spin in solid state devices.

### SUMMARY

In an embodiment, a device is provided. The device can include a doped silicon layer. The device can also include a magnesium oxide (MgO) layer positioned upon the doped silicon layer. A strain gradient can be present in the doped silicon layer in a thickness direction such that a structural inversion asymmetry is present within a portion of the doped silicon layer adjacent to the MgO/doped silicon interface.

In another embodiment, a thickness of the MgO layer relative to the doped silicon layer can be configured to induce at least a portion of the strain gradient within the doped silicon layer.

In another embodiment, the doped silicon layer is n-type silicon.

In another embodiment, the doped silicon layer is p-type silicon.

In another embodiment, the doped silicon layer has a thickness selected from 2 nm to 3 μm.

In another embodiment, the MgO layer has a non-zero thickness less than 2 nm.

In another embodiment, a portion of the doped silicon layer and the magnesium oxide layer is freestanding.

In one embodiment, a device is provided. The device can include a doped silicon layer. The device can further include a magnesium oxide (MgO) layer positioned upon the doped silicon layer. The device can additionally include a Ni₈₀₊ₓFe₂₀₋ₓ layer positioned upon the MgO layer, where x is 0 or 1. A strain gradient can be present in the doped silicon layer in a thickness direction such that a structural inversion asymmetry is present within the portion of the doped silicon layer adjacent to the MgO/doped silicon interface.

In another embodiment, the device includes a heating layer overlying the Ni₈₀₊ₓFe₂₀₋ₓ layer.

In another embodiment, a temperature gradient extends through the thickness of the doped silicon layer, the temperature gradient being configured to induce at least a portion of the strain gradient within the doped silicon layer.

In another embodiment, a thickness of the MgO layer relative to the doped silicon layer is configured to induce at least a portion of the strain gradient within the doped silicon layer.

In another embodiment, the doped silicon layer is configured to undergo a second order phase transformation at a temperature between 200 K and 400 K.

In another embodiment, the second order phase transformation is a metal insulator transition.

In another embodiment, the doped silicon layer is n-type silicon.

In another embodiment, the doped silicon layer is p-type silicon.

In another embodiment, a portion of the doped silicon layer and the magnesium oxide layer is freestanding.

In an embodiment, a device is provided. The device can include a doped polysilicon layer. The device can further include a layer of NiFe or Ni₈₀Fe₂₀ positioned upon the doped polysilicon layer. The device can additionally include an insulating layer positioned upon the NiFe or Ni₈₀Fe₂₀ layer. A strain gradient can be present in the doped polysilicon layer in a thickness direction such that a structural inversion asymmetry is present within the portion of the doped polysilicon layer adjacent to the NiFe/p-Si interface or the Ni₈₀Fe₂₀/p-Si interface.

In another embodiment, the device further includes heating layer overlying the MgO layer.

In another embodiment, a temperature gradient extends through the thickness of the doped polysilicon layer, the temperature gradient being configured to induce at least a portion of the strain gradient within the doped polysilicon layer.

In another embodiment, the doped polysilicon layer is p-type.

### DESCRIPTION OF THE DRAWINGS

FIG. 1A is a diagram illustrating one exemplary embodiment of a freestanding multilayer Si thin film device exhibiting a strain gradient mediated flexoelectric polarization;

FIG. 1B is a diagram illustrating one exemplary embodiment of an on-substrate multilayer Si thin film exhibiting a strain gradient due to residual stress in an insulating layer (e.g., MgO);

FIG. 2A is a diagram illustrating hypothetical spin accumulation;

FIG. 2B is a diagram illustrating one exemplary embodiment of a freestanding p-Si thin film;

FIG. 2C is a plot of temperature dependent non-local resistance across J4 and J2 which electrical current is applied across J3 in the p-Si thin film of FIG. 2B;

FIG. 2D is a plot of temperature dependent longitudinal resistance of the p-Si thin film of FIG. 2B;

FIG. 3 is a diagram illustrating an MgO/Si thin film device;

FIG. 4A is a plot of non-local resistance as a function of temperature for applied current across J1 of the MgO/p-Si thin film device of FIG. 3;

FIG. 4B is a plot of non-local resistance as a function of temperature for applied current across J2 of the MgO/p-Si thin film device;

FIG. 4C is a plot of non-local resistance as a function of temperature for applied current across J3 of the MgO/p-Si thin film device;

FIG. 4D is a plot of non-local resistance as a function of temperature for applied current across J4 of the MgO/p-Si thin film device;

FIG. 5 is a plot of non-local resistance as a function of temperature for applied current across J3 of the MgO/p-Si thin film device;

FIG. 6 is a plot of longitudinal resistance (R_{L}) and transverse resistance (R_{T}) of the MgO/p-Si thin film device as a function of temperature; (inset) transverse resistance (ΔR_{T}) after subtraction of longitudinal contribution (ΔR_{T}) as a function of temperature;

FIG. 7 is a plot of transverse resistance as a function of magnetic field in the MgO/p-Si thin film device;

FIG. 8A is a plot of non-local resistance as a function of transverse in-plane magnetic field (y-direction) at J2 of the MgO/p-Si thin film device;

FIG. 8B is a plot of non-local resistance as a function of transverse in-plane magnetic field (y-direction) at J3 of the MgO/p-Si thin film device;

FIG. 8C is a plot of non-local resistance as a function of transverse out-of-plane magnetic field (z-direction) at J2 of the MgO/p-Si thin film device;

FIG. 8D is a plot of non-local resistance as a function of transverse out-of-plane magnetic field (z-direction) at J3 of the MgO/p-Si thin film device;

FIG. 9A is an X-Ray photoemission spectroscopy (XPS) spectrum of the MgO/p-Si thin film device illustrating intensity as a function of binding energy corresponding to Si₂ₚ;

FIG. 9B is an X-Ray photoemission spectroscopy (XPS) spectrum of the MgO/p-Si thin film device illustrating intensity as a function of binding energy corresponding to Mg₂ₚ;

FIG. 9C is an X-Ray photoemission spectroscopy (XPS) spectrum of the MgO/p-Si thin film device illustrating intensity as a function of binding energy corresponding to Mg₁ₛ;

FIG. 10A is a plot of longitudinal resistance (R_{L}) and transverse resistance (R_{T}) as a function of temperature for an MgO/n-Si thin film device according to FIG. 3;

FIG. 10B is a plot of non-local resistance (R_{NL}) as a function of temperature for applied current across J1 of the MgO/n-Si thin film device;

FIG. 11 is a plot of transverse resistance (R_{T}) as a function of temperature for another MgO/n-Si thin film device;

FIG. 12A is a schematic diagram illustrating proposed intrinsic spin transport behavior and spin-charge conversion at an MgO/Si interface;

FIG. 12B is a schematic diagram illustrating an MgO/Si interface responsible for efficient spin-to-charge conversion;

FIG. 12C is a schematic diagram illustrating the inverse spin Hall effect (ISHE) occurring at an MgO/Si interface resulting in observed transverse resistance;

FIG. 13 is a false color micrograph illustrating one exemplary embodiment of a freestanding Pd/Ni₈₁Fe₁₉/MgO/p-Si thin film device;

FIGS. 14A-14J are schematic illustrations of a process for fabricating the Pd/Ni₈₁Fe₁₉/MgO/p-Si thin film device of FIG. 13;

FIG. 15A is a plot of ΔR/R as a function of magnetic field at various temperatures between 5 K and 300 K illustrating magnetoresistance behavior of the Pd/Ni₈₁Fe₁₉/MgO/p-Si thin film device;

FIG. 15B is a plot of V_{2ω} as a function of magnetic field at various temperatures between 5 K and 300 K for the Pd/Ni₈₁Fe₁₉/MgO/p-Si thin film device;

FIG. 15C is a plot of V_{3ω} as a function of magnetic field at various temperatures between 5 K and 300 K for the Pd/Ni₈₁Fe₁₉/MgO/p-Si thin film device;

FIG. 16 is a plot of magnetoresistance as a function of magnetic field at various temperatures between 50 K and 300 K for the Pd/Ni₈₁Fe₁₉/MgO/p-Si thin film device;

FIG. 17 is a plot of V_{2ω} as a function of current for the Pd/Ni₈₁Fe₁₉/MgO/p-Si thin film device;

FIG. 18A is a plot of resistance (R_{DC}) as a function of temperature for the Pd/Ni₈₁Fe₁₉/MgO/p-Si thin film device;

FIG. 18B is a plot of V_{3ω} a as a function of temperature for the Pd/Ni₈₁Fe₁₉/MgO/p-Si thin film device;

FIG. 18C is a plot of

$$\frac{R}{{V}_{3 ω}}$$

as a function of temperature for the Pd/Ni₈₁Fe₁₉/MgO/p-Si thin film device;

FIG. 18D is a plot of R_{1ω} as a function of temperature for the Pd/Ni₈₁Fe₁₉/MgO/p-Si thin film device;

FIG. 19A is a plot of V_{2ω} as a function of temperature under zero applied magnetic field for the Pd/Ni₈₁Fe₁₉/MgO/p-Si thin film device; Arrows show the direction of temperature change;

FIG. 19B is a plot of V_{2ω} as a function of temperature under an out-of-plane 14T applied magnetic field for the Pd/Ni₈₁Fe₁₉/MgO/p-Si thin film device; Arrows show the direction of temperature change;

FIG. 19C is a plot of V_{3ω} as a function of temperature under an out-of-plane 14T applied magnetic field for the Pd/Ni₈₁Fe₁₉/MgO/p-Si thin film device; Arrows show the direction of temperature change;

FIG. 20A is a plot of longitudinal resistance as a function of temperature for a p-Si control specimen;

FIG. 20B is a plot of longitudinal resistance as a function of temperature for an Ni₈₁Fe₁₉ control specimen;

FIG. 21A is a plot of resistance (R_{1ω}) as a function of temperature for a second Pd/Ni₈₁Fe₁₉/MgO/p-Si thin film device;

FIG. 21B is a plot of V2ω as a function of temperature for the second Pd/Ni₈₁Fe₁₉/MgO/p-Si thin film device;

FIG. 21C is a plot of V_{3ω} as a function of temperature for the second Pd/Ni₈₁Fe₁₉/MgO/p-Si thin film device;

FIG. 21D is a plot of

$$\frac{R}{{V}_{3 ω}}$$

as a function of temperature for the second Pd/Ni₈₁Fe₁₉/MgO/p-Si thin film device;

FIG. 22A is a plot of resistance (R_{1ω}) as a function of temperature at different applied currents for an embodiment of the Pd/Ni₈₁Fe₁₉/MgO/p-Si thin film device;

FIG. 22B is a plot of V_{3ω} as a function of temperature at different applied currents for an embodiment of the Pd/Ni₈₁Fe₁₉/MgO/p-Si thin film device;

FIG. 22C is a plot of

$$\frac{R}{{V}_{3 ω}}$$

as a function of temperature at different applied currents for an embodiment of the Pd/Ni₈₁Fe₁₉/MgO/p-Si thin film device;

FIG. 22D is a plot of V_{2ω} as a function of temperature at different applied currents for an embodiment of the Pd/Ni₈₁Fe₁₉/MgO/p-Si thin film device;

FIG. 23A is a plot of angular field rotation in xy, zx, and zy planes illustrating spin Hall magnetoresistance (SMR) behavior for an embodiment of the Pd/Ni₈₁Fe₁₉/MgO/p-Si thin film device;

FIG. 23B is a plot of Hall resistance at 350 K and 200 K for an out-of-plane magnetic field (zx plane) for an embodiment of the Pd/Ni₈₁Fe₁₉/MgO/p-Si thin film device;

FIG. 24A is a plot of resistance R_{1ω} as a function of angular field rotation in the zy-plane at 350 K for an embodiment of the Pd/Ni₈₁Fe₁₉/MgO/p-Si thin film device;

FIG. 24B is a plot of resistance R_{1ω} as a function of angular field rotation in the zy-plane at 200 K for an embodiment of the Pd/Ni₈₁Fe₁₉/MgO/p-Si thin film device;

FIG. 24C is a plot of V_{2ω} response as a function of angular field rotation in the zy-plane at 350 K for an embodiment of the Pd/Ni₈₁Fe₁₉/MgO/p-Si thin film device;

FIG. 24D is a plot of V_{2ω} response as a function of angular field rotation in the zy-plane at 200 K for an embodiment of the Pd/Ni₈₁Fe₁₉/MgO/p-Si thin film device;

FIG. 25A is a schematic diagram illustrating SMR behavior due to intrinsic SHE and Rashba SOC;

FIG. 25B is a schematic diagram illustrating one exemplary embodiment of a proposed mechanism for observed emergent anti-ferromagnetic behavior;

FIG. 26A is a plot of magnetic moment as a function of temperature at an applied magnetic field of 20 Oe for an embodiment of the Pd/Ni₈₁Fe₁₉/MgO/p-Si thin film device;

FIG. 26B is a plot of magnetic hysteresis as a function of magnetic field at temperatures of 300 K, 178 K, and 5 K for an embodiment of the Pd/Ni₈₁Fe₁₉/MgO/p-Si thin film device;

FIG. 27A is a schematic diagram illustrating one exemplary embodiment of a proposed mechanism for emergent anti-ferromagnetic behavior;

FIG. 27B is a schematic diagram illustrating one exemplary embodiment of a freestanding Pd/Ni₈₀Fe₂₀/MgO/n-Si thin film device;

FIG. 28A is a plot of electrical resistance (R_{1ω}) as a function of temperature for an embodiment of the Pd/Ni₈₀Fe₂₀/MgO/n-Si thin film device and a p-Si control sample;

FIG. 28B is a plot of V_{3ω} response as a function of temperature for an embodiment of the Pd/Ni₈₀Fe₂₀/MgO/n-Si thin film device and a p-Si control sample;

FIG. 28C is a plot of V_{2ω} response as a function of temperature for an embodiment of the Pd/Ni₈₀Fe₂₀/MgO/n-Si thin film device and a p-Si control sample;

FIG. 28D is a plot of

$$\frac{{R}_{1 ω}}{{V}_{3 ω}}$$

response as a function of temperature for an embodiment of the Pd/Ni₈₀Fe₂₀/MgO/n-Si thin film device and a p-Si control sample;

FIG. 29A is a plot of magnetoresistance (MR) as a function of applied magnetic field at temperatures ranging from 5 K to 300 K for an embodiment of the Pd/Ni₈₀Fe₂₀/MgO/n-Si thin film device;

FIG. 29B is a plot of V_{2ω} response as a function of applied magnetic field at temperatures ranging from 5 K to 300 K for an embodiment of the Pd/Ni₈₀Fe₂₀/MgO/n-Si thin film device;

FIG. 29C is a plot of V_{3ω} response as a function of applied magnetic field at temperatures ranging from 5 K to 300 K for an embodiment of the Pd/Ni₈₀Fe₂₀/MgO/n-Si thin film device;

FIG. 30A is a plot of magnetoresistance (MR) for an applied magnetic field rotated in the yz-plane at temperatures ranging from 5 K to 300 K for an embodiment of the Pd/Ni₈₀Fe₂₀/MgO/n-Si thin film device;

FIG. 30B is a plot of V_{2ω} response for an applied magnetic field rotated in the yz-plane at temperatures ranging from 5 K to 300 K for an embodiment of the Pd/Ni₈₀Fe₂₀/MgO/n-Si thin film device;

FIG. 30C is a plot of V_{3ω} response for an applied magnetic field rotated in the yz-plane at temperatures ranging from 5 K to 300 K for an embodiment of the Pd/Ni₈₀Fe₂₀/MgO/n-Si thin film device;

FIG. 31A is a false color micrograph illustrating one exemplary embodiment of a freestanding Pd/Ni₈₀Fe₂₀/MgO/p-Si thin film device;

FIG. 31B is a schematic diagram illustrating a proposed mechanism for strain-mediated Rashba spin-orbit coupling (SOC);

FIG. 31C is a schematic diagram illustrating angular rotation for SMR measurement;

FIG. 32A is a plot of magnetoresistance (MR) as a function of angle in the zy-plane at different applied currents for an embodiment of the Pd/Ni₈₀Fe₂₀/MgO/p-Si thin film device;

FIG. 32B is a plot of magnetoresistance (MR) as a function of angle in the zy-plane at different applied fields for an embodiment of the Pd/Ni₈₀Fe₂₀/MgO/p-Si thin film device;

FIG. 32C is a plot of magnetoresistance (MR) as a function of angle in the zy-plane at a constant temperature of 200 K and different applied fields for an embodiment of the Pd/Ni₈₀Fe₂₀/MgO/p-Si thin film device;

FIG. 33A is a plot of magnetoresistance (MR) as a function of current in the zy-plane at a constant temperature of 300 K for an embodiment of the Pd/Ni₈₀Fe₂₀/MgO/p-Si thin film device;

FIG. 33B is a plot of transverse magnetoresistance (R_{xy}) as a function of applied magnetic field and current from 0.5 mA to 10 mA a constant temperature of 300 K for an embodiment of the Pd/Ni₈₀Fe₂₀/MgO/p-Si thin film device;

FIG. 33C is a plot of magnetoresistance (MR) as a function of current for an embodiment of the Pd/Ni₈₀Fe₂₀/MgO/p-Si thin film device;

FIG. 34 is a plot of magnetoresistance (MR) as a function of angular rotation in the zy-plane at a constant temperature of 300 K for an embodiment of a 25 nm Ni₈₀Fe₂₀ control specimen;

FIG. 35 is a plot of transverse magnetoresistance (R_{xy}) as a function of angular rotation in the zy-plane at a constant temperature of 375 K for an embodiment of the Pd/Ni₈₀Fe₂₀/MgO/p-Si thin film device;

FIG. 36 is a plot of magnetoresistance (MR) as a function of applied out of plane magnetic field for current applied along <110> direction or along the flat of the Si(100) wafer (15° to the <110> direction, at 30° to the <110> direction, and along the <100>direction). Arrows indicate saturation magnetization and possible canted states and its transition;

FIG. 37A is a plot of resistance (R_{1ω}) as a function of temperature for an embodiment of the Pd/Ni₈₀Fe₂₀/MgO/p-Si thin film device;

FIG. 37B is a plot of V_{3ω} response as a function of temperature for an embodiment of the Pd/Ni₈₀Fe₂₀/MgO/p-Si thin film device;

FIG. 37C is a plot of

$$\frac{R}{{V}_{3 ω}}$$

response as a function of temperature for an embodiment of the Pd/Ni₈₀Fe₂₀/MgO/p-Si thin film device;

FIG. 37D is a plot of magnetic moment as a function of magnetic field illustrating magnetic hysteresis behavior at 5 K showing a possible bias behavior for another embodiment of the Pd/Ni₈₀Fe₂₀/MgO/p-Si thin film device;

FIG. 38A is a schematic illustration of an experimental setup for measurement of longitudinal spin Seebeck effect (LSSE);

FIG. 38B is a false color micrograph illustrating one exemplary embodiment of an on-substrate Ni₈₀Fe₂₀/p-Si (poly) bilayer device;

FIG. 39A is a plot of second harmonic response V2ω as a function of applied magnetic field in transverse in-plane (y-direction) and out-of-plane (z-direction) for the Ni₈₀Fe₂₀/p-Si (poly) bilayer device;

FIG. 39B is a plot of V2ω response as a function of heating power for constant applied magnetic field of 1000 Oe in the z-direction and at constant temperature of 400 K for the Ni₈₀Fe₂₀/p-Si (poly) bilayer device;

FIG. 40A is a plot of V_{2ω} response as a function of applied magnetic field in transverse in-plane (y-direction) and out-of-plane (z-direction) at a constant temperature of 300 K and heating current of 15 mA for the Ni₈₀Fe₂₀/p-Si (poly) bilayer device; Arrows show the direction of magnetic field sweep;

FIG. 40B is a plot of V_{2ω} response as a function of applied magnetic field in transverse in-plane (y-direction) and out-of-plane (z-direction) at a constant temperature of 300 K and heating current of 20 mA for the Ni₈₀Fe₂₀/p-Si (poly) bilayer device; Arrows show the direction of magnetic field sweep;

FIG. 40C is a plot of V_{2ω} response as a function of applied magnetic field in transverse in-plane (y-direction) and out-of-plane (z-direction) at a constant temperature of 300 K and heating current of 30 mA for the Ni₈₀Fe₂₀/p-Si (poly) bilayer device; Arrows show the direction of magnetic field sweep;

FIG. 40D is a plot of V_{2ω} response as a function of applied magnetic field in transverse in-plane (y-direction) and out-of-plane (z-direction) at a constant temperature of 300 K and heating current of 50 mA for the Ni₈₀Fe₂₀/p-Si (poly) bilayer device; Arrows show the direction of magnetic field sweep;

FIG. 41A is a plot of V_{2ω} response as a function of angular rotation at a constant applied magnetic field in the yz-plane for the Ni₈₀Fe₂₀/p-Si (poly) bilayer device;

FIG. 41B is a plot of V2ω response as a function of temperature from 10 K to 400 K at applied magnetic fields of 1000 Oe and IT for a second Ni₈₀Fe₂₀/p-Si (poly) bilayer device;

FIG. 41C is a plot of V_{2ω} response as a function of applied magnetic field at temperatures of 20 K, 100 K, and 200 K for a second Ni₈₀Fe₂₀/p-Si (poly) bilayer device;

FIG. 42 is a plot of resistance (R_{1ω}) and third harmonic response V_{3ω} as a function of temperature from 10 K to 300 K;

FIG. 43A is a diagram illustrating the temperature gradient between the heater and the substrate predicted by the COMSOL model for the Ni₈₀Fe₂₀/p-Si (poly) bilayer device;

FIG. 43B is a diagram illustrating the temperature gradient across the layered structure predicted by the COMSOL model at 20 mA heating current for the Ni₈₀Fe₂₀/p-Si (poly) bilayer device;

FIG. 44A is a schematic diagram illustrating hole accumulation and two-dimensional hole gas (2DHG) at a metal-semiconductor interface (Ni₈₀Fe₂₀/p-Si (poly));

FIG. 44B is a schematic diagram illustrating one exemplary embodiment of a proposed mechanism of observed spin Seebeck effect (SSE);

FIG. 44C is a schematic diagram illustrating one exemplary embodiment of a proposed mechanism of observed tunneling spin galvanic effect (TGSE);

FIG. 45A is a schematic illustration of an experimental setup for measurement of longitudinal spin Seebeck effect (LSSE);

FIG. 45B is a false color micrograph illustrating another exemplary embodiment of an on-substrate Ni₈₀Fe₂₀/p-Si (poly) bilayer device;

FIG. 45C is a plot of V_{2ω} response as a function of heating current at an applied magnetic field of 1500 Oe for the Ni₈₀Fe₂₀/p-Si (poly) bilayer device of FIGS. 45A-45B;

FIG. 46A is a plot of V_{2ω} response as a function of magnetic field applied along the y-direction at 10 K, 100 K, 300 K for the Ni₈₀Fe₂₀/p-Si (poly) bilayer device of FIGS. 45A-45B having 100 nm layer thickness;

FIG. 46B is a plot of V_{2ω} response as a function of magnetic field applied along the y-direction at 10 K, 100 K, 300 K for the Ni₈₀Fe₂₀/p-Si (poly) bilayer device of FIGS. 45A-45B having 25 nm layer thickness;

FIG. 46C is a plot of V_{2ω} response as a function of magnetic field applied along the y-direction at 10 K, 100 K, 300 K for the Ni₈₀Fe₂₀/p-Si (poly) bilayer device of FIGS. 45A-4B having 5 nm layer thickness;

FIG. 47A is a plot of V_{2ω} response as a function of temperature from 5 K to 350 K for the Ni₈₀Fe₂₀/p-Si (poly) bilayer device of FIGS. 45A-45B having 5 nm, 25 nm, and 100 nm p-Si layer thickness;

FIG. 47B is a plot of V_{2ω} response as a function of angular dependence in the yx-plane at an applied magnetic field of 2T for the Ni₈₀Fe₂₀/p-Si (poly) bilayer device of FIGS. 45A-45B having 5 nm, 25 nm, and 100 nm p-Si layer thickness;

FIG. 47 is a plot of calculated spin-Seebeck coefficient as a function of thickness; and

FIG. 48 is a schematic diagram illustrating one exemplary embodiment of the mechanism of observed Rashba SSE behavior.

### DETAILED DESCRIPTION

Orbital and spin angular momentum of an electron are each associated with a magnetic moment and can interact with one another through these magnetic moments. This interaction is referred to as spin orbit coupling or SOC.

Rashba spin orbit coupling (Rashba SOC) arises in materials and interfaces due to lack of inversion symmetry. Rashba SOC can give rise to emergent phenomena at the interfaces [6-1, 6-2]. These phenomena include intrinsic spin-Hall effect [6-3], quantum spin-Hall effect [6-4], superconductivity and topological insulators [6-5, 6-6, 6-7, 6-8]. The Rashba SOC provides an efficient mechanism to manipulate the spin transport and can lead to efficient spin to charge conversion, as compared to intrinsic SOC, which are essential for energy efficient spintronics devices [6-9].

In addition to structural inversion asymmetry, Rashba SOC requires elements with strong intrinsic SOC. This has led to research in Rashba SOC being restricted to heavy and rare earth element materials and interfaces [6-9, 6-10]. Observation of bulk Rashba SOC [6-11, 6-12, 6-13] has been reported recently but it is still considered to exist primarily in two-dimensional electron gas systems (2DES).

Silicon is the pre-eminent material in semiconductor electronics and is optically shown to exhibit Rashba SOC in a Bi/Si (111) interface with Rashba energy larger than any other semiconductor heterostructures [6-14, 6-15]. The Rashba SOC in Si metal oxide semiconductor field effect transistors (MOSFET) has been reported using magneto-transport behavior [6-16, 6-17, 6-18, 6-19] and using spin resonance measurements [6-20]. Rashba SOC has also been reported in Si quantum dots at SiO₂/Si interface. The inverse spin-Hall effect (ISHE) is also demonstrated in Si by ferromagnetic resonance, with reported spin-Hall angle of 0.0001 for p-Si [6-21].

These results indicate potential to implement Si-based spintronics using Rashba SOC. The Rashba SOC in Si promises a bright future for spintronics devices, since the cumulative understanding of 2DES at Si interfaces due to semiconductor electronics research can provide a wealth of knowledge to manipulate spin transport behavior for device applications.

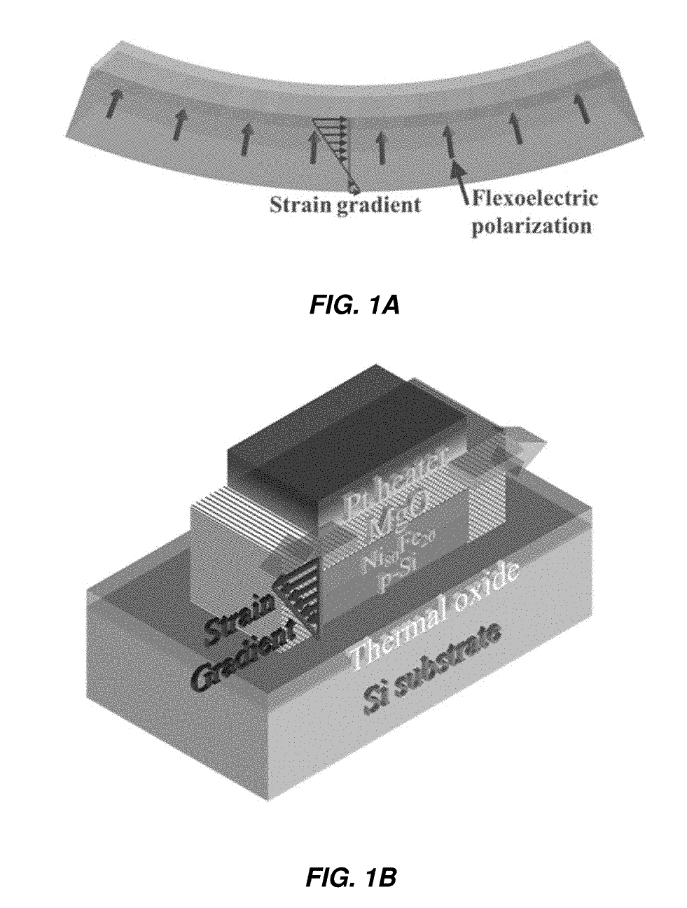

Rashba SOC can arise due to flexoelectric polarization caused by strain gradients. Flexoelectric polarization is a property of dielectric materials which results in spontaneous electrical polarization induced by strain gradient. As discussed in detail below, multi-layer Si thin film structures are presented which are configured with through-thickness strain gradients in order to take advantage of flexoelectric polarization and achieve Rashba SOC at Si interfaces. In freestanding thin films, through-thickness strain gradients can be achieved due to differential thermal expansion, as shown in FIG. 1A. In on-substrate thin films, through-thickness strain gradients can be achieved by use of a thick insulating layer (e.g., MgO). The residual stress due to the insulating layer will give rise to through-thickness strain gradients as shown in FIG. 1B. The residual stresses can be controlled using layer thickness, deposition parameters and layer material. In principle, other thin films having a large residual stress (e.g., silicon nitride) can also be used to enhance the strain gradient and in turn Rashba spin-orbit coupling.

Embodiments of different multi-layer Si thin film devices which take advantage of flexoelectric polarization to achieve Rashba SOC at Si interfaces are discussed in detail below.

### Generation and Detection of Dissipationless Spin Current in Si

The generation and detection of spin current without ferromagnetic or exotic/scarce materials are two challenges for spintronics devices. Si is the foundation of modern semiconductor electronics devices and can be a suitable material for spintronics as well.

Spin injection in Si has been experimentally demonstrated by tunneling from a ferromagnetic electrode across a thin insulator [1-1, 1-2, 1-3, 1-4], with spin diffusion length of up to about 6 μm [1-5]. The long spin diffusion length at room temperature makes Si an ideal spin channel (transport) material. The inverse spin-Hall effect (ISHE) has been demonstrated in p-Si [1-6], although the spin-Hall angle is extremely small. The spin-Hall effect (SHE) [1-7, 1-8, 1-9] is considered to be an efficient method for generation of pure spin currents using an electric field. The intrinsic SHE has been proposed to exist in some p-type semiconductors, including GaAs, Ge and Si. This spin current is proposed to be quantum in nature, hence dissipationless [1-10]. SHE has been observed in gallium arsenide (GaAs) using optical detection techniques, Kerr microscopy, and a two-dimensional light-emitting diode [1-11, 1-12].

However, Si is an indirect band-gap semiconductor. As a result, optical methods are not applicable for studying the SHE in Si. In addition, the spin-orbit coupling in Si is very small (e.g., 44 meV), and intrinsic ISHE may not produce a measurable signal. The experimental evidence of the SHE has been reported in p-Si using magneto-thermal transport measurements but the mechanism of SHE is not clearly demonstrated. The long spin diffusion length and SHE of Si satisfy the two requirements of spintronics devices: spin transport and spin current generation. Without a reliable spin detection mechanism, though, Si spintronics may not be practically realizable. In addition, a scientific understanding of the mechanism of the SHE, which has not previously been determined, is essential for manipulation of spin current.

In this embodiment, a solution to the problems of spin current generation and detection in Si is discussed. Using non-local measurement, the generation of dissipationless spin current using spin-Hall effect (SHE) is demonstrated in freestanding thin film devices formed from MgO/Si. Contrary to existing theoretical predictions, the spin Hall effect is observed in both n-doped Si and p-doped Si. Without being bound by theory, the intrinsic SHE is attributed to site-inversion asymmetry in the diamond cubic lattice of Si. It is proposed that site inversion mediated antiferromagnetic interactions lead to dissipationless spin current.

The second challenge addressed herein is detection of spin current, especially for Si spintronics. The spin-to-charge conversion arising from ISHE in Si is insignificant due to weak spin-orbit coupling. For the efficient detection of spin current, spin to charge conversion is investigated at the MgO/Si thin film interface for p-doped Si and n-doped Si. Using x-ray photoemission spectroscopy (XPS), it can be determined that the interface is formed from MgO/Mg/SiO₂. The oxygen deficient interface leads to a two-dimensional electron system. The structure inversion asymmetry at the interface leads to Rashba spin orbit coupling and efficient spin to charge conversion observed in this work. Spin currents are detected at a distance of >100 μm, which is an order of magnitude larger than the longest spin diffusion length measured using spin injection techniques.

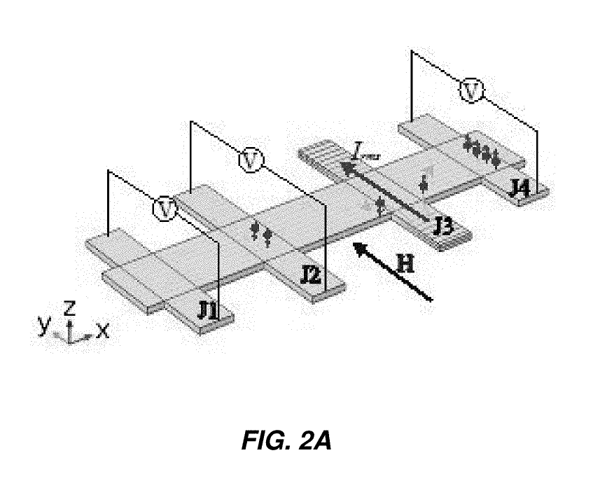

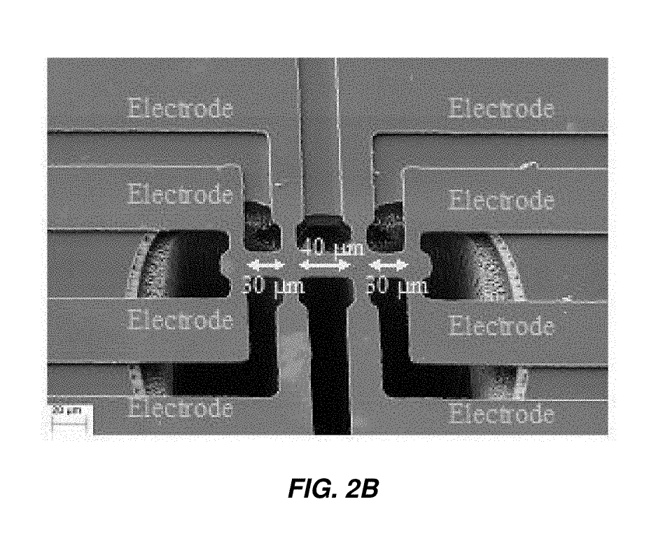

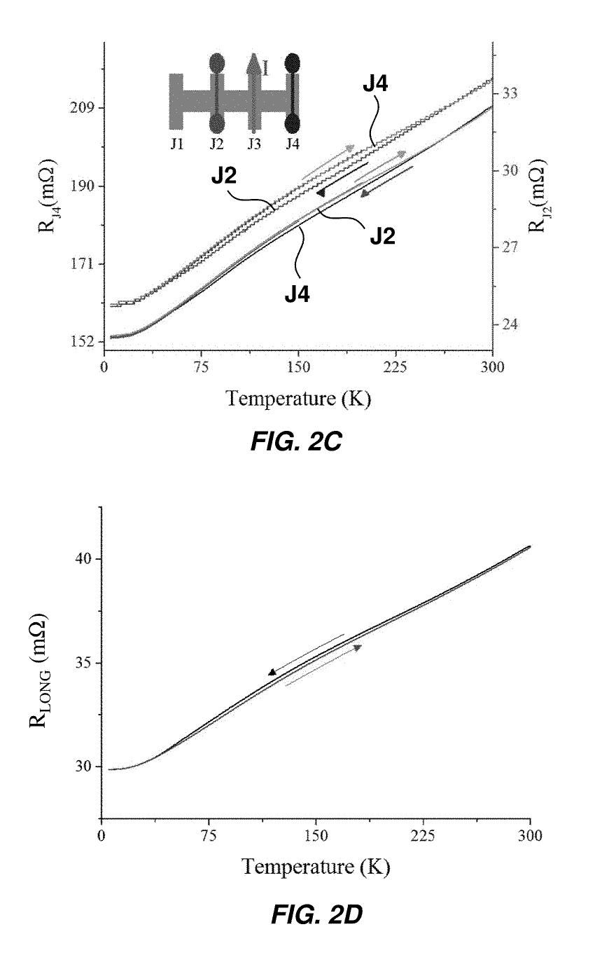

It is hypothesized that the SHE in Si leads to spin accumulation, as shown in FIG. 2A, and that non-local measurement can allow characterization the mechanism of spin current in Si.

To investigate this hypothesis, a freestanding Si device is prepared in the form of a Hall bar MEMS structure. The device is formed on a silicon on insulator (SOI) wafer with electrical resistivity of 0.001 Ωcm to 0.005 Ωcm with a device layer of 2 μm. Using photolithography and deep reactive ion etching (DRIE), the front side (device layer) is patterned with specimen and electrodes. The back side of the wafer is etched underneath the sample area to have the freestanding specimen using DRIE.

As illustrated in FIG. 2B, the thin film device employs a layer of p-Si (0.001-0.005 Ωcm) with a channel width of 20 μm. The specimen is made freestanding to avoid a vertical temperature gradient, which can lead to electric potential due to anomalous Nernst effect (ANE) in case of magneto-transport measurements.

Measurements were carried out inside a Quantum Design physical property measurement system (PPMS). The temperature-dependent, non-local resistance measurement is acquired using a current of 2 mA (37 Hz) applied across J3 and the results are shown in FIG. 2C. The experiment is started at a temperature of 300 K and the specimen is cooled at a rate of 0.3 K/min to 5 K. The data is acquired every 30 sec. Subsequently, the specimen is heated to 150 K at a rate of 0.3 K/min.

It is observed that the non-local resistances while heating do not follow the cooling curve. At 150 K, the temperature is raised to 200 K and cooling is started again to 5 K. The non-local resistances now follow the heating curve and do not join the first cooling curve. After cooling to 5 K, the temperature is raised to 300 K. It is observed that the non-local resistances merge back to the first cooling curve at approximately 250 K.

The spin-phonon interaction is the primary spin relaxation mechanism. Without being bound by theory, it is proposed that the observed thermal hysteretic behavior is due to spin accumulation from pure spin current in p-Si in the absence of spin-phonon relaxation at low temperatures.

To investigate this hypothesis, similar temperature-dependent longitudinal resistance measurements were acquired and are shown in FIG. 2D. A thermal hysteresis is observed in longitudinal resistance as well. However, the thermal hysteresis in longitudinal resistance may be due to temperature lag, since the resistance measured during heating is lower than the resistance measured during cooling. Without being bound by theory, it is proposed that the observed non-local resistance is attributed to spin polarization leading to the thermal hysteresis. However, a clear ISHE behavior is missing due to small spin-orbit coupling.

The electrical measurement of spin-dependent behavior requires an efficient spin to charge conversion, which is absent in pure p-Si. Without being bound by theory, it is hypothesized that Rashba spin orbit coupling due to structure inversion asymmetry (SIA) may allow efficient spin to charge conversion [1-15, 1-16]. To test this hypothesis, a layer of MgO is deposited on the p-Si thin film of FIG. 2B to provide structure inversion asymmetry (SIA) and Rashba spin orbit coupling; the MgO/Si interface is observed to have localized electronic states [1-17].

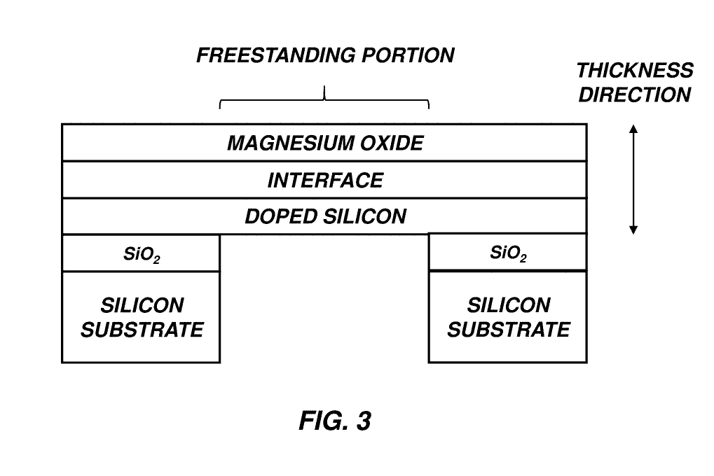

The resultant MgO/Si thin film structure is illustrated in FIG. 3. In certain embodiments, the thickness of the MgO layer can be selected from 1 nm to 50 nm (e.g., a non-zero value less than 2 nm). The thickness of the doped silicon layer can be selected from 2 nm to In one embodiment, the instant device is formed with a doped silicon layer having a thickness of 2μm and an MgO layer having a thickness of 1 nm. The length of the freestanding portion of the MgO/Si thin film structure can be a non-zero value up to 250 μm (e.g., 110 μm). While a doped silicon layer of p-Si is discussed immediately below, other embodiments of the MgO/Si thin film structure can employ a doped silicon layer in the form of n-Si, rather than p-Si. The thickness of the MgO layer relative to the thickness of the doped. Si layer can be selected to induce a strain gradient through the thickness of the MgO/Si thin film device. The strain gradient can be sufficient to promote structural inversion symmetry within the doped Si layer at and/or adjacent to the MgO/doped Si interface.

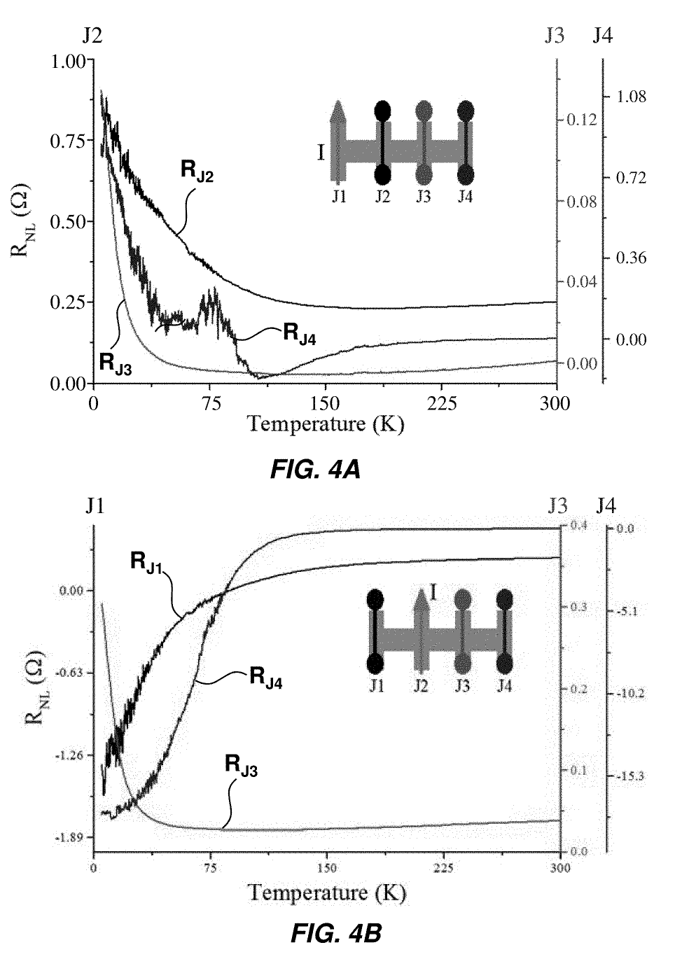

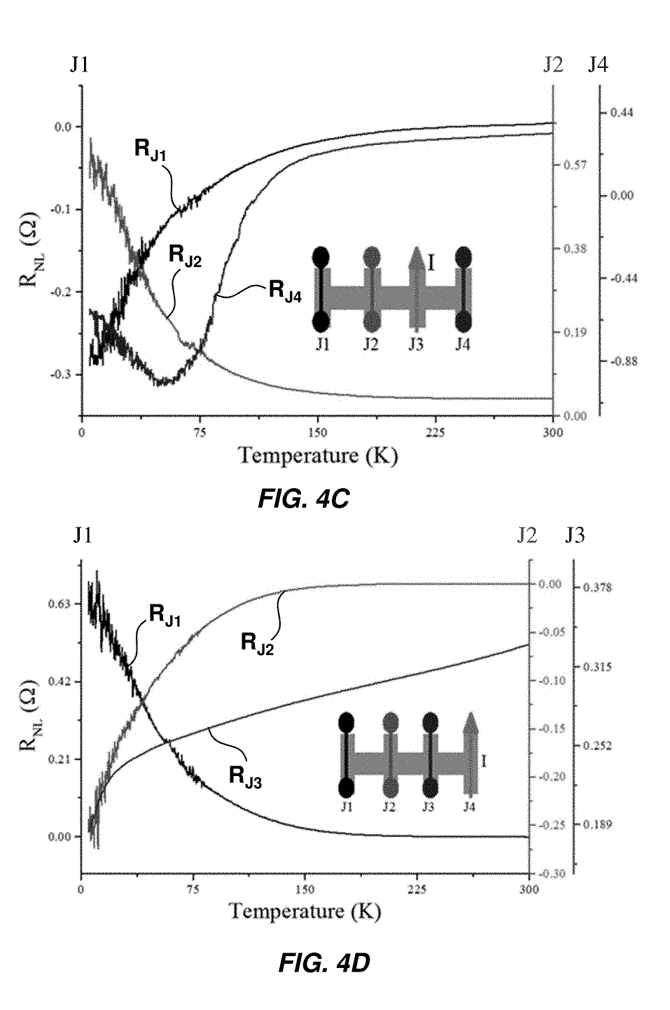

The non-local measurements discussed above are repeated on this MgO/p-Si specimen. First, current is applied across J1 and the non-local resistance is measured across J2, J3, and J4 as a function of temperature, as shown in FIG. 4A. It is observed that the R_{NL} for J2, J3, and J4 increases rapidly as the temperature is reduced from 300 K to 5 K at a rate of 0.4 K/min. Increase in non-local resistances are observed as follows: R_{J2} from 300 mΩ to 870 mΩ, R_{J3} from 30 mΩ to 120 mΩ and R_{J4} from 0.03 mΩ to 1Ω. A diffusive spin current will have the largest values closest to source and will decrease exponentially as a function of distance. Now, J2 is closest and J4 is farthest from the location of applied current. The highest non-local resistance is observed at J4, while the smallest at J3. In addition, the R_{J4} changes the sign twice, going from positive to negative at about 292 K and turning positive again at about 90 K.

Notably at room temperature (300 K), the Ohmic non-local resistances can be calculated from the van der Pauw theorem [1-18], illustrated in Equation 1:

$${R}_{NL} = {R}_{sq} {e}^{\frac{- π L}{w}} \qquad ( Eq . 1 )$$

where

$${R}_{sq} = \frac{ρ}{t} ,$$

ρ is resistivity, t is thickness, L is the channel length, and w is the channel width.

According to this theorem, the Ohmic non-local resistances show an exponential drop as a function of distance at room temperature. With reduction in temperature, non-local resistance increases as opposed to the longitudinal resistance, suggesting an additional contribution, which is attributed to the spin to charge conversion.

Non-local resistances are also measured for current applied across J2, J3 and J4 junctions as shown in FIGS. 4B-4D. When current is applied across J2 (FIG. 4B), it is observed that direction of current changes for J1 and J4. Assuming a diffusive spin Hall effect, the non-local resistance is expected to have opposite signs for R_{J2} for I_{J1} as compared with R_{J1} for I_{J2}, which is supported by the measurement. In addition, the sign of R_{J3} should not change, which is confirmed as shown in FIGS. 4A-4B. However, a sign reversal for R_{J4} is observed when the current is applied across J2 as opposed to when current is applied across J1. The sign reversal is not observed for non-local resistances R_{J4} and R_{J3} for current across J3 and J4, respectively, as shown in FIGS. 4C-4D. In all the measurements, a consistent increase in non-local resistances is observed at low temperatures.

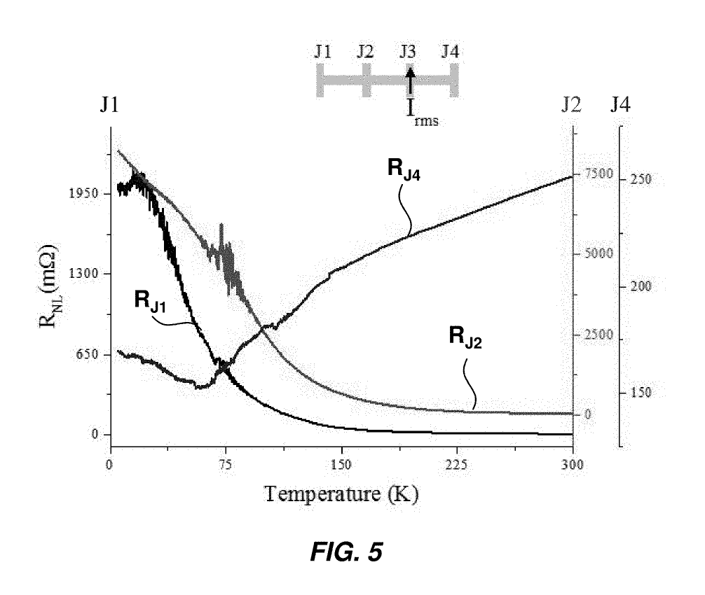

Assuming spin diffusion due to SHE in p-Si, the non-local resistance can be calculated using Equation 2 proposed by Abanin et al. [1-14]:

$${R}_{NL} ( x ) = \frac{1}{2} {( \frac{{β}_{s}}{σ} )}^{2} \frac{w}{σ {l}_{s}} {e}^{- \vert x \vert \text{/} {l}_{s}} \qquad ( Eq . 2 )$$

where βₛ is spin Hall conductivity, a is electrical conductivity, w is width, lₛ is spin diffusion length, and x is distance from the source. It is observed that the parameters cannot be fit since the non-local resistance can be higher at relatively longer distances. The observed spin transport is dissipationless and not diffusive. Without being bound by theory, it is proposed that the observed non-local resistance behavior is attributed to the intrinsic spin-Hall effect in p-Si. In addition, it is proposed that spin-to-charge conversion occurs due to ISHE at the MgO/p-Si interface and not intrinsically in p-Si. The observed non-local resistance behavior is confirmed by repeating the temperature dependent measurement on another device, as illustrated in FIG. 5.

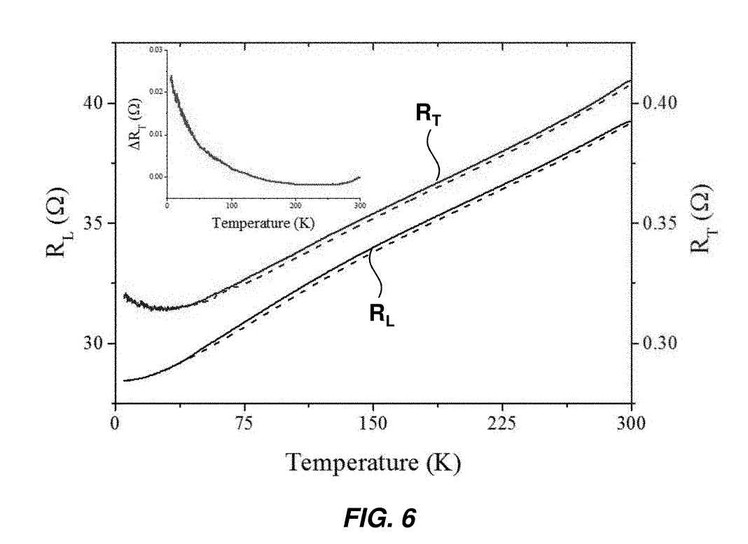

In order to prove the hypothesis, the temperature-dependent longitudinal and transverse resistance of MgO/p-Si specimen are measured, as illustrated in FIG. 6. From the longitudinal resistance measurement, a metallic behavior observed in Si and MgO layer at the surface has no effect. However, the measured transverse resistance shows an increase in resistance below about 30 K. The transverse resistance will have contribution from longitudinal resistance (due to misalignment of the Hall bar) and contribution from the other phenomena (likely due to spin transport).

The contribution of longitudinal resistance is subtracted from the transverse resistance to extract the probable spin transport behavior in transverse resistance as shown in the inset of FIG. 6. A behavior similar to the non-local resistance is observed. This increase in transverse resistance can be attributed to anomalous Hall effect (AHE) or interfacial ISHE attributed to the MgO at the top surface.

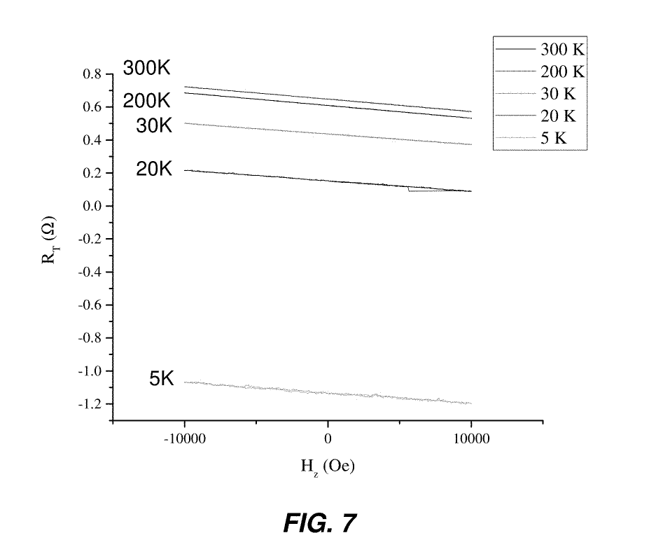

To discover the mechanism, magnetic field-dependent transverse resistance measurements were performed at 300 K, 200 K, 30 K, 20 K and 5 K and are illustrated in FIG. 7. These measurements show an ordinary Hall effect behavior. No anomalous Hall effect is observed. From these observations, it can be deduced that the observed increase in transverse resistance at low temperature is attributed to the ISHE at the MgO/p-Si interface. In addition, magnetic field-dependent transverse resistance shows a sign change at 5 K, as compared to higher temperatures. This sign change occurs because the contribution of the ISHE at the MgO/p-Si interface towards transverse resistance is greater than the opposing contribution of longitudinal resistance due to misalignment of Hall bar.

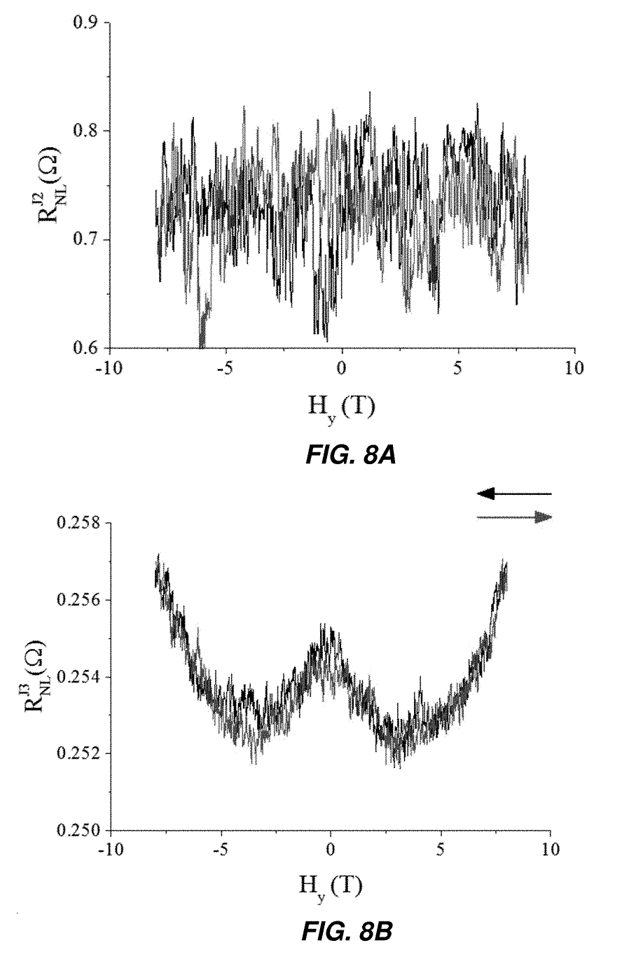

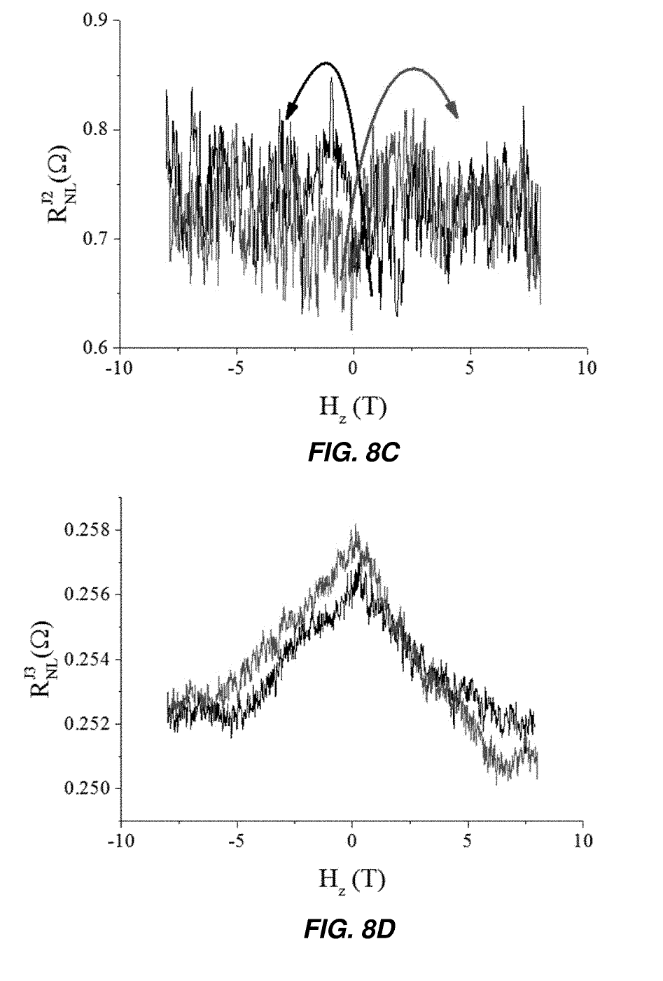

To further support the argument of the intrinsic spin-Hall effect, the non-local resistance at 5 K is measured as a function of the applied magnetic field in the y and z-direction. These measurements are illustrated in FIGS. 8A-8D. The magnetic field is swept from 8T/-8T while the current is applied across J1. A pseudo Hanle precession behavior is observed for R_{J3} for both larger in plane (y-direction) and out-of-plane (z-direction) magnetic fields. However, Hanle precession is not observed in case of R_{J2}, even though J2 is closer to the spin source than J3 is.

Without being bound by theory, it is proposed that spin transport is intrinsic, leading to negligible effect of the applied magnetic field. The applied magnetic field may affect the intrinsic spin transport by Zeeman splitting. This measurement is carried out on a third device and the non-local resistance measured is similar to the results presented in FIGS. 4A-4D.

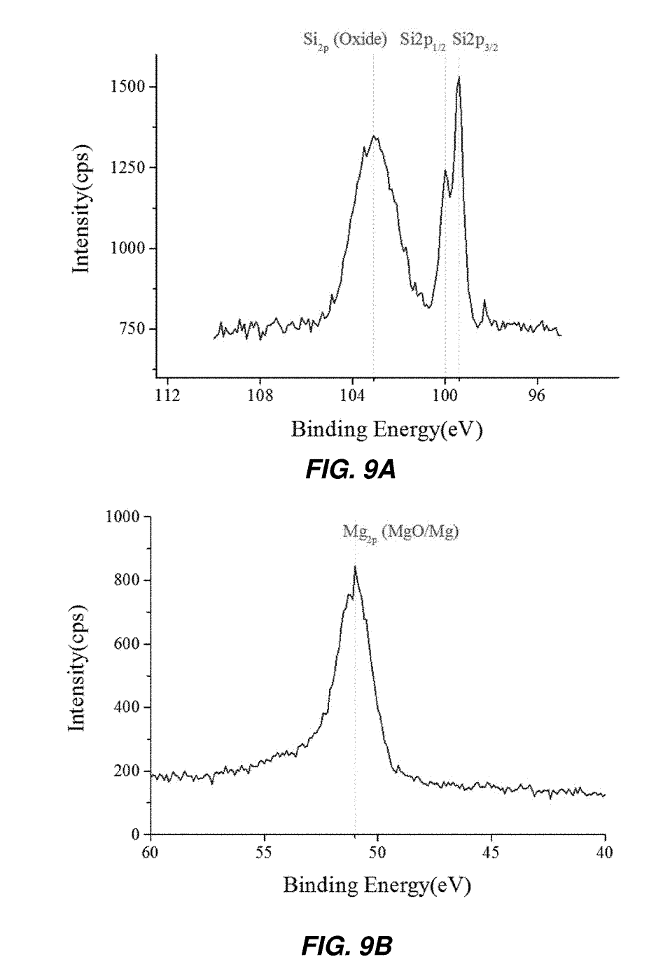

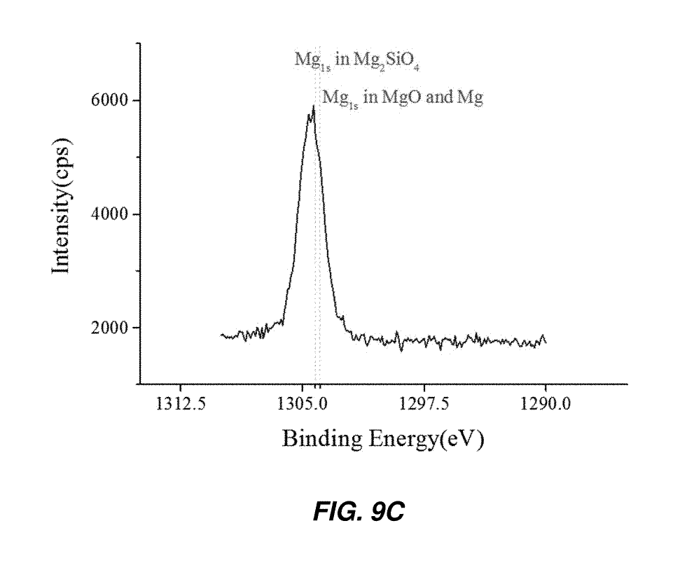

The MgO/Si interface is characterized by X-ray photoemission spectroscopy (XPS) using a Kratos AXIS ULTRA^{DLD} XPS system (Kratos Analytical Ltd., Manchester, UK) equipped with an Al Kα monochromated X-ray source and a 165-mm mean radius electron energy hemispherical analyzer. Vacuum pressure is kept below 3×10⁻⁹ torr during the acquisition, and data is acquired at a step of 0.1 eV and a dwell of 200 ms. Results of the XPS characterization are illustrated in FIGS. 9A-9C and analyzed using NIST XPS database [1-19]. An Ar milling of 10 min is performed remove the native oxide before sputtering MgO. However, the Si₂ₚ peak corresponding to silicon oxide is observed. Analysis of Mg₂ₚ reveals a peak corresponding to Mg (51.1 eV) in MgO/Mg as shown in FIG. 9B [1-20]. From the Mg₁ₛ XPS data, a peak corresponding to Mg is observed in MgSi₂O₄ (1304.2 eV) and MgO (1303.9 eV).

Based upon this XPS data, it is proposed that the MgO/Si interface includes MgO/Mg/SiO₂ (moving from top to bottom). It is further proposed that oxygen deficiency leads to a metallic Mg, creating a two-dimensional electron gas system (2DES) at the MgO/Si interface. It is additionally proposed that a Rashba spin orbit coupled 2DES exists due to the structure inversion asymmetry. The structural inversion asymmetry can be present due to flexoelectric polarization arising from a through-thickness strain gradient. The observed behavior is scientifically significant since intrinsic spin-orbit coupling in Si, O and Mg is small individually, but a combined effect is significant for spin to charge conversion.

Rashba spin-orbit coupled 2DES systems are proposed to exhibit intrinsic SHE [1-21], which has been experimentally observed [1-22]. In the embodiments of the MgO/p-Si thin film, spin current may originate from the interfacial 2DES. However, such systems are expected. to have very short spin diffusion length [1-22]. In contrast, spin transport behavior at a distance of 100 μm is observed.

In addition, spin current from the MgO/Si interface will not lead to the transverse resistance behavior presented in FIG. 6. The Si and MgO interface has been demonstrated to have interfacial electronic states. The SIA at the MgO/p-Si interface leads to Rashba spin-orbit coupling and efficient spin to charge conversion reported in this work. Lesne et al. experimentally demonstrated the highly efficient spin to charge conversion at oxide interfaces [1-15].

In addition, IrO₂ has been observed to show large spin Hall conductivity [1-16]. However, the interfacial spin to charge conversion presented herein involves atoms having insignificant spin orbit coupling individually. Here, conclusive proof is provided to demonstrate that the spin current originates from the p-Si and spin to charge conversion takes place at the MgO/Si interface due to Rashba spin orbit coupling.

In a recent work, Lou et al. [1-23] demonstrated SHE in p-Si using magneto-thermal transport measurements, but the underlying mechanism is still unknown. The intrinsic SHE has been proposed to exist only for p-Si. This behavior suggests the existence of spin-orbit coupled band structure as proposed by Murakami et al. [1-10]. In Si, only valence band is spin orbit coupled; the conduction band is not.

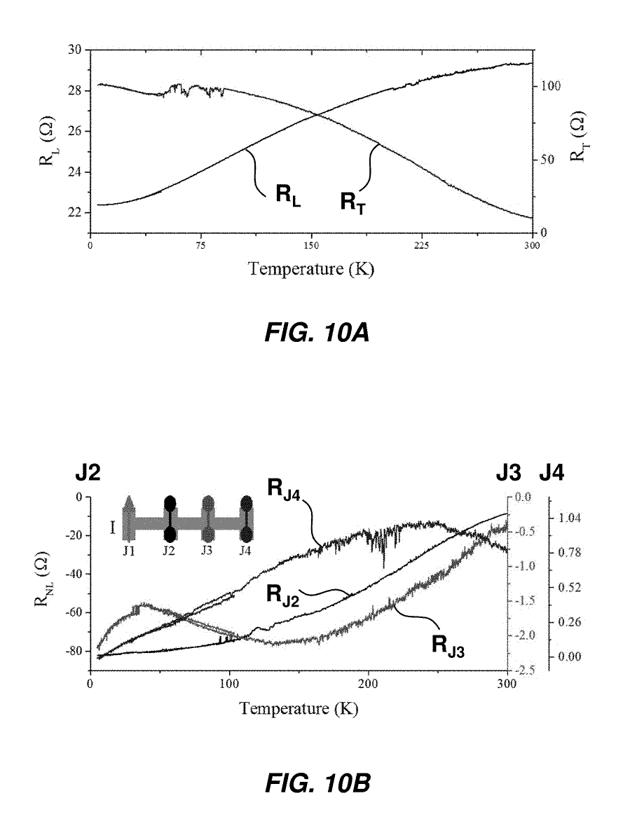

Accordingly, temperature-dependent non-local measurements are further performed on an MgO/n-Si thin film device. As discussed above, the thickness of the MgO layer relative to the thickness of the n-Si layer can be selected to induce a strain gradient through the thickness of the MgO/n-Si thin film device. In certain embodiments, the thickness of the MgO layer can be selected from 1 nm to 50 nm (e.g., a non-zero value less than 2 nm). The thickness of the n-Si layer can be selected from 2 nm to 3 μm. As an example, a specimen formed with MgO (1 nm)/n-Si (2 μm) is formed as discussed above. The specimen is subjected to cooling from 300 K to 5 K at a rate of 0.4 K and heating to 100 K at a rate of 0.4 K/min during acquisition to confirm the reproducibility. Unexpectedly an increase in transverse resistance (RT) and non-local resistance (RNL) behavior similar to that of the MgO/p-Si specimen is observed, as illustrated in FIGS. 10A-10B. As shown in FIG. 10A, the transverse resistance RT at room temperature (300 K) is measured to be about 7Ω, which is very large and cannot be explained by misalignment of the Hall bar structure. The non-local resistances RNL are measured by applying current across J1, as shown in FIG. 10B.

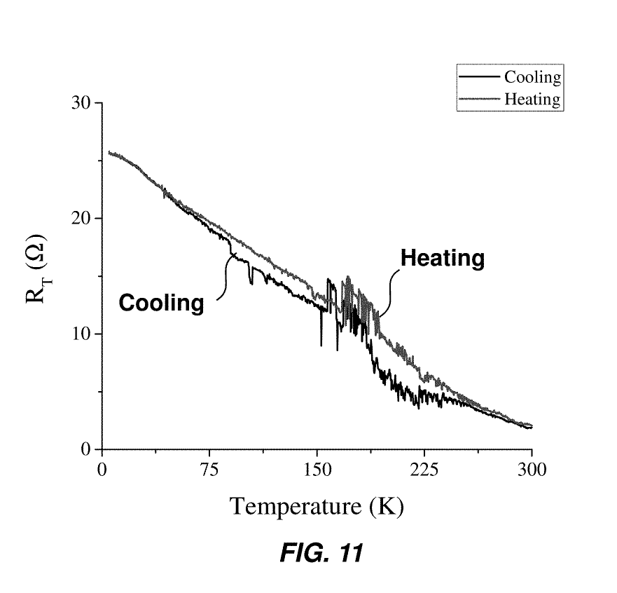

In the case of MgO/n-Si, the spin mediated non-local resistance is an order of magnitude larger than the MgO/p-Si. This observed behavior is attributed to a giant intrinsic SHE in n-Si. Since the transverse resistance is high in the first measurement, the measurement is repeated on another device and the results are illustrated in FIG. 11. The transverse resistance is measured to be about 2Ω at room temperature (300 K), which is high as well, and temperature dependent behavior is similar to the first device (FIG. 10A). This corroborates the measurement and repeatability of data.

These measurements lead to the conclusion that the mechanism proposed by Murakami et al. [1-10] is not the underlying mechanism for the observed behavior, since SHE has not been predicted for n-Si. Zhang et al. [1-24] theoretically predicted that the site inversion asymmetry in Si may create hidden spin polarization. The lattice of Si is centosymmetric but individual sites are not. This leads to intrinsic spin polarization, which is hidden due to the compensation by the inversion counterpart. This behavior can be regarded as local antiferromagnetic-like non-equilibrium spin polarization [1-25].

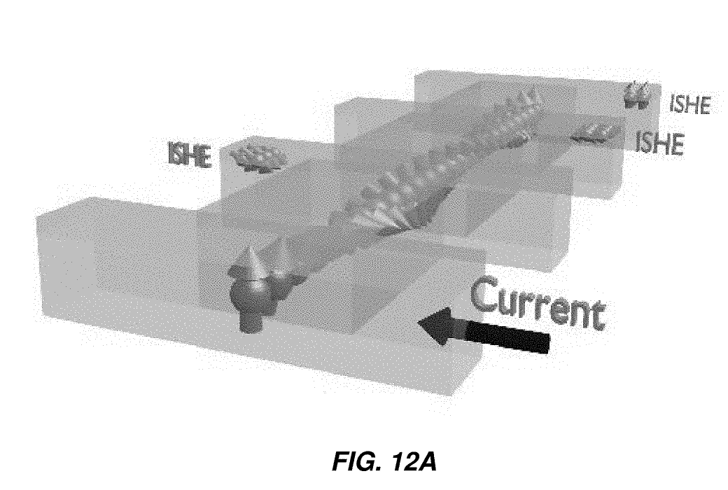

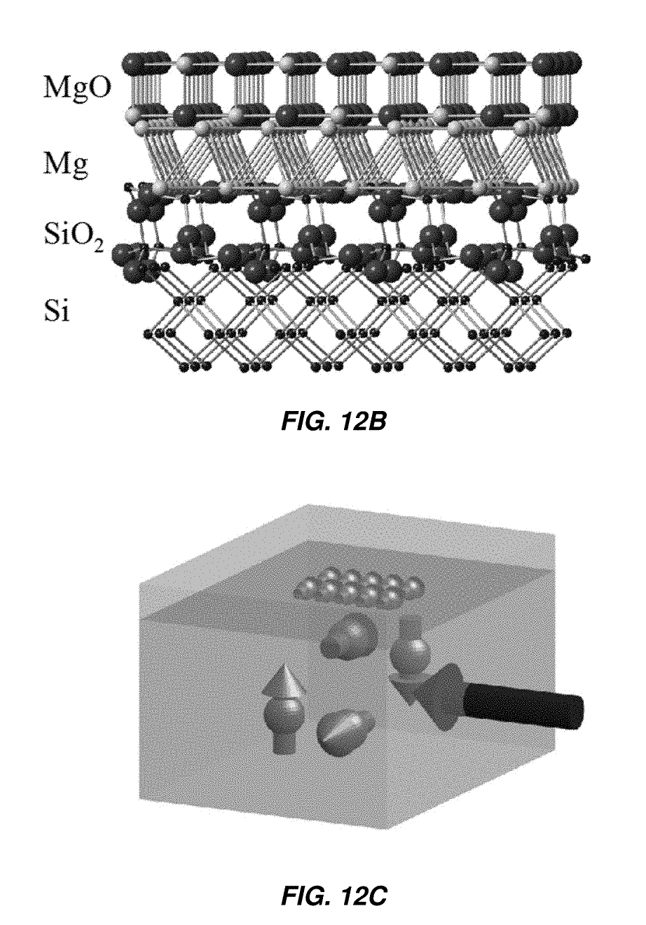

Without being bound by theory, it is proposed that the intrinsic spin current is attributed to the site inversion asymmetry due to local antiferromagnetic interactions. These antiferromagnetic spin-spin interactions lead to helical spin states in Si, generating intrinsic dissipationless spin current observed in this study as shown in FIG. 12A. in the bulk Si, this hidden spin polarization is undetected, as with the observed non-local transport measurements on Si only (without MgO) presented in FIGS. 2C-2D, since the spin-orbit coupling is weak. In embodiments of the present disclosure, detection of intrinsic spin current is achieved by having structure inversion asymmetry at the MgO/Si interface, as shown in FIG. 12B. The Rashba spin-orbit coupling at the MgO/Si interface leads to efficient spin to charge conversion. The structural inversion asymmetry can be present due to flexoelectric polarization arising from a through-thickness strain gradient. The ISHE at the MgO/Si interface is also responsible for the anomalous increase in Hall voltage at the low temperatures, as shown in FIG. 12C.

Thus, generation of intrinsic dissipationless spin current in MgO/Si thin film devices (p-Si and n-Si) is demonstrated without use of a ferromagnetic source. Efficient spin to charge conversion is achieved by having structure inversion asymmetry at the MgO/Si interface. Site inversion asymmetry is also demonstrated in a centosymmetric diamond cubic lattice of Si. Local antiferromagnetic interactions are also shown to lead to dissipationless spin current.

### Spin Driven Emergent Anti-Ferromagnetism and Metal Insulator Transitions In Nanoscale p-Si

The entanglement of the charge, spin and orbital degrees of freedom can give rise to emergent behavior especially in thin films, surfaces and interfaces. Often, materials that exhibit those properties require large spin orbit coupling. Without being bound by theory, it is hypothesized that the emergent behavior can also occur due to spin, electron, and phonon interactions in widely studied materials such as Si. That is, large intrinsic spin-orbit coupling is not an essential requirement for emergent behavior. The central hypothesis is that when one of the specimen dimensions is of the same order (or smaller) as the spin diffusion length, then non-equilibrium spin accumulation due to spin injection or spin-Hall effect (SHE) will lead to emergent phase transformations in the non-ferromagnetic semiconductors.

According to embodiments of the disclosure, spin mediated emergent anti-ferromagnetism and metal insulator transition are demonstrated in thin film of the type Pd/Ni₈₀₊ₓFe20₋ₓ/MgO/p-Si or n-Si, where x is selected from 0 and 1 (e.g., Pd/Ni₈₁Fe₁₉/MgO/p-Si for x=1). The spin-Hall effect in p-Si, observed through spin-Hall magnetoresistance behavior, is proposed to cause the spin accumulation and resulting emergent behavior. Such phase transition is discovered from the diverging behavior in longitudinal third harmonic voltage, which is related to the thermal conductivity and heat capacity.

Si is the apex semiconductor and an important material for spintronic applications because of weak spin-orbit coupling and absence of spin scattering mechanisms [2-1]. Since spin-phonon interactions are the primary mechanism of spin relaxation in Si, it is hypothesized that reduction of phonon population, occupation, and mean-free-path can enhance the spin accumulation, allowing the manifestation of coherent spin states (spin condensate) in p-Si. The site inversion asymmetry in lattice structure of Si has been proposed to cause hidden (or local) anti-ferromagnetic (AFM) exchange interaction [2-2, 2-3]. The hidden AFM interaction may be enhanced to strong AFM interactions with introduction of spin current, resulting in the spin mediated emergent behavior [2-4, 2-5, 2-6].

The spin mediated emergent AFM phase transition is considered as second order phase transformation, which can be discovered using thermal transport measurements [2-7 to 2-13]. The p-Si has been experimentally shown to exhibit inverse spin-Hall effect [2-14]. Hence, it is expected to have spin-Hall effect (SHE) as well due to reciprocity. The spin accumulation due to SHE when absorbed at the ferromagnet/semiconductor interface will create spin polarization in the semiconductor. The proposed spin polarization mechanism is adapted from the observation of spin-Hall magnetoresistance (SMR) [2-15, 2-16] in ferromagnetic metal/heavy metal bilayers.

To enable emergent behavior, phonon mean-free-path should first be reduced. Studies have shown reduction in mean-free-path can be achieved with boundary scattering in in nanoscale and nanowires [2-17 to 2-20]. This can be mimicked in a magneto-electro-thermal transport measurement setup, discussed below, having p-Si thickness similar to the spin diffusion length (about 300 nm [2-21]). The micro-electro-mechanical systems (MEMS) setup relies on the spin-Hall effect (SHE) to create spin polarization the p-Si layer, as noted above. In one embodiment, a freestanding Pd (1 nm)/Ni₈₁Fe₁₉ (25 nm)/MgO (1 nm)/p-Si (400 nm) multilayer thin film device is investigated.

As discussed in detail below, the MgO layer facilitates spin tunneling, as well as acts as a diffusion barrier. To observe the spin mediated behavior, the longitudinal V_{1ω} (electrical resistance), V_{2ω} (spin Seebeck effect (SSE), anomalous Nernst effect (ANE), tunneling anisotropic magnetoresistance (TAMR)) [2-22, 2-23, 2-24], and V_{3ω} (self-heating 3ω method for thermal conductivity [2-25]) responses are measured. The application of electrical current creates an approximately parabolic longitudinal temperature gradient in the specimen [2-26, 2-27]. In the thin film specimens on substrate, the resulting in-plane temperature gradient is insignificant and can be neglected. However, in the case of a freestanding specimen, the longitudinal temperature gradient can be used to measure the in-plane thermal transport behavior of the specimen. Furthermore, the temperature gradient can produce or augment a strain gradient extending through the thickness of the device and in turn enhance Rashba spin-orbit coupling.

The self-heating 3ω technique utilizes a time-dependent current of frequency ω and amplitude I₀ in the specimen to both generate the temperature fluctuations and probe the thermal response. The technique relies on the solution of the one-dimensional heat conduction equation for the device, which is given by Equation 3:

$$ρ {C}_{p} \frac{\partial θ ( x , t )}{\partial t} = κ \frac{{\partial }^{2} θ ( x , t )}{\partial {x}^{2}} + \frac{{I}_{o}^{2} {sin}^{2} ω t}{LS} ( {R}_{o} + {R}^{′} θ ( x , t ) ) \qquad ( Eq . 3 )$$

where L is the length between the voltage contacts, S is the cross-sectional area of the device, ρ is the density in the material, Cₚ is the specific heat of the device, κ is the thermal conductivity of the device. R₀ is the initial electrical resistance of the device at temperature Tₒ, R′ is the temperature derivative of the resistance and is given by

$${R}^{′} = {( \frac{dR}{dT} )}_{{T}_{o}}$$

at Tₒ. θ(x, t)=T(x, t)−Tₒ is the temporal (t) and spatial (x) dependent temperature change, as measured along the length of the device, which coincides with the heat flow direction. ω is frequency and Iₒ is the heating current amplitude.

The V_{3ω} is a function of both thermal conductivity and heat capacity and is given by Equation 4:

$${V}_{3 ω} \approx \frac{4 {I}^{3} {R}_{o} {R}^{′} L}{{π}^{4} S κ \sqrt{1 + {( 2 ωγ )}^{2}}} \qquad ( Eq . 4 )$$

where I is heating current and γ is the thermal time constant and is related with the heat capacity

$$( {C}_{p} = \frac{{π}^{2} γκ}{ρ {L}^{2}} ) .$$

The thermal conductivity can be expressed in terms of the third harmonic voltage V_{3ω} in the low frequency limit by

$$κ \approx \frac{4 {I}^{3} {R}_{o} {R}^{′} L}{{π}^{4} {V}_{3 ω} S}$$

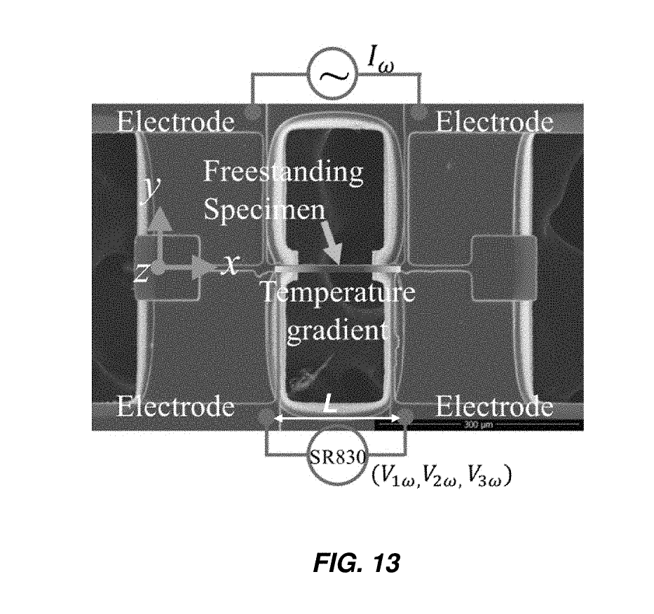

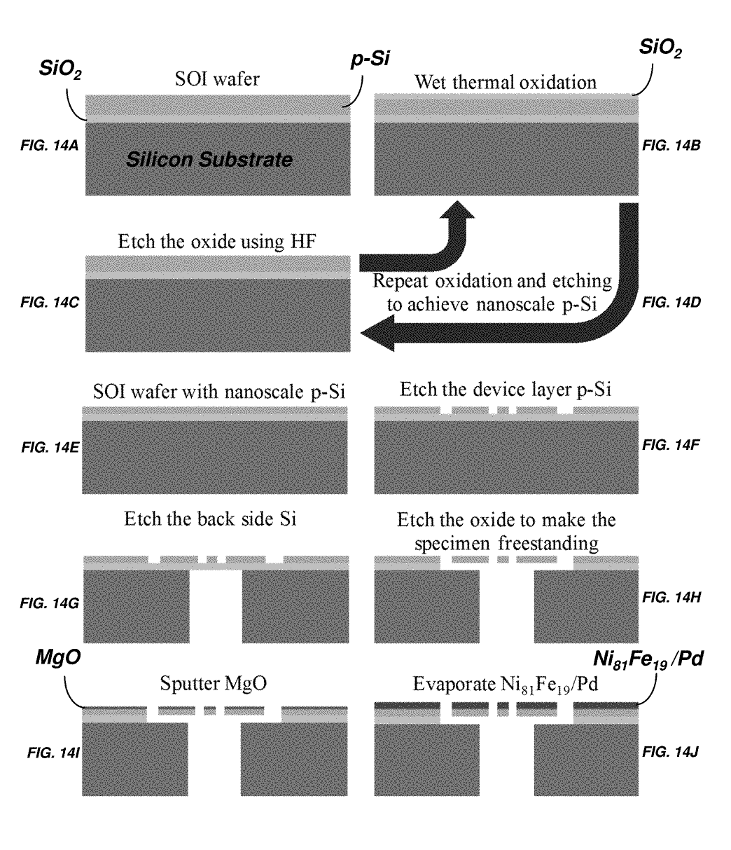

FIG. 13 is a false color micrograph illustrating one exemplary embodiment of a freestanding Pd/Ni₈₁Fe₁₉/MgO/p-Si thin film device. An embodiment of a process for forming the Pd/Ni₈₁Fe₁₉/MgO/p-Si thin film device utilizing micro/nanofabrication techniques is illustrated in FIGS. 14A-14J.

As shown, the device fabrication process begins in FIG. 14A with a silicon on insulator (SOI) wafer. The SOI wafer includes a silicon substrate, a first silicon dioxide (SiO₂) insulating layer positioned on the silicon substrate, and a p-Si device layer positioned on the SiO₂ layer. In certain embodiments, the p-Si layer can be B-doped. A resistivity of the p-Si layer can range from 0.001 Ωcm to 0.005 Ωcm.

A wet thermal oxidation is performed on the SOI wafer (FIG. 14B) to produce a second silicon dioxide (SiO₂) layer positioned on the p-Si device layer. This oxidation is followed by etching of the second SiO₂ layer and a portion of the p-Si device layer (FIG. 14C) with hydrofluoric acid (HF). The oxidation and etching operations can be repeated (FIG. 14D) until the thickness of the p-Si device layer achieves a target value near the spin diffusion length (FIG. 14E). As an example, a target thickness of the p-Si device layer can be selected from 2 nm to 3 μm (e.g., 400 nm).

Using ultraviolet (UV) lithography and deep reactive ion etching (DRIE), the top of the p-Si device layer is patterned and etched, as illustrated in FIG. 14F. A portion of the silicon substrate is etched to reveal the back side of the first SiO₂ layer (FIG. 14G) The first SiO₂ layer is also etched using an HF vapor to provide a freestanding portion of the p-Si device layer (FIG. 14H).

Surface oxide formed on the top side of the p-Si device layer is removed by Ar milling (e.g., 15 minutes) in preparation for deposition of MgO. An MgO layer is deposited upon the p-Si device layer using RF sputtering (FIG. 14I). The MgO layer has a non-zero thickness sufficient to inhibit formation of silicide compounds. As an example, the MgO layer can have a non-zero thickness less than 2 nm (e.g., 1 nm).

A layer of Ni₈₁Fe₁₉/Pd is deposited on the MgO layer using e-beam evaporation (FIG. 14J). Deposition by evaporation leads to line of sight thin film deposition. The Ni₈₁Fe₁₉ layer is positioned on the MgO layer and the Pd layer is positioned on the Ni₈₁Fe₁₉ layer. The thickness of the Ni₈₁Fe₁₉ layer is selected from 5 nm to 200 nm (e.g., 25 nm). The thickness of the Pd layer can be any thickness sufficient to protect the Ni₈₁Fe₁₉ layer from oxidation. As an example, the Pd layer can have a thickness of 1 nm. The MgO layer functions as a tunneling barrier and can have a non-zero thickness less than 2 nm (e.g., 1 nm). In certain embodiments, the thickness of the MgO layer relative to the thickness of the p-Si layer can be selected to induce a strain gradient through the thickness of the p-Si layer. The strain gradient can be sufficient to promote structural inversion symmetry within the doped Si layer at and/or adjacent to the Ni₈₁Fe₁₉/p-Si interface.

Magneto-electro-thermal transport measurements are carried out inside a Quantum Design physical property measurement system (PPMS). An AC bias of 290 μA at 5 Hz is applied across the outer electrodes using Keithley 6221 current source. Corresponding measurements of R_{1ω}, V_{2ω}, and V_{3ω} are recorded using SR-830 lock-in amplifiers.

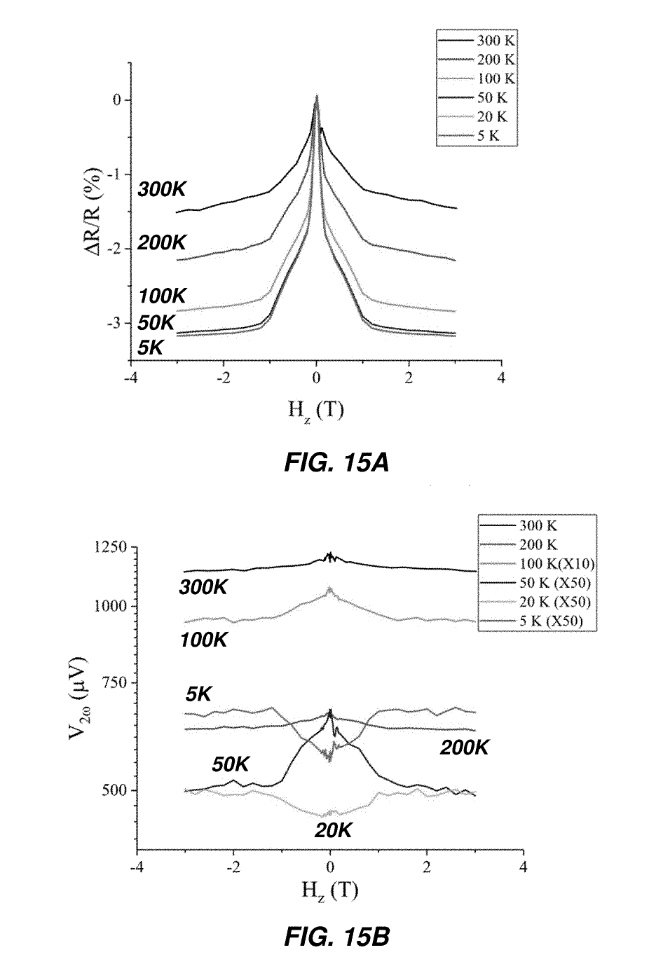

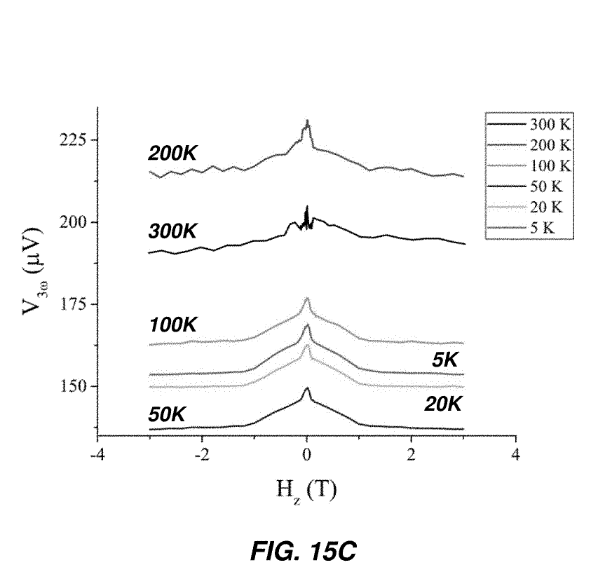

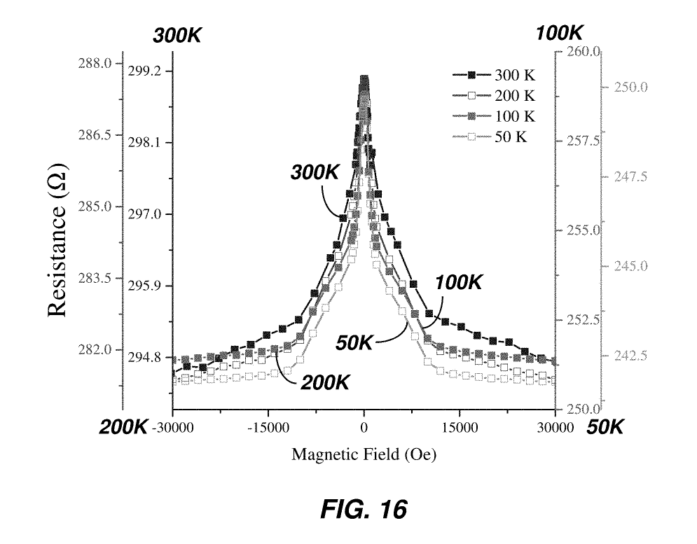

The responses are measured as function of magnetic field from 3 T to −3 T at various temperatures between 5 K and 300 K as shown in FIGS. 15A-5C and FIG. 16. From the magneto-electro-thermal transport data, a negative magnetoresistance (MR) of −1.5% at 300 K is observed, which gradually increases to −3.1% at 5 K. The negative MR can be understood to originate from the Ni₈₁Fe₁₉ layer. The MR behavior presented in FIG. 15A shows a knee at approximately 1.25 T, which corresponds to the saturation magnetization of Ni₈₁Fe₁₉. It is also observed that the specimen resistance at 300 K is about 299Ω and at 200 K it is 290Ω, which is a small change for 100 K temperature difference (FIG. 16).

The V_{2ω} behavior is analyzed to uncover the potential contribution of the SSE, ANE and TAMR. The V_{2ω} response measured at 300 K is very large, and it does not show a change in sign when the direction of applied magnetic field is reversed, which is contrary to the reported behavior of SSE. The SSE can be detected only with a large spin-Hall angle in the detector for efficient spin to charge conversion. In the current sample geometry, the p-Si layer functions as the spin detector, which has a small spin-Hall angle (e.g., 10⁻⁴) [2-14]. This will lead to insignificant SSE response, although spin polarization from SSE may still be significant. The longitudinal temperature gradient will not cause ANE in x-direction and out-of-plane magnetic field will lead to zero ANE due to vertical temperature gradient.

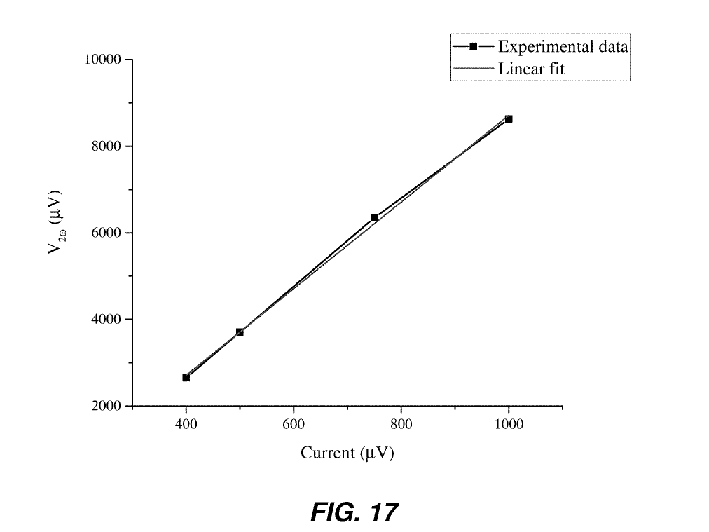

In addition, the V_{2ω} response, discussed in greater detail below, shows a linear behavior as a function of applied current (FIG. 17), as opposed to quadratic (I²) behavior expected for SSE, ANE and TAMR, which can be attributed to the electric current being shunted across the bulk of the Ni₈₁Fe₁₉ and p-Si layers. These observations lead to the belief that TAMR is also not the primary cause of observed V_{2ω} response. The lack of dependency in V_{2ω} with direction of magnetic field shows that spin current in this system is not dependent on magnetization of a ferromagnet (Ni₈₁Fe₁₉ in the present device). Instead, spin current is created by a mechanism that relies on spin absorption/reflection at the interface rather than magnetization of ferromagnet. Without being bound by theory, it is proposed that the spin polarization in the p-Si layer due to spin imbalance leads to thermal fluctuation due to spin-phonon coupling and results in the V_{2ω} observed response. The V_{2ω} response is linear in current, since current shunted across the Ni₈₁Fe₁₉ layer does not contribute towards spin polarization. The SSE may also give rise to spin-phonon interactions and resulting V_{2ω} response.

The V_{3ω} response shows a magnetic field dependent behavior, and this can be interpreted as a spin-influenced thermal transport in p-Si, since p-Si is significantly more thermally conducting than Ni₈₁Fe₁₉. It is estimated that the thermal resistance of the p-Si layer will be about 26 times, assuming a κₚ₋ₛᵢ=30 W/mK of Ni₈₁Fe₁₉ layer (κ_{Ni}_{₈₁}_{Fe}_{₁₉}=21 W/mK [2-28]). In addition, the magnetic field dependent measurements of V_{2ω} and V_{3ω} responses show temperature dependent minima between 20 K and 50 K.

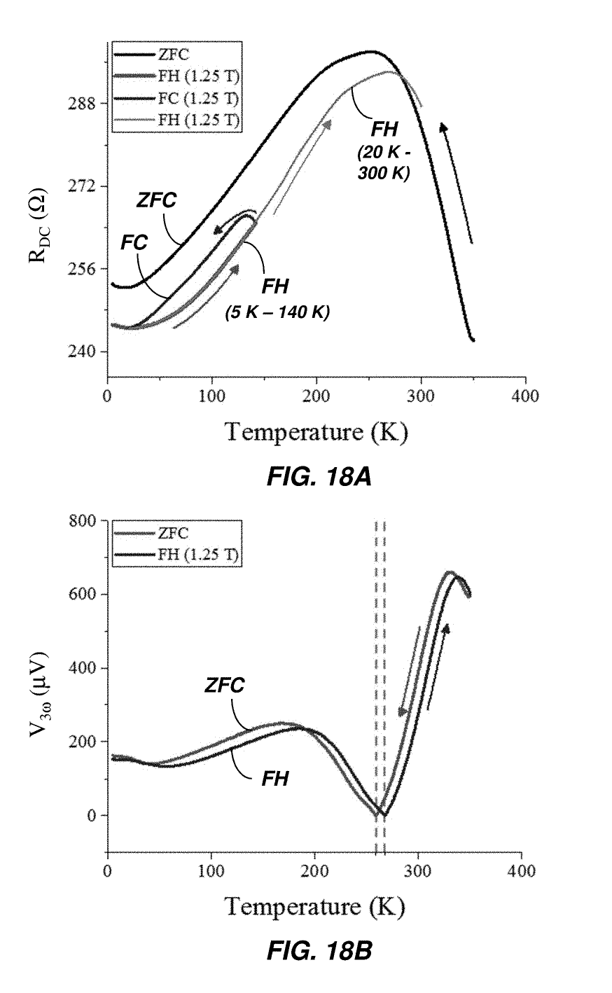

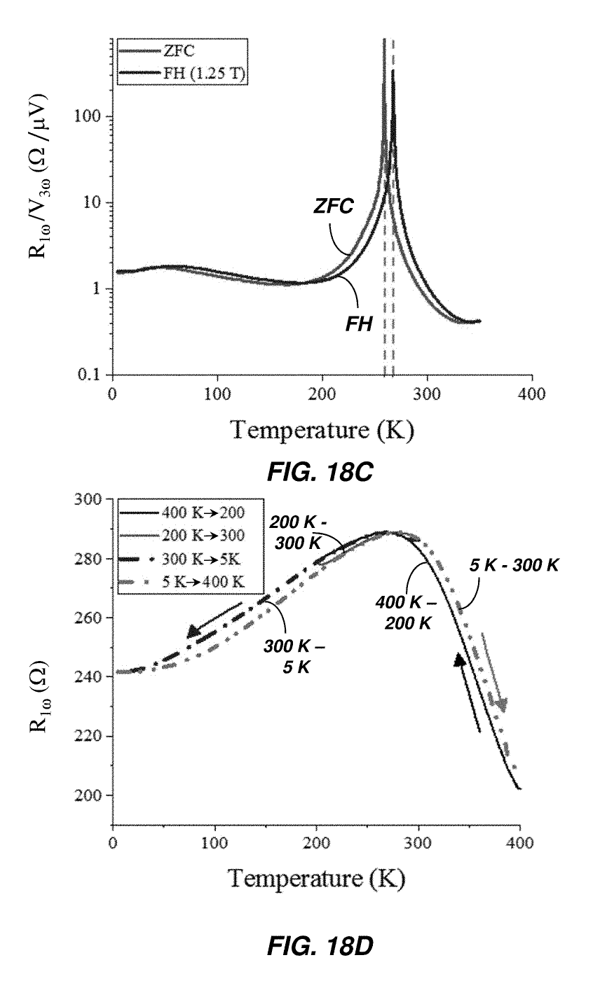

To uncover the insignificant temperature dependent change in resistance and to measure the R′ for thermal conductivity calculations, measurements of R_{DC} as a function of temperature are acquired from 350 K to 5 K at direct current of 10 μA to minimize the heating. Resistance is measured using a Keithley 6221 current source and a 2182A nanovoltmeter. The temperature dependent resistance behavior shows a rapid increase and then continuous decrease after about 250 K, as shown in FIG. 18A. The device is heated from 5 K to 140 K with an applied magnetic field of 1.25 T. Subsequently, the device is cooled again to 5 K in the presence of an applied magnetic field of 1.25 T. It is observed that the field-cooling (FC) curve starts to separate from field-heating (FH) curve and both meet around 20 K. Carrying out FH again, over the range from 20 K to 300 K, the FH behavior is observed to follow the first FH curve, indicating a hysteretic behavior. Although the current density in this case is about 2.64×10² A/cm², hysteretic behavior may originate from thermal drift because the device is freestanding. In addition, the box oxide layer of the SOI wafer is 1 μm thick and may induce thermal lag in the measurements. The observed diverging resistance behavior shown in FIG. 18A can be interpreted as metal-insulator transition (MIT) in the p-Si layer, due to either ferromagnetic proximity or spin accumulation (SHE) leading to shunting of the electric current across Ni₈₁Fe₁₉ layer.

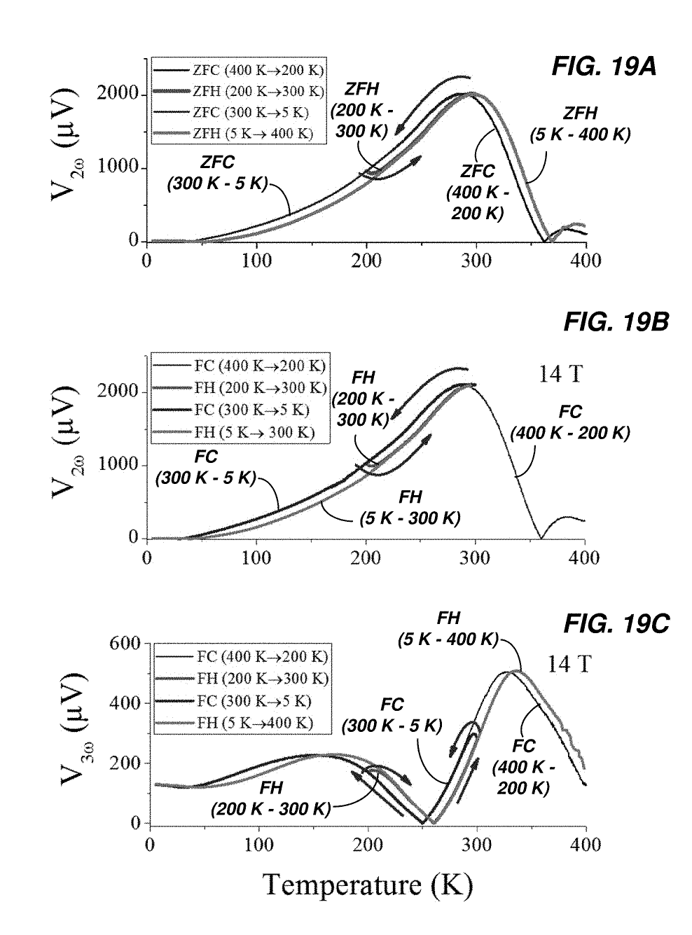

To understand the origin of observed behavior, the V_{2ω} response of the device was acquired as a function of temperature under zero applied magnetic field (heating—ZFH; cooling—ZFC). The device was cooled at 0.3 K/min from 400 K to 200 K, followed by heating from 200 K to 300 K. The device was further cooled again from 300 K to 5 K, followed by heating from 5 K to 300 K. The measured V_{2ω} response is presented in FIGS. 19A-19C. An inflection point is observed in the V_{2ω} response at about 360 K, which may indicate advent of spin dependent behavior.

R_{1ω} and V_{3ω} o are also acquired as a function of temperature while the device was cooled from 350 K to 5 K at 0.3 K/min for Iᵣₘₛ of 290 μA. The measured V_{3ω} data (FIG. 18B) shows an inflection point at 259 K. R_{DC} has a peak at approximately 268 K, making the thermal conductivity undefined around the peak due to zero slope. The V_{3ω} is a function of thermal conductivity only in the case of low frequency, and the observed behavior may violate the low frequency assumption. In that case, V_{3ω} will be a function of both thermal conductivity and heat capacity (through thermal time constant γ). The quantity

$$f ( κ , {C}_{p} ) = \frac{R}{{V}_{3 ω}}$$

is plotted as a function of temperature to understand the thermal property behavior in the absence of valid R′ (FIG. 18C). A sharp peak is observed in this data and diverging behavior in thermal transport.

$$\frac{R}{{V}_{3 ω}}$$

is found to increase from 0.725 Ω/μV at 300 K to 764.2 Ω/μV at 259 K.

Since the second order phase transformations are characterized from singularities or discontinuities in the temperature dependent heat capacity measurements, the diverging behavior in

$$\frac{R}{{V}_{3 ω}}$$

can be considered a second order phase transformation. In embodiments discussed herein, V_{3ω} response is instead employed to uncover the phase transition behavior, which is a function of thermal conductivity and heat capacity especially near the phase transition. Then, the device is heated under an applied magnetic field of 1.25 T at a rate of 0.3 K/min. The field dependent heating shows a shift in inflection point in V_{3ω} 267 K, which is also attributed to the thermal drift (FIG. 18B).

From the temperature dependent study, it is proposed that the second order AFM phase transformation is the underlying cause of inflection point observed in the temperature dependent V_{3ω} measurement. To understand the effect of applied magnetic field on the phase transformation, temperature dependent V_{1ω}, V_{2ω}, and V_{3ω} measurements are performed for an applied magnetic field of 14 T, as shown in FIGS. 18D, 19A, and 19B. The qualitative behavior for R_{1ω} as a function of temperature for applied magnetic field of 14 T is similar to the RDC data presented earlier (FIG. 18A), except the resistance values are lower due to negative magnetoresistance and the peak has shifted toward higher temperature. The 14 T V_{2ω} measurement of FIG. 19B shows minimal field dependent changes in the behavior as compared with zero field V_{2ω} measurement shown in FIG. 19A. The inflection point for V_{3ω} response (FIG. 19C) is shifted approximately 250 K due to applied magnetic field from 259 K at zero field (ZFC). The magnetic field has a measurable but small effect on the phase transition behavior.

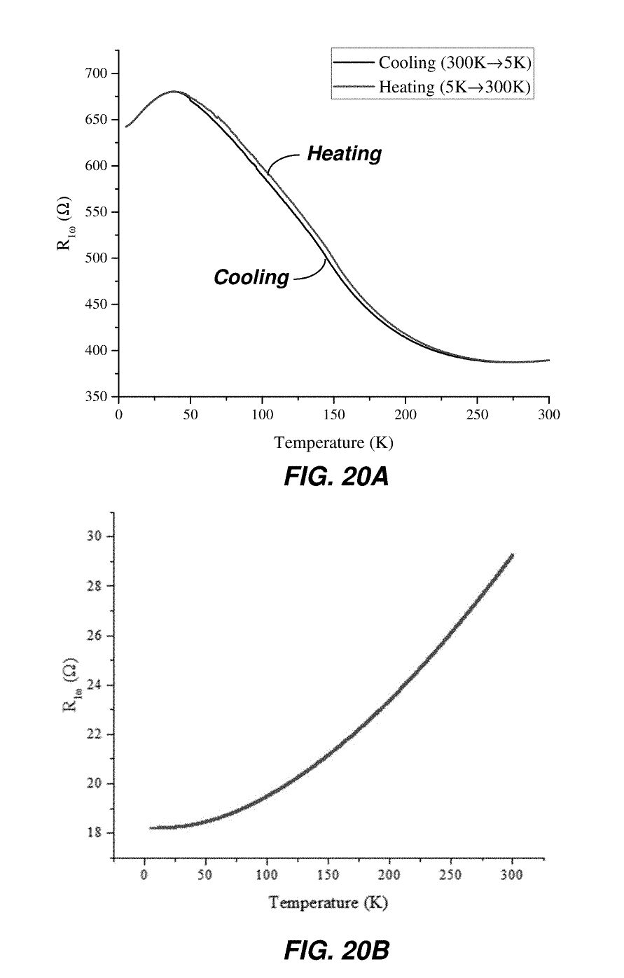

The diverging resistance behavior as a function of temperature, shown in FIGS. 18A and 18D, can be considered a metal-to-insulator transition (MIT). To uncover the origin of this transition. The resistance as a function of temperature is measured for two samples. A p-Si control sample (having similar resistivity) is formed from layers of SiO₂ and p-Si on an Si substrate. A Ni₈₁Fe₁₉ control specimen is formed from layers of layers of SiO₂, p-Si, and Ni₈₁Fe₁₉ on an Si substrate. Each specimen possessed dimensions of 40 μm length, 19 μm width, and 400 nm thickness. These resistance measurements are illustrated FIGS. 20A-20B.

The p-Si control specimen shows a semiconductor behavior (FIG. 20A). Notably, the peak in electrical resistance occurs below 50 K and the resistance does not increase significantly until about 200 K. The p-Si control specimen loses the metallic behavior (dopants) during oxidation-based chemical thinning methods utilized in the present work (methods), which may be the reason for semiconducting behavior.

The Ni₈₁Fe₁₉ control specimen including Ni₈₁Fe₁₉ and p-Si layers can be modeled as resistors in parallel. To simplify the calculations, it is assumed that the resistance of the Ni₈₁Fe₁₉ layer (e.g., about 290Ω) does not change appreciably from 350 K to 260 K (the peak temperature). It is further assumed that the resistance of the p-Si layer changes. With these assumptions, it is predicted that the resistance of p-Si will change from about 1200Ω at 350 K to about 8000Ω at 268 K. Since the resistance of the Ni₈₁Fe₁₉ layer is decreasing as a function of temperature, the increase in p-Si resistance is expected to be even higher. Without being bound by theory, it is proposed that the spin accumulation in p-Si may induce an emergent ferromagnetic or AFM phase transition. The temperature dependent measurement of V_{3ω} response at 14 T (FIG. 19C) suggests an AFM phase transition, and not ferromagnetic transition, since the transition behavior is weakly dependent on the applied magnetic field. It is proposed that the AFM spin-spin interactions lead to a gradual transition from conductor to insulating state, as hypothesized herein.

To replicate the experimental results, the temperature dependent measurement is carried out on a second Pd/Ni₈₁Fe₁₉/MgO/p-Si thin film device, which has significantly lower resistance at room temperature (e.g., about 300 K) than the first Pd/Ni₈₁Fe₁₉/MgO/p-Si thin film device. This result indicates that the p-Si layer of the second Pd/Ni₈₁Fe₁₉/MgO/p-Si thin film device has a large charge carrier density (approximately 10 times) relative to the first Pd/Ni₈₁Fe₁₉/MgO/p-Si thin film device. The resistance of the layered thin film specimen at 400 K is about 98.24Ω. Using a parallel resistor configuration, the resistance of p-Si layer is estimated to be approximately 150Ω, which is an order of magnitude lower than the first Pd/Ni₈₁Fe₁₉/MgO/p-Si thin film device.

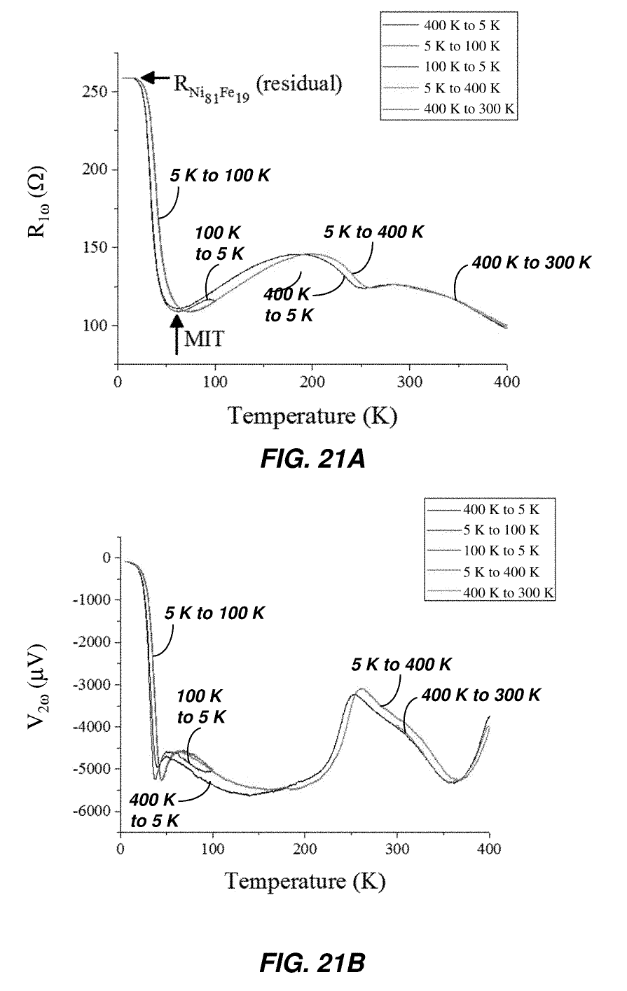

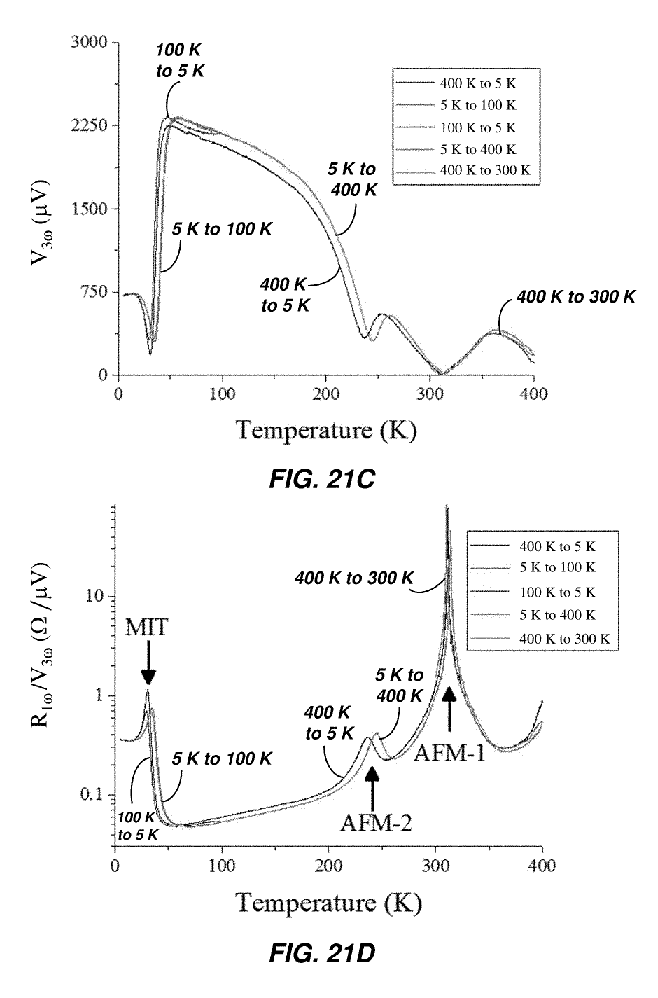

The data from the second Pd/Ni₈₁Fe₁₉/MgO/p-Si thin film device is shown in FIGS. 21A-21D. The data is acquired at cooling and heating rates of 0.2 K/min, which may reduce the thermal drift. It is observed that the proposed AFM transition occurs at about 312 K, which corresponds to V_{3ω} magnitude of zero (FIG. 21C), and a corresponding peak in

$$\frac{R}{{V}_{3 ω}}$$

### (FIG. 21D).

Two additional transitions are also observed at about 236 K and about 50 K. The emergent AFM is not intrinsic to p-Si and multiple AFM states may exist at different temperature and charge carrier concentrations. Without being bound by theory, it is proposed that the second transition at about 236 K is a transition from one emergent AFM state to another AFM state. At low temperatures, the AFM interactions open the band gap and cause a MIT [2-19, 2-20]. As a result, resistance goes from 110Ω to about 260Ω, as shown in FIG. 21A. The resistance after MIT (e.g., about 260Ω) corresponds to the Ni₈₁Fe₁₉ layer only. Based on diverging behavior in

$$\frac{R}{{V}_{3 ω}} ,$$

it can be confirmed that the observed transition discussed herein is a second order transition and not a structural phase transition

As discussed above, it has been proposed that the V_{2ω} originates from the absorption of spin current from SHE in p-Si to Ni₈₁Fe₁₉ layer. After MIT, the V_{2ω} response is expected to go to zero, since SHE in p-Si will cease to exist in the absence of charge current across the p-Si layer. The temperature dependent V_{2ω} response clearly supports this hypothesis, as shown in FIG. 21B.

In addition, a sharp drop in V_{3ω} response is also observed due to MIT from 2340 μV to about 185 μV, as illustrated in FIG. 21C. The V_{3ω} response is inversely related with the thermal transport behavior. The drop in V_{3ω} due to MIT may signify recovery of large phononic thermal transport in p-Si, which is suppressed due to spin polarization before MIT. The implication of this is that the MIT is not a Mott transition.

In addition, it is observed that the phase transition behavior is a function of doping level in p-Si. At low charge carrier density, the AFM transition is observed at about 259 K, as shown in the R/V_{3ω} response of FIG. 21D, while at higher charge carrier density the transition occurs at about 312 K. It is proposed that the observed MIT is an Anderson disorder transition [2-29, 2-31] observed in Si due to doping but is induced due to spin accumulation.

The observed transition behavior discussed herein is attributed to the spin accumulation due to SHE. The spin accumulation should be a function of applied current density. Hence, the transition behavior is expected to be a function of current density.

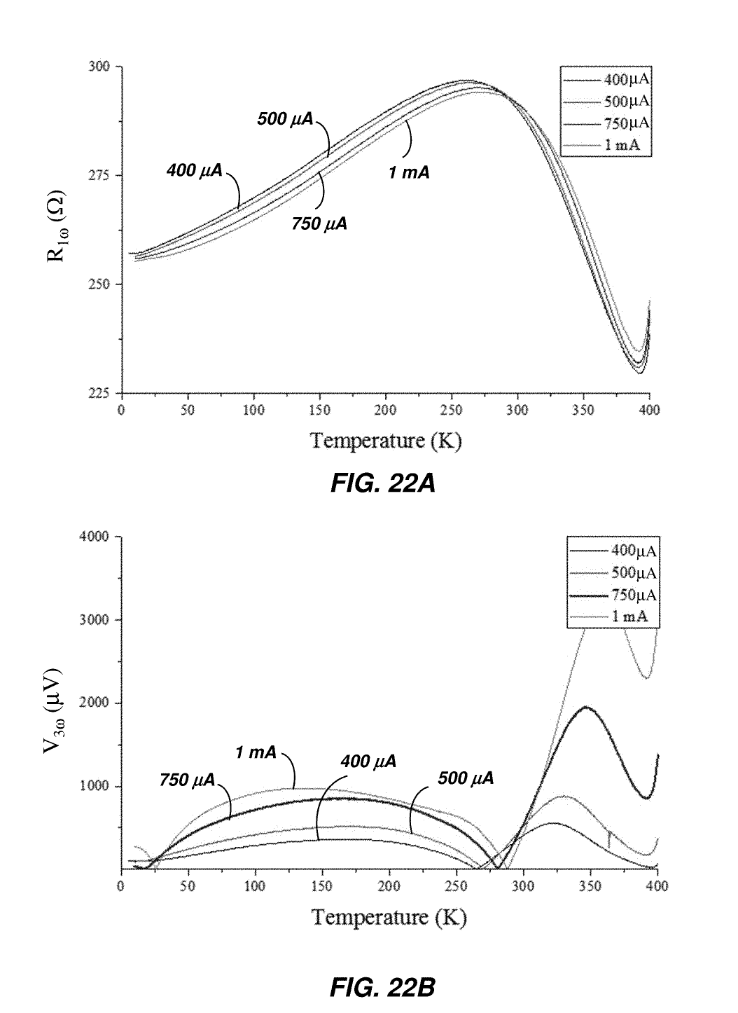

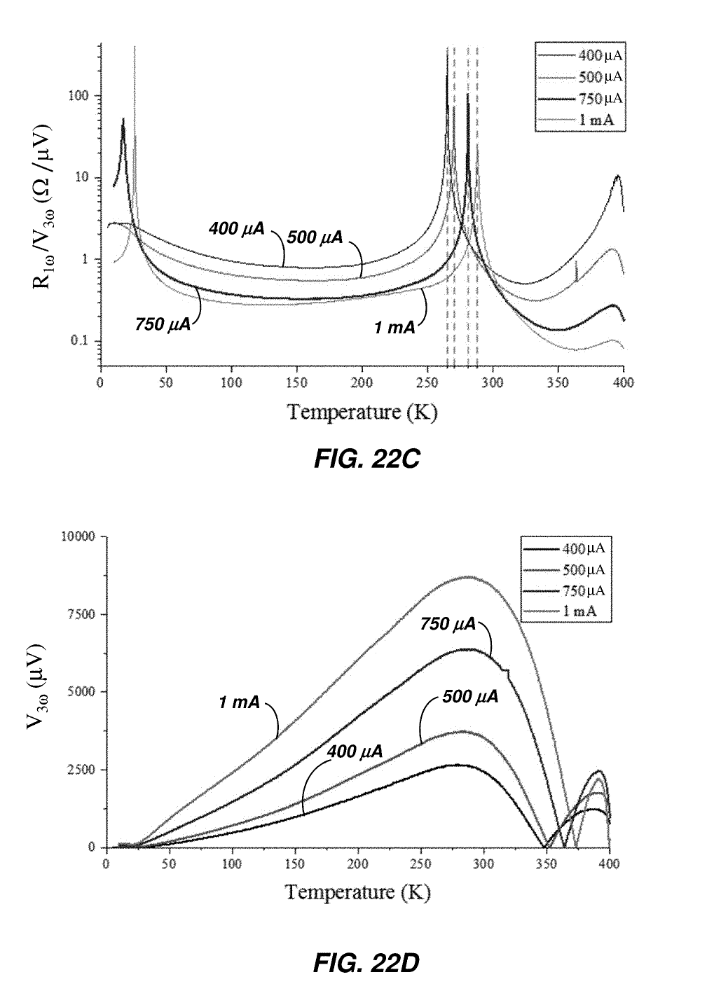

To validate this hypothesis, R_{1ω}, V_{2ω}, and V_{3ω} are measured as a function of temperature (at 0.2 K/min) for different applied electric currents (400 μA, 500 μA, 750 μA and 1 mA) in an embodiment of the Pd/Ni₈₁Fe₁₉/MgO/p-Si thin film device, illustrated in FIG. 22A-22D. The Joule heating is expected to lower the transition temperature (spin relaxation) and electrical resistance after transition, whereas enhanced polarization due to SHE may increase the transition temperature. The resistance corresponding to the peak reduces as the current is increased, which is inferred as effect of Joule heating. However, the transition temperature (deduced from the

$$\frac{R}{{V}_{3 ω}} )$$

increases as a function of applied electrical current as shown in FIGS. 22A and 22C. The transition temperature is observed at 259 K for 290 μA of electrical current as discussed above. The transition temperature is observed at 265 K, 270 K, 282 K and 288 K for applied current of 400 μA, 500 μA, 750 μA and 1 mA, respectively.

In addition, a second transition emerges for the applied current of 750 μA and 1 mA. This second transition may be inferred as transition from one AFM state to another and may be a precursor to the Anderson transition observed in the second Pd/Ni₈₁Fe₁₉/MgO/p-Si thin film device. These measurements convincingly demonstrate that the observed behavior is transport mediated.

In order to identify direct proof of the SHE, the magnetoresistance and V_{2ω} response of the Pd/Ni₈₁Fe₁₉/MgO/p-Si thin film device is measured as a function of angular rotation of the constant magnetic field in the yz-plane at 350 K (before transition) and 200 K (after transition). This measurement allows identification of the spin Hall magnetoresistance (SMR), anomalous magnetoresistance (AMR), SSE, ANE and TAMR.

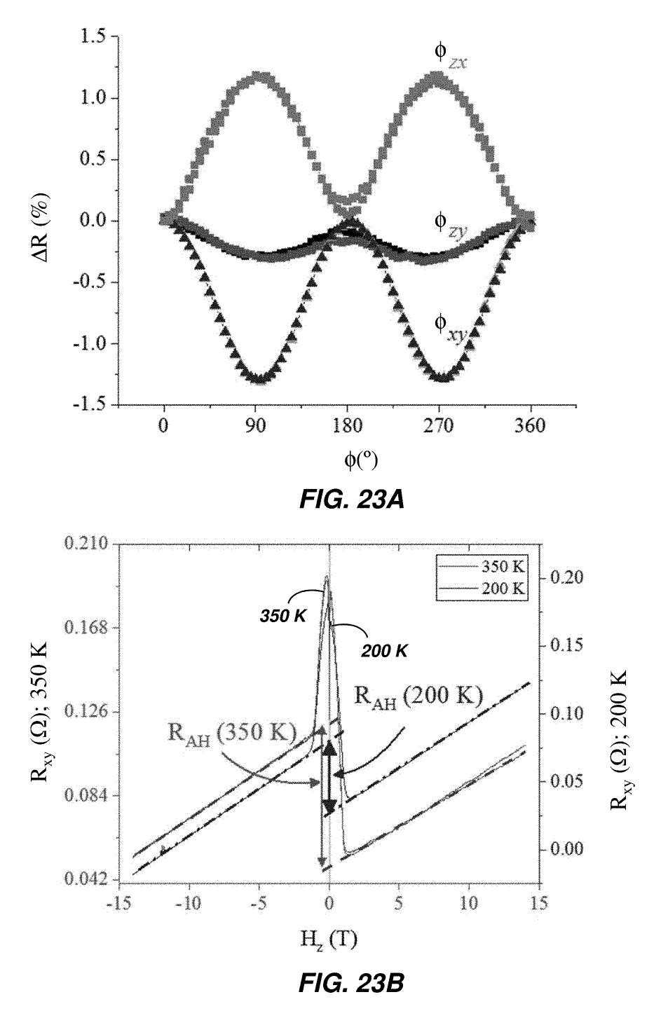

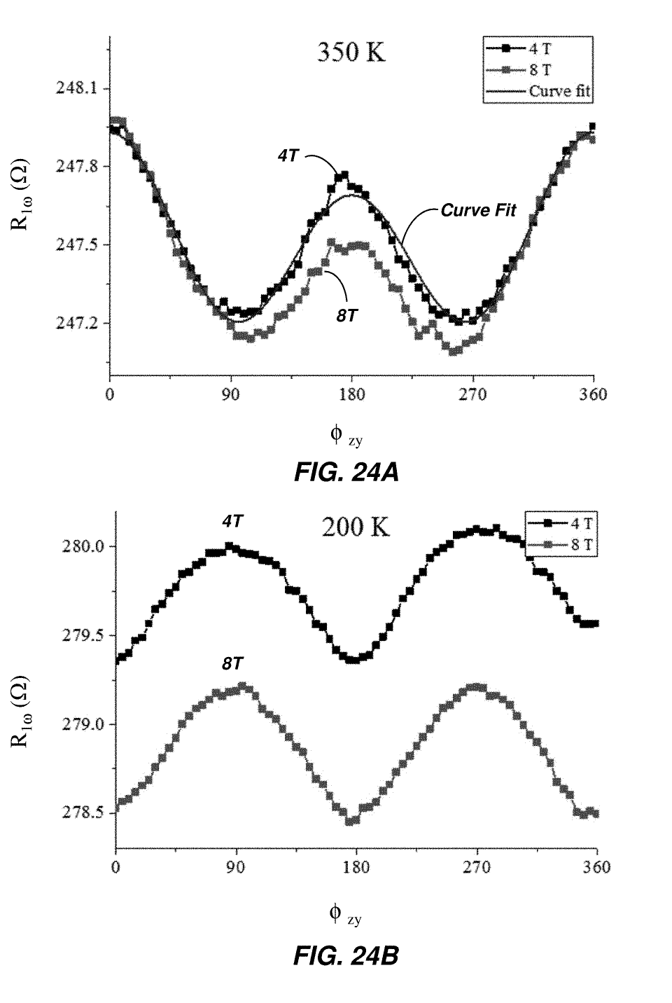

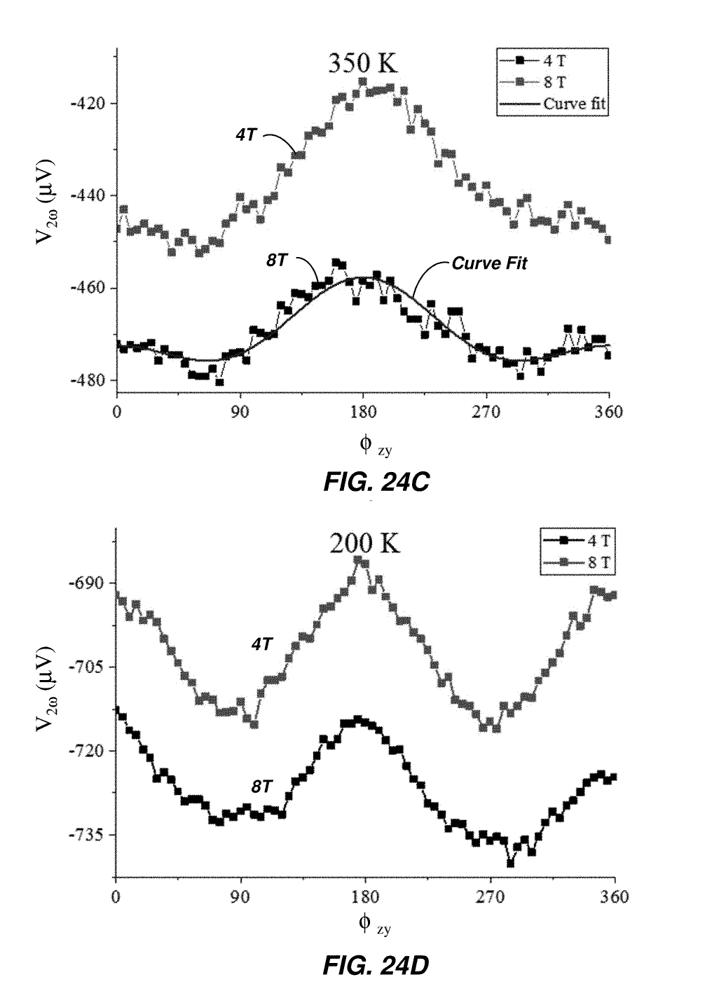

The magnetoresistance measurement at 350 K shows a response, which can be considered a combination of sin² ϕ_{zy} and cos ϕ_{zy} as shown in FIG. 23A and FIG. 24A. The dominant sin² ϕ_{zy} response originates from the SMR and this response disappears at 200 K, as shown in FIG. 24B. At 200 K, the resistance response is entirely due to AMR of the Ni₈₁Fe₁₉ layer, which is confirmed from the Ni₈₁Fe₁₉ control specimen. From the V_{2ω} response shown in FIGS. 24C-24D, the existence of ANE and SSE can be eliminated from consideration, since the sine dependence is not observed. At 350 K, a combination of sin² ϕ_{zy} and cos ϕ_{zy} behavior is observed in the V_{2ω} response. The cos ϕ_{zy} behavior is related to spin absorption due to SHE and sin² ϕ_{zy} may originate from the TAMR. The cos ϕ_{zy} behavior suggests spin current absorption when the magnetization is in z-direction and reflection when the magnetization is in the y-direction. The cos ϕ_{zy} behavior disappears at 200 K due to the phase transition.

Notably, the SMR behavior is unexpected, since the spin Hall angle of p-Si has been reported to be insignificant. Assuming spin diffusion length of 230 nm and a thickness of the p-Si of 400 nm, the spin-Hall angle (θ^{SH}) can be calculated as follows. The p-Si layer in the Pd/Ni₈₁Fe₁₉/MgO/p-Si thin film device is metallic at 350 K. Hence, θ_{SH}to can be calculated based upon SMR equation for a bimetallic. ΔRₓₓ^{SMR} is the change in resistance due to spin-Hall magnetoresistance and Rₓₓ⁰ is the base resistance.

$$\frac{Δ {R}_{xx}^{SMR}}{{R}_{xx}^{0}} ∼ - {θ}_{SH}^{2} \frac{{λ}_{N}}{d} \frac{{tanh}^{2} ( \frac{d}{2 {λ}_{N}} )}{1 + ξ} [ \frac{{ℊ}_{R}}{1 + {ℊ}_{R} coth ( \frac{d}{{λ}_{N}} )} + \frac{{ℊ}_{F}}{1 + {ℊ}_{F} coth ( \frac{d}{{λ}_{N}} )} ] \\ {ℊ}_{R} ≡ 2 {ρ}_{N} {λ}_{N} Re [ {G}_{MIX} ] \\ {ℊ}_{F} ≡ \frac{( 1 - {P}^{2} ) {ρ}_{N} {λ}_{N}}{{ρ}_{F} {λ}_{F} coth ( \frac{{t}_{F}}{{λ}_{F}} )} \\ {ρ}_{F} = 3.17 \times {10}^{- 5} Ω m \\ {λ}_{N} = 230 nm \\ Re [ {G}_{MIX} ] = {10}^{19} {Ω}^{- 1} {m}^{- 2} \\ P = 0.7 \\ {ρ}_{F} = 3.97 \times {10}^{- 7} Ω m \\ {λ}_{F} = 4 nm \\ {t}_{F} = 25 nm and \\ d = 400 nm . \qquad ( Eq . 5 )$$

From these values, it can be understood that

$$1 << {ℊ}_{R} coth ( \frac{d}{{λ}_{N}} ) and 1 << {ℊ}_{F} coth ( \frac{d}{{λ}_{N}} ) .$$

This simplifies the relationship of Equation 5 to the form of Equation 6:

$$\frac{Δ {R}_{xx}^{SMR}}{{R}_{xx}^{0}} ∼ - {θ}_{SH}^{2} \frac{{λ}_{N}}{d} \frac{2 * {tanh}^{2} ( \frac{d}{2 {λ}_{N}} )}{( 1 + ξ ) coth ( \frac{d}{{λ}_{N}} )} \qquad ( Eq . 6 )$$

### Accordingly, for

$$\frac{Δ {R}_{xx}^{SMR}}{{R}_{xx}^{0}} = 0.002 ,$$

θ_{SH} is approximately equal to 0.05.

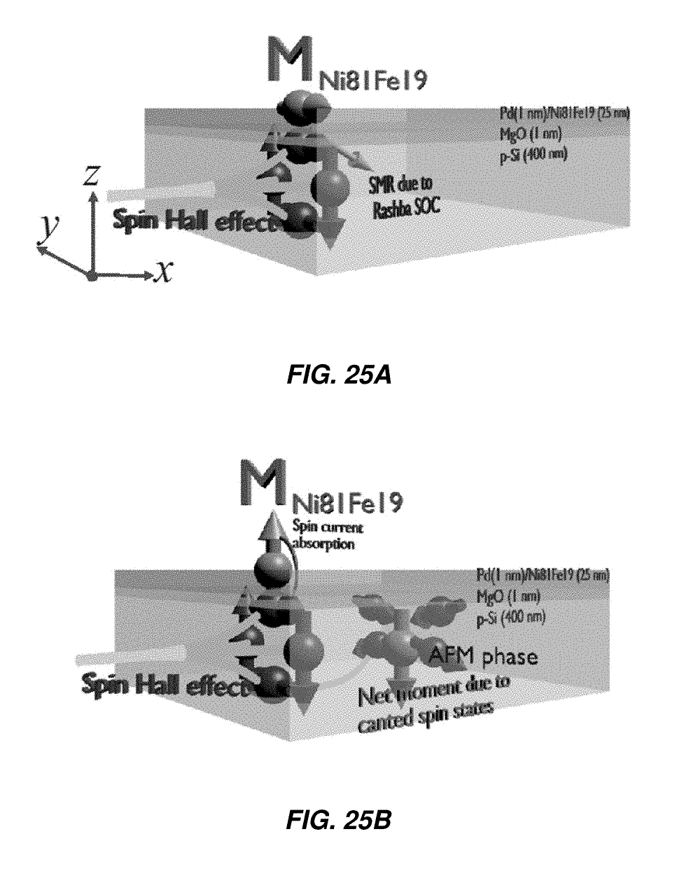

The calculated value of 0.05 for θ_{SH} is significantly larger than the value of θ_{SH}=10⁻⁴ reported for p-Si [2-14] and is of the same order as Pt [2-32]. This observation indicates that the ISHE is needed for SMR to originate from Rashba spin-orbit coupling (SOC) [2-5, 2-6] due to broken structural symmetry at the MgO/p-Si interface, as shown in FIG. 25A, and not from the bulk p-Si.

As most of the applied current is carried by the bulk Ni₈₁Fe₁₉ and p-Si layers, the observed SMR behavior is unexpected and does not originate only from the interface. To resolve this dichotomy, it is hypothesized that the p-Si exhibits intrinsic SHE, while the ISHE occurs at the interface. Notably, though, an interfacial SOC is expected to also contribute towards SSE, which is not observed. The absence of SSE can be attributed to the T_{magnon} (Ni₈₁Fe₁₉)<Tₚₕₒₙₒₙ (p-Si) [2-33], causing the spin backflow to Ni₈₁Fe₁₉ to be larger than the spin-Seebeck tunneling,. This is supported by the cos ϕ_{zy} behavior observed in the second harmonic response at 350 K (FIG. 24C). The SMR behavior is supported by the angular field rotation measurement in zx and xy-planes as shown in FIG. 23A.

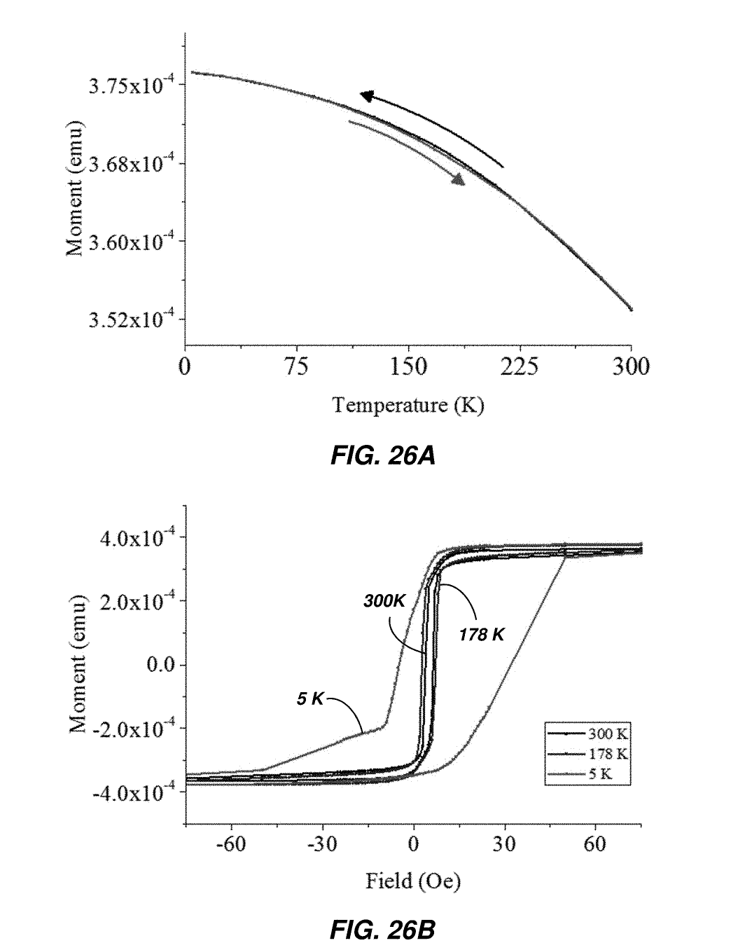

To further support this interpretation, magnetic characterization using Quantum Design magnetic property measurement system (MPMS) is performed, as shown in FIGS. 26A-26B. No phase transition in temperature dependent magnetic moment measurement is observed at a magnetic field of 20 Oe, as shown in FIG. 26A. The ferromagnetic interactions can be attributed to the proximity effect to the ferromagnetic layer. Instead, insignificant exchange bias (e.g., about 5 Oe) is observed in the magnetic hysteresis measured at 300 K, 168 K and 5 K, as shown in FIG. 26B. This is attributed to the remnant magnetization in the superconducting magnet coils employed to generate the magnetic field. The magnetic characterization eliminates Ni or Fe diffusion from Ni₈₁Fe₁₉ layer into p-Si as being the cause of observed behavior. These measurements support that the observed behavior is a transport-mediated phenomenon and not due to Fe/Ni doping or induced only by proximity effect.

To test this hypothesis, an experimental MEMS device having a Hall bar structure was fabricated to measure the change in anomalous Hall effect (AHE). The transverse resistance is measured at 350 K and 200 K as a function of magnetic field (out-of-plane) from 14 T to −14 T. The temperatures of 350 K and 200 K lie on the either side of the phase transition temperature. The AHE measurements at 350 K and 200 K exhibit a reduction in anomalous Hall resistance (R_{AH}), as shown in FIG. 23B. Using a line fit, the intercepts are identified and R_{AH} is calculated. The R_{AH} decreases from 71.91 mΩ at 350 K to 54.34 mΩ at 200 K.

From the magnetic moment measurements presented in FIG. 26A, it is understood that R_{AHE} should increase as the temperature is reduced, since the magnetic moment increases. The observed R_{AHE} behavior may arise if the spin accumulation in the p-Si leads to canted AFM states and the net moment is opposite of Ni₈₁Fe₁₉ magnetization. From the comprehensive experimental measurements presented herein, it is confirmed that the SHE induces spin polarization leads to the transition from weakly local AFM to strong global AFM behavior in p-Si. A schematic illustration of the AFM phase transition mechanism is shown in FIG. 25B. The SHE is necessary for this behavior, and hence magnetic characterization does not exhibit phase transition behavior.

### Spin-Hall Effect and Emergent Antiferromagnetic Phase Transition In n-Si

Spin current experiences minimal dephasing and scattering in Si due to small spin-orbit coupling. Spin-lattice interactions are the primary source of spin relaxation. Without being bound by theory, it is hypothesized that, if the specimen dimension is of the same order as the spin diffusion length then spin polarization will lead to non-equilibrium spin accumulation and emergent phase transition. In n-Si, spin diffusion length has been reported up to about 6 μm. The spin accumulation in Si will modify the thermal transport behavior of Si, which can be detected with thermal characterization.

Observations of spin-Hall effect and emergent antiferromagnetic phase transition behavior using magneto-electro-thermal transport characterization are discussed in detail below.

As an example, a freestanding Pd/Ni₈₁Fe₂₀/MgO/n-Si thin film device is shown to exhibit a magnetic field dependent thermal transport and spin-Hall magnetoresistance behavior attributed to the Rashba effect. The Rashba effect can arise due to a structural inversion asymmetry at the Ni₈₀Fe₂₀/n-Si interface resulting from a strain gradient present through the thickness of the n-Si. An emergent phase transition is discovered using a self-heating 3ω method, which shows a diverging behavior at 270 K as a function of temperature, similar to a second order phase transition. It is proposed that the spin-Hall effect (SHE) leads to the spin accumulation and resulting emergent antiferromagnetic phase transition. This represents the first experimental evidence of SHE in n-Si. The emergent antiferromagnetic phase transition is attributed to the site inversion asymmetry in diamond cubic Si lattice.

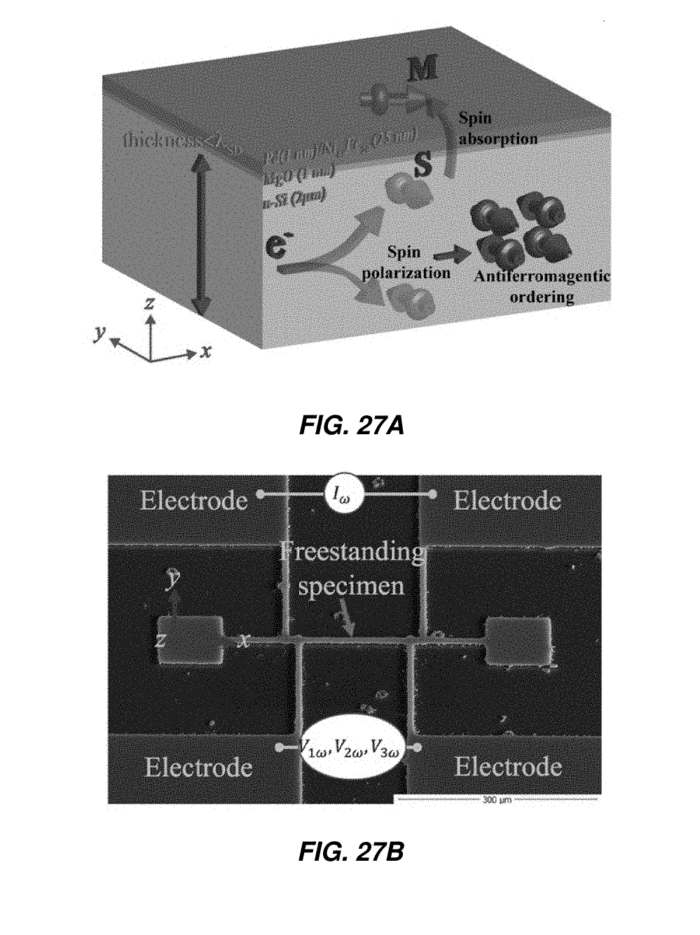

Due to small intrinsic spin orbit coupling (SOC), spin-phonon interaction is the primary spin relaxation mechanism in Si. As noted above, it is hypothesized that if the spin diffusion length is larger than the specimen dimension, spin-phonon relaxation can be suppressed and non-equilibrium spin accumulation occurs as shown in FIG. 27A. In case of Si, the spin accumulation will lead to change in phonon in thermal transport due to spin-phonon relaxation behavior. The spin diffusion length for most of the materials is less than 10 nm but that of n-Si has been measured to be up to about 6 [4-1 to 4-4]. The long spin diffusion length allows observation of the effect of spin polarization on phononic thermal transport in n-Si.

The electrical spin injection and thermal spin-Seebeck tunneling are the popular methods of spin injection in Si. It is hypothesized that electrical current across the ferromagnet/n-Si bilayer can lead to spin polarization in an n-Si layer, either due to the spin Hall effect (SHE) or due to spin-Seebeck tunneling resulting from out-of-plane temperature gradient. When an electrical bias is applied across the conducting thin film specimen, a parabolic temperature gradient develops across the length of the specimen. In addition, out-of-plane temperature gradient may occur, which may lead to spin-Seebeck tunneling. The longitudinal temperature gradient gives rise to thermal transport across the specimen and the in-plane temperature gradient can be used to characterize the thermal properties (thermal conductivity and heat capacity). The spin polarization due to SHE or spin-Seebeck tunneling in an n-Si specimen will modify the thermal transport behavior. The resulting change in thermal transport can be discovered using thermal property characterization also known as self-heating 3w method [4-5 to 4-8].

The self-heating 3ω method relies on the solution of the one-dimensional heat conduction equation for the specimen, as discussed above with respect to Equations 3 and 4. It can be inferred that the heat capacity Cₚ and thermal conductivity κ can be considered as a function of resistance and V_{3ω} response

$$( f ( κ , {C}_{p} ) ) = \frac{R}{{V}_{3 ω}} .$$

The self-heating 3ω method has been successfully applied to elucidate the spin mediated thermal transport behavior in p-Si specimens [4-9, 4-10]. The self-heating 3ω w method employs a freestanding thin film specimen to minimize the heat loss and, in turn, the error in thermal property measurement.

An embodiment of a process for forming the Pd/Ni₈₀Fe₂₀/MgO/n-Si thin film device utilizing micro/nanofabrication techniques is similar to that discussed above and illustrated in FIGS. 14A-14I. In the present context, the process differs by use of an SOI wafer including a n-Si (e.g., B-doped) device layer, rather than an n-Si device layer. Additionally, a layer of Ni₈₀Fe₂₀/Pd is deposited on MgO by e-beam evaporation instead of Ni₈₁Fe₁₉/Pd. Otherwise, the process can be the same as that discussed above. A resistivity of the n-Si device layer ranges from 0.001 Ωcm to 0.002 Ωcm. The n-Si layer has a thickness selected from 2 nm to 3 μm thick (e.g., 2 μm). The MgO layer has a non-zero thickness less than 2 nm (e.g., 1 nm). The thickness of the Ni₈₀Fe₂₀ layer is selected from 25 nm to 75 nm (e.g., 25 nm, 75 nm). The thickness of the Pd layer can be any thickness sufficient to protect the Ni₈₀Fe₂₀ layer from oxidation. As an example, the Pd layer can have a thickness of 1 nm. In certain embodiments, the thickness of the MgO layer relative to the thickness of the n-Si layer can be selected to induce a strain gradient through the thickness of the n-Si layer. The strain gradient can be sufficient to promote structural inversion symmetry within the n-Si layer at and/or adjacent to the Ni₈₀Fe₂₀/n-Si interface. One exemplary embodiment of a freestanding Pd/Ni₈₀Fe₂₀/MgO/n-Si thin film device is illustrated in FIG. 27B.

To perform the self-heating 3ω technique, an alternating current (AC) bias across the four-probe device of FIG. 27B. Measurements of the following parameters are acquired: V_{1ω} (electrical resistance), V_{2ω} (spin mediated thermoelectric effects including spin-Seebeck effect (SSE) [4-11, 4-12] and anomalous Nernst effect (ANE) [4-12]), and V_{3ω} (thermal properties) [4-9, 4-10] responses as a function of temperature and magnetic field.

The magneto-electro-thermal transport measurements are carried out using a Quantum Design physical property measurement system (PPMS) at high vacuum. In general, the self-heating 3ω method requires a cubic relationship between heating current and the corresponding V_{3ω} response. It is observed that the Pd/Ni₈₀Fe₂₀/MgO/n-Si thin film device having an Ni₈₀F₂₀ layer of 25 nm thickness deviates significantly from the cubic relationship. It is assumed that the resistance of the Ni₈₀Fe₂₀ layer will be larger than that of the 2 μm thick n-Si layer, which will keep the specimen resistance behavior Ohmic. It is observed that the n-Si layer is significantly more conducting than the Ni₈₀Fe₂₀ layer.

Although the device design is not expected to be a source of error in the cubic relationship, a second embodiment of the Pd/Ni₈₀Fe₂₀/MgO/n-Si thin film device was fabricated with a 75 nm thick Ni₈₀Fe₂₀ layer to maintain equality of current density within each layer. However, this second embodiment also does not exhibit the cubic relationship, between current and the V_{3ω} response. To identify the source of this deviation, the V_{1ω}, V_{2ω}, and V_{3ω} responses are measured as a function of temperature on the 75 nm Ni₈₀Fe₂₀ device. The temperature is varied from 300 K to 5 K at a rate of 0.3 K/min and an heating current of 1.55 mA is applied at 7 Hz.

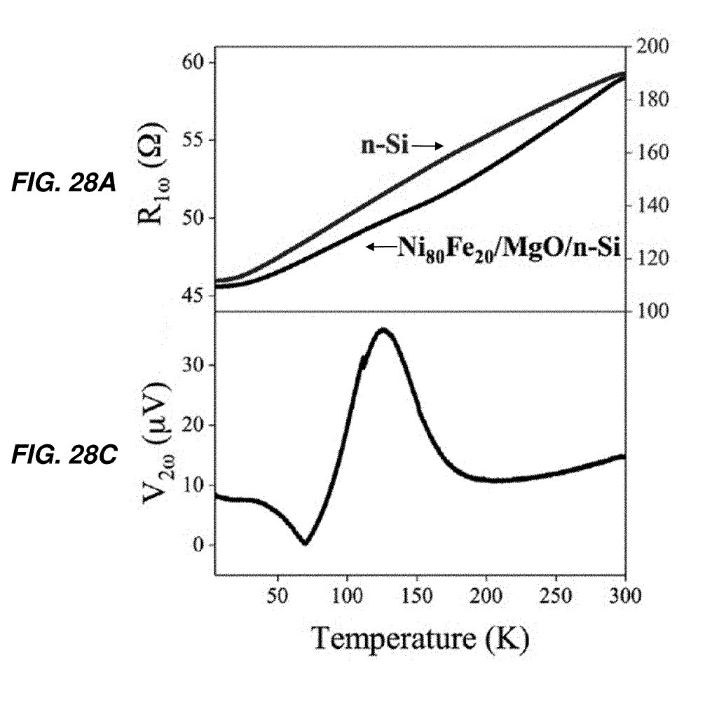

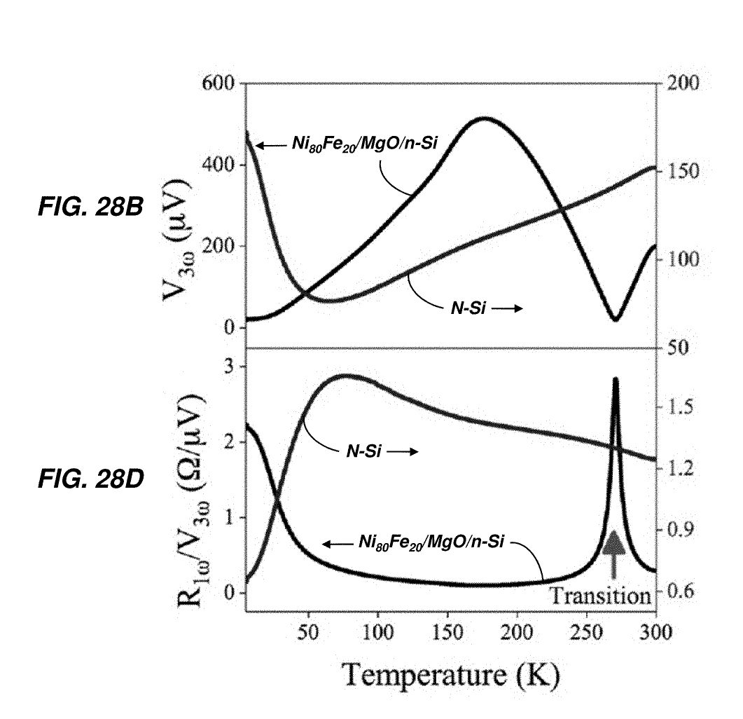

For the self-heating 3ω technique, the metallic behavior is essential and the R_{1ω}, demonstrates an Ohmic behavior, as shown in FIG. 28A. The V_{3ω} and

$$\frac{R}{{V}_{3 ω}}$$

responses, show an inflection and diverging behavior at 270 K, respectively, as shown in FIGS. 28B-28D. The Ni₈₀Fe₂₀ layer has a thermal conductivity of about 20 W/m·K [4-13], which is significantly lower than that of Si (e.g., about 80 W/m·K [4-14]). Accordingly, the observed thermal transport is attributed primarily to the Si layer only. For in-plane conduction, it is estimated that the 2 μm n-Si layer is 2000 times

$$( {R}_{thermal} = \frac{1}{κ A} )$$

more thermally conducting than the 75 nm Ni₈₀Fe₂₀ layer.

The deviation from cubic relationship between current and V_{3ω} response is attributed to this emergent behavior. Since the emergent behavior can only be observed in thermal transport measurement (the V_{3ω} and

$$\frac{R}{{V}_{3 ω}}$$

responses) and not in resistance (R_{1ω}) measurement, it originates in the n-Si layer. Around the transition phase, Equation 4 is not a good approximation to thermal conductivity and Equation 3, which also includes heat capacity, is expected to be a better approximation of thermal transport behavior.

The diverging behavior in

$$\frac{R}{{V}_{3 ω}}$$

can be considered a second order phase, transformation since second order phase transformations are characterized from singularities or discontinuities in their temperature dependent heat capacity measurements [4-15 to 4-21]. The ratio of

$$\frac{R}{{V}_{3 ω}}$$

experiences a large increase again below 50 K (FIG. 28D), indicating another gradual phase transition.

To verify if this behavior is intrinsic to n-Si, the measurements are repeated on an n-Si control specimen with 0.55 mAᵣₘₛ heating current. The control specimen exhibits the Ohmic behavior as expected for a highly doped n-Si, but it does not show transition in the V_{3ω} and

$$\frac{R}{{V}_{3 ω}}$$

responses. The temperature dependent

$$\frac{R}{{V}_{3 ω}}$$

response, shown in FIG. 28D, is similar to the thermal conductivity of highly doped n-Si reported in the literature. Comparison of two results indicates that the transition is present in the specimen with a ferromagnetic layer. Without being bound by theory, it is proposed that spin accumulation in n-Si is the underlying cause of the observed behavior. The spin accumulation leads to emergent antiferromagnetic phase transition due to site inversion asymmetry in Si.

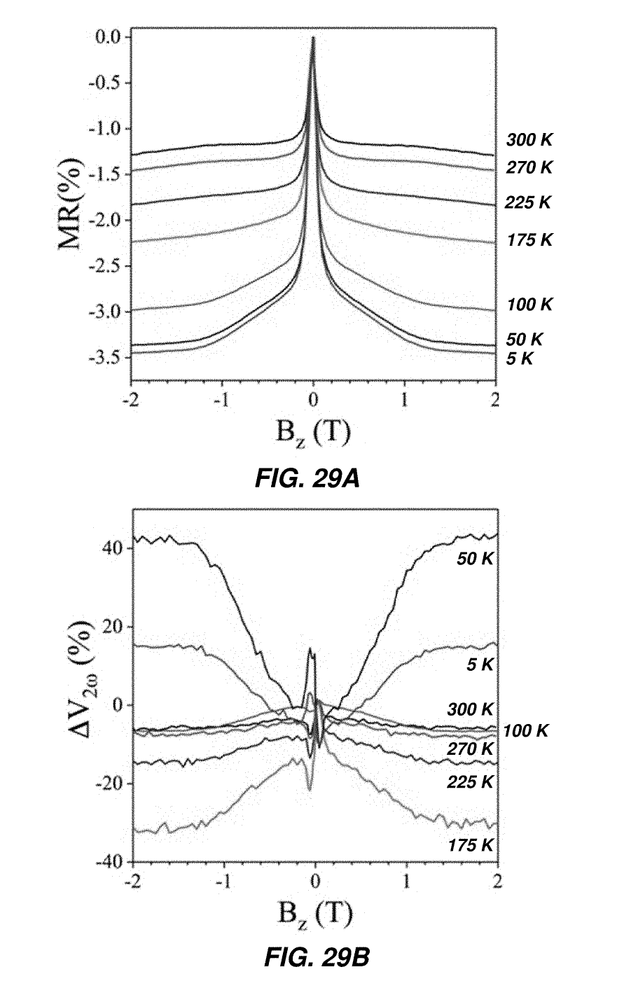

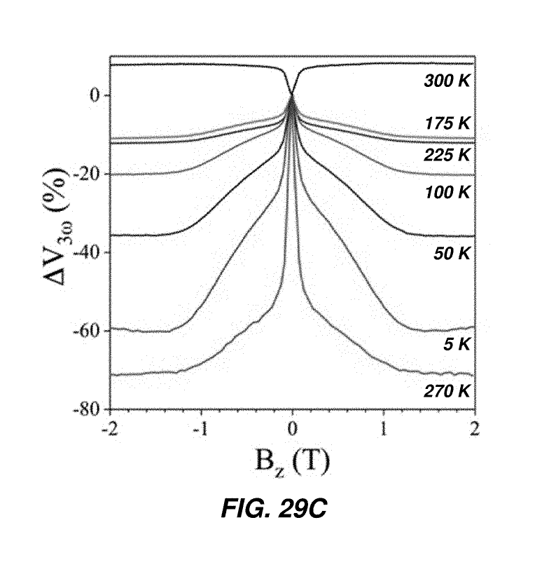

In order to identify the mechanism for the transition, magnetic field dependent measurements (V_{1ω}, V_{2ω}, V_{3ω}) are acquired for the Pd/Ni₈₀Fe₂₀ (75 nm)/MgO/n-Si thin film device. As shown in FIGS. 29A-29C, the magnetic field is varied from 2 T to −2 T and measurements are made at temperatures of 5 K, 50 K, 100 K, 175 K, 225 K, 270 K, and 300 K. The temperatures are chosen around the valley and plateau of the transition temperatures seen in the V_{3ω} and

$$\frac{R}{{V}_{3 ω}}$$

responses of FIGS. 28C-28D. The resistance of 75 nm Ni₈₀Fe₂₀ layer is estimated to be approximately 84Ω and the resistance of the n-Si layer is estimated to be approximately 190Ω.

The observed magnetoresistance behavior (FIG. 29A) pertains to the Ni₈₀Fe₂₀ layer. The magnetoresistance increases as the temperature is reduced from 300 K to 5 K. The negative magnetoresistance increases from 1.1% at 300 K to 3.375% at 5 K. Below 200 K, after the emergent transition, the observed magnetoresistance shows a knee at approximately 1.25 T, which corresponds to the saturation magnetization of Ni₈₀Fe₂₀ layer, as shown in FIG. 29A. At high temperatures of 300 K and 270 K, the device behaves similar to a soft magnetic, with saturation field of 0.3 T—four times less than the expected saturation field of Ni₈₀Fe₂₀. Since Ni₈₀Fe₂₀ is the only ferromagnetic material in the specimen, the reduction of saturation field indicates spin-orbit torque (SOT) transfer from n-Si to Ni₈₀Fe₂₀ layer. The expected saturation field of 1.25 T in Ni₈₀Fe₂₀ is seen at low temperatures of 100 K, 50 K, and 5 K, indicating absence of SOT.

In V_{2ω} sweep (FIG. 29B), the effect of Ni₈₀Fe₂₀ switching is observed. At 300 K and 100 K, V_{2ω} switching behavior is observed after crossing the zero-magnetic field, as expected for switching of ferromagnetic material. However, at 50 K and below, V_{2ω} switching occurs prior to zero magnetic field. The inverted switching behavior is attributed to the antiferromagnetic canted spin states in n-Si due to spin accumulation, which has been reported in p-Si at low temperatures [4-10].

The measured V_{3ω} dependency with field is shown in FIG. 29C. At 300 K, V_{3ω} response increases with increasing field. However, as the temperature is reduced below 270 K, the relationship inverts and the V_{3ω} response decreases with increasing field. Inversion of relationship at 270 K between external field and thermal transport behavior supports the hypothesis of emergent phase transition behavior. Maxima of V_{3ω} is seen at 170 K, agreeing with the maxima in temperature sweep from FIG. 28C. Saturation of Ni₈₀Fe₂₀ layer became suddenly profound at temperatures below 270 K, but is only gradually visible in R_{1ω}.

The difference with electrical and thermal transport can be seen by comparing the field response between V_{1ω} and V_{3ω}. Since both Ni₈₀Fe₂₀ and n-Si layers are metallic, R_{1ω} indicates the behavior of electrical transport within both layers. Whereas n-Si is the primary heat carrier in the specimen with dominant phonon population, majority of the effects seen in the V_{3ω} response is the contribution from thermal properties of n-Si. Thus, the phase transition seen in the V_{3ω} response is attributed to the n-Si layer as stated earlier. Since the transition exists only with presence of ferromagnetic layer on top of n-Si, the Ni₈₀Fe₂₀ layer induces spin accumulation in n-Si. This leads to the strong spin-phonon relaxation behavior in n-Si, which changes the phonon mediated thermal transport (since phonon is the primary spin relaxation mechanism in Si).

The spin polarization is attributed to SHE in n-Si. To confirm the presence of spin polarization within n-Si, the behavior of the V_{1ω}, V_{2ω}, V_{3ω} responses are acquired as a function of angular rotation of magnetic field in the yz-plane. If the magnetization direction of ferromagnet is orthogonal to the spin at the interface, it is expected that the spin is absorbed. If the magnetization direction is instead parallel, spin is expected to be reflected and converted back into charge current through inverse spin-Hall effect (ISHE). The reflection of spin current due to SHE from the ferromagnetic interface gives rise to spin Hall magnetoresistance (SMR) behavior [4-22 to 4-26].

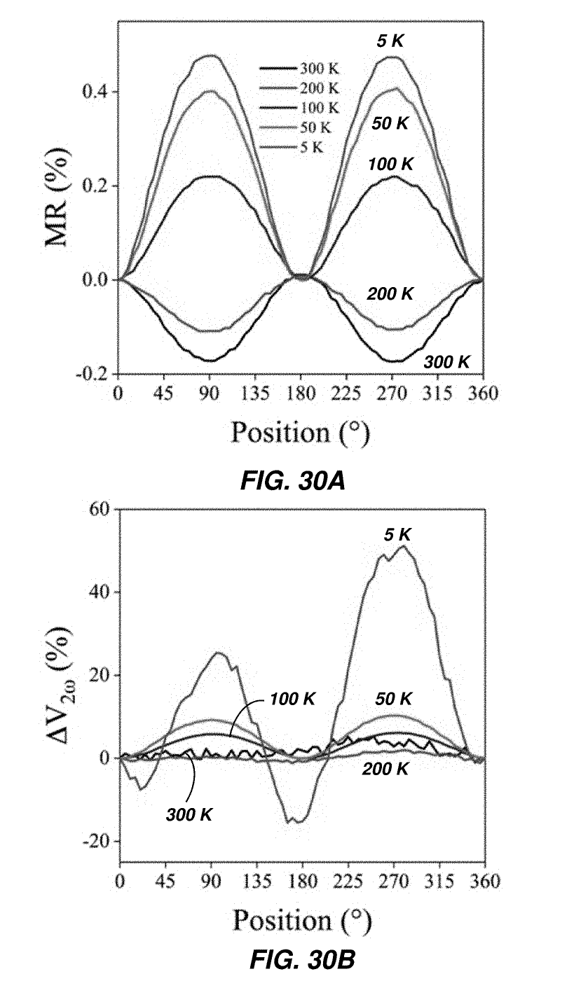

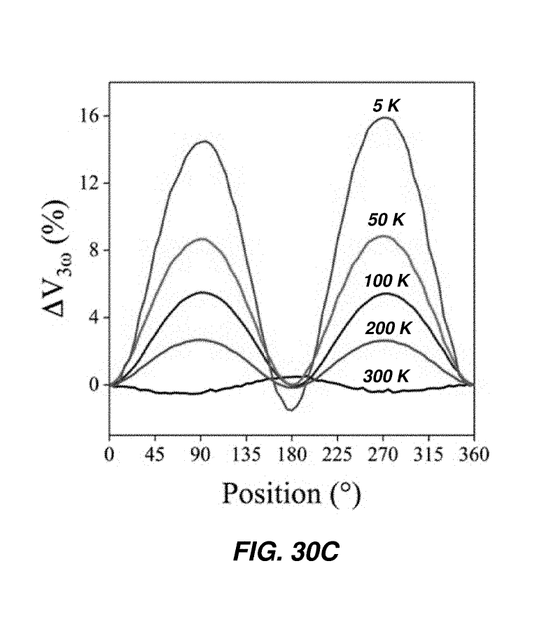

The measurements are performed in the zy-plane at 8 T at temperatures of 300, 200, 100, 50 and 5 K, and the results are shown in FIGS. 30A-30C. At 300 K and 200 K, the specimen exhibits SMR behavior, with decreasing magnitude as temperature is decreased (FIG. 30A). For temperatures below 100 K, magnetoresistance exhibits anisotropic magnetoresistance (AMR) behavior. The presence of SMR at high temperatures and AMR at low temperatures indicates both signals occur simultaneously, but the dominant phenomena for the overall signal is dependent on the specimen temperature. The origin of SMR is believed to be from n-Si, since SMR behavior cannot originate from spin tunneling (spin-Seebeck tunneling or electrical injection) from the Ni₈₀Fe₂₀ layer. In addition, n-Si has insignificant intrinsic spin-orbit coupling. Hence, inverse spin-Hall effect (ISHE) and SMR behavior arising intrinsically in n-Si is not expected to be observable.

Without being bound by theory, it is proposed that the interfacial spin-orbit coupling gives rise to the ISHE and SMR observed herein. The sinusoidal behavior expected for SSE and ANE is not observed in the V_{2ω} response (FIG. 30B). Instead, a dominant sin²θ_{zy} behavior in the V_{2ω} response, which can be attributed to the spin-phonon interactions [4-9] due to SHE. In addition, the observed V_{2ω} response can arise from the Rashba effect mediated tunneling anisotropic thermopower [4-27].

While the transition from SMR to AMR occurs below 200 K, the emergent phase transition V_{3ω} response is observed below 300 K, similar to temperature dependent measurement. At 300 K, a sin²θ_{zy} behavior is observed in the V_{3ω} response with negative amplitude. The magnitude shows a sign reversal as the temperature is lowered to 200 K. The amplitude increases with decrease in temperature, as shown in FIG. 30C. The observed behavior is attributed to the SHE mediated thermal resistance, and IS hence called a spin-Hall magneto thermal resistance (SMTR) [4-9].

From these measurements, it is proposed that the SHE in n-Si causes non-equilibrium spin accumulation due to proximity with Ni₈₀Fe₂₀ layer. The spin accumulation leads to the observed emergent antiferromagnetic phase transition behavior as hypothesized (FIG. 27A). The emergent antiferromagnetic phase transition is attributed to the site-inversion asymmetry in inversion symmetric diamond cubic lattice of n-Si [4-28, 4-29]. The emergent antiferromagnetic phase transition changes the magneto-thermal transport behavior, as shown in FIGS. 28C-28D. The applied magnetic field causes dephasing of spin excitations in emergent antiferromagnetic phase and changes spinphonon relaxation behavior. This enhances the thermal transport behavior at low temperatures, as observed in reduction in V_{3ω} response.

The observation of SHE is supported by the SMR measurements at 300 K and 200 K. This is the first experimental proof of SHE in n-Si. The SMR behavior disappears at low temperatures due to emergent antiferromagnetic phase transition. However, n-Si does not have intrinsic spin-orbit coupling. It is proposed that the ISHE, which is necessary for SMR behavior, occurs at or near the interface of Ni₈₀Fe₂₀/MgO/n-Si. This interface gives rise to structure inversion asymmetry and in turn Rashba spin-orbit coupling [4-30, 4-31, 4-32]. The spin-orbit coupling due to structure inversion asymmetry in Si metal-oxide semiconductor field effect transistor (MOSFET) has been reported in magneto-transport behavior in two-dimensional electron gas (2DEG) in at low carrier concentrations [4-33 to 4-36].

In addition, spin resonance measurements on Si metal-oxide semiconductor field effect transistor (FET) report suppression of spin resonance due to SOC [4-37]. This behavior agrees with the proposed hypothesis presented herein due to ferromagnetic metal-oxide-Si interface, except this behavior is observed at higher charge carrier concentrations. For strong Rashba SOC, the essential requirements are structure inversion asymmetric interface and intrinsic SOC. In the Si MOSFET, the SOC due to structure inversion asymmetry is relatively small because the gate metals have small intrinsic SOC. As discussed herein, n-Si has insignificant intrinsic SOC but Ni₈₀Fe₂₀ has significantly large intrinsic SOC [4-38], which may give rise to the strong Rashba SOC due to proximity effect [4-3, 4-39].

This poses a problem, since Rashba effect is expected at two-dimensional electron gas (2DEG) or nanoscale thin films (few nanometer), whereas n-Si thickness in this study is 2 μm. The length scale for Rashba effect is currently unknown. It is proposed that the length scale for Rashba spin-orbit coupling can be as large as the spin diffusion length in semiconductor or normal metal, which is supported by the observed experimental results. The observed Rashba effect may challenge the non-local spin transport measurement [4-1, 4-3, 4-40] in Si, since Rashba effect may enhance the spin polarization.

### Strain-Mediated Rashba Spin Orbit Coupling in N₈₀Fe₂₀/MgO/p-Si Thin Film Devices

Silicon can be a promising material for spintronics due to long spin diffusion length at room temperature. However, insignificant intrinsic spin-orbit coupling leads to small inverse spin-Hall effect, which is a bottleneck for the realization of Si spintronics. Rashba spin-orbit coupling induced due to strain, proximity effect and structural inversion asymmetry can be used to overcome this shortcoming. As discussed in detail below, strain mediated strong cubic Rashba spin orbit coupling is demonstrated in a Ni₈₀Fe₂₀/MgO/p-Si thin film device. The cubic Rashba spin-orbit coupling lifts the spin degeneracy of band structure introducing intrinsic spin-Hall effect, which is uncovered using spin-Hall magnetoresistance. The strain effects are uncovered by current dependent resistance change attributed to the change in interfacial strain and piezoresistance behavior of p-Si. The spin polarization predominantly occurs along the <110> direction indicating that the cubic Rashba leads to intrinsic spin-Hall effect. The cubic Rashba spin splitting causes non-equilibrium spin accumulation leading to a second order antiferromagnetic phase transition. These results demonstrate that strain can be used to control the spin-Hall effect and, in turn, spin polarization in Si.

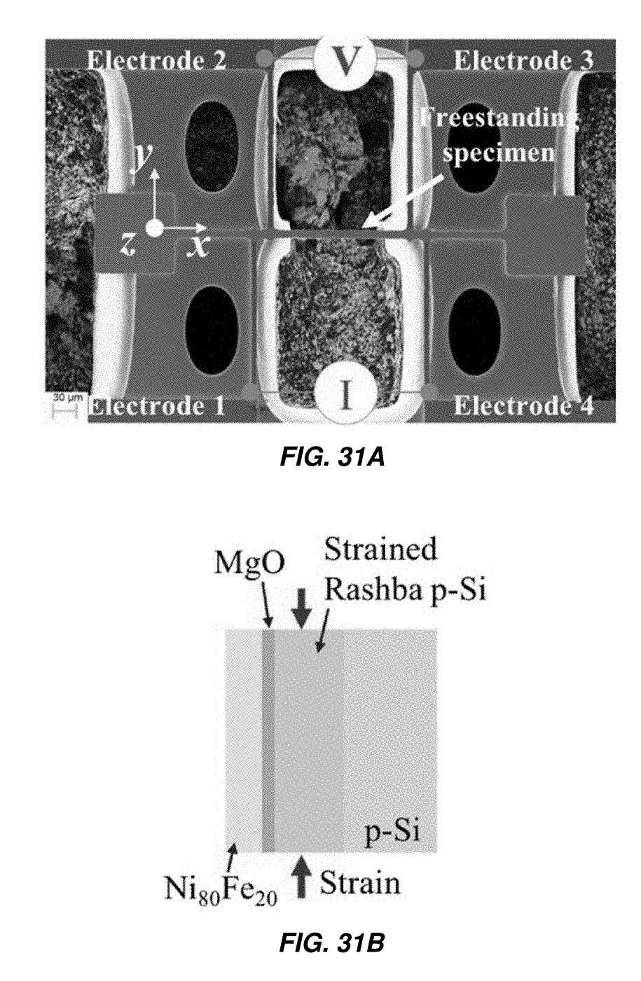

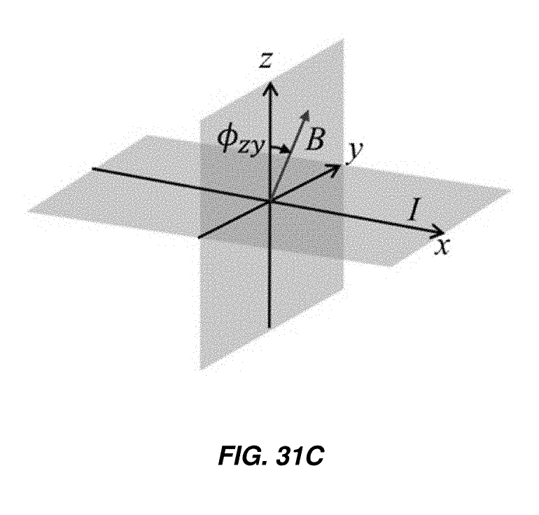

Spin-Hall magnetoresistance (SMR) is a widely used SHE characterization technique. For SMR measurement, a four-probe longitudinal resistance measurement setup having freestanding Pd/Ni₈₀Fe₂₀/MgO/p-Si thin film device. In an embodiment, a process for forming the Pd/Ni₈₀Fe₂₀/MgO/p-Si thin film device utilizing micro/nanofabrication techniques is similar to that discussed above and illustrated in FIGS. 14A-14I. In the present context, a layer of Ni₈₀Fe₂₀/Pd is deposited on MgO by e-beam evaporation instead of Ni₈₁Fe₁₉/Pd. Otherwise, the process can be the same as that discussed above. A resistivity of the p-Si device layer ranges from 0.001 Ωcm to 0.005 Ωcm. The p-Si layer has a thickness selected from 2 nm to 3 μm thick (e.g., 2 μm). The MgO layer has a non-zero thickness less than 2 nm (e.g., 1 nm). The thickness of the Ni₈₀Fe₂₀ layer is selected from 5 nm to 200 nm (e.g., 25 nm). The thickness of the Pd layer can be any thickness sufficient to protect the Ni₈₁Fe₁₉ layer from oxidation. As an example, the Pd layer can have a thickness of 1 nm. The MgO layer promotes efficient spin tunneling and inhibits diffusion, while the Pd layer inhibits oxidation of the Ni₈₀Fe₂₀ layer. In certain embodiments, the thickness of the MgO layer relative to the thickness of the p-Si layer can be selected to induce a strain gradient through the thickness of the p-Si layer. The strain gradient can be sufficient to promote structural inversion symmetry within the p-Si layer at and/or adjacent to the Ni₈₀Fe₂₀/p-Si interface. One exemplary embodiment of a freestanding Pd/Ni₈₀Fe₂₀/MgO/p-Si thin film device is illustrated in the false-color scanning electron micrograph of FIG. 31A.

For the experimental work, it is hypothesized that the strain and structural inversion asymmetry (SIA) induced Rashba SOC will lead to a Rashba layer as shown in FIG. 31B, which will give rise to SMR or Rashba-Edelstein magnetoresistance (REMR). The thermal mismatch and residual stresses at the interface causes the strain . In the Pd/Ni₈₀Fe₂₀/MgO/p-Si system, charge-to-spin conversion is caused by Rashba SOC, which promotes either SHE, Rashba-Edelstein effect (REE), or both. Likewise, spin-to-charge conversion is caused by either ISHE, inverse Rashba-Edelstein effect (IREE), or both. By applying a magnetic field to control the magnetization of Ni₈₀Fe₂₀, spin absorption and reflection at the Ni₈₀Fe₂₀ interface is manipulated leading to modulation in the specimen resistance. The resistance modulation can be measured using angular rotation of a constant magnetic field. Though field rotation in all the three-principal planes is used to quantify the SMR and REMR behavior, but the rotation in the yz-plane (field always perpendicular to the direction of current) is the primary source for identification of SMR and REMR behavior. Since the symmetry of SMR and REMR is same, the observed behavior is referred to as SMR herein.

The experiments for SMR and REMR measurements are performed in Quantum Design's Physical Properties Measurement System (PPMS). The transport properties are measured using an alternating current (AC) technique. An AC bias is applied across the outer electrodes from Keithley 6221 current source and voltage drop is measured using Stanford Research Systems SR830 lock-in amplifier. The Ni80Fe₂₀ thin film exhibits an out of plane anisotropic magnetoresistance (OP-AMR) in yz-plane due to size effect. Hence, the specimen magnetoresistance (MR) will be a superposition of SMR from Rashba Si layer and OP-AMR from Ni80Fe20. The angular modulation in resistance due to OP-AMR and SMR can be written in the form of Equation 7:

R=Rₒ+(ΔR_{OP-AMR}−ΔR_{SMR})sin²ϕ_{xy} (Eq. 7)

The SMR and REMR exhibit the same symmetry behavior and cannot be differentiated. However, the contribution of OP-AMR can be extracted from SMR using magnetic field dependent angular measurement. Notably, the OP-AMR is a function of applied magnetic field, while SMR is not. Using field rotation in the yz-plane as a function of magnetic field and applied current, the SMR and OP-AMR can be identified as shown in FIG. 31C.

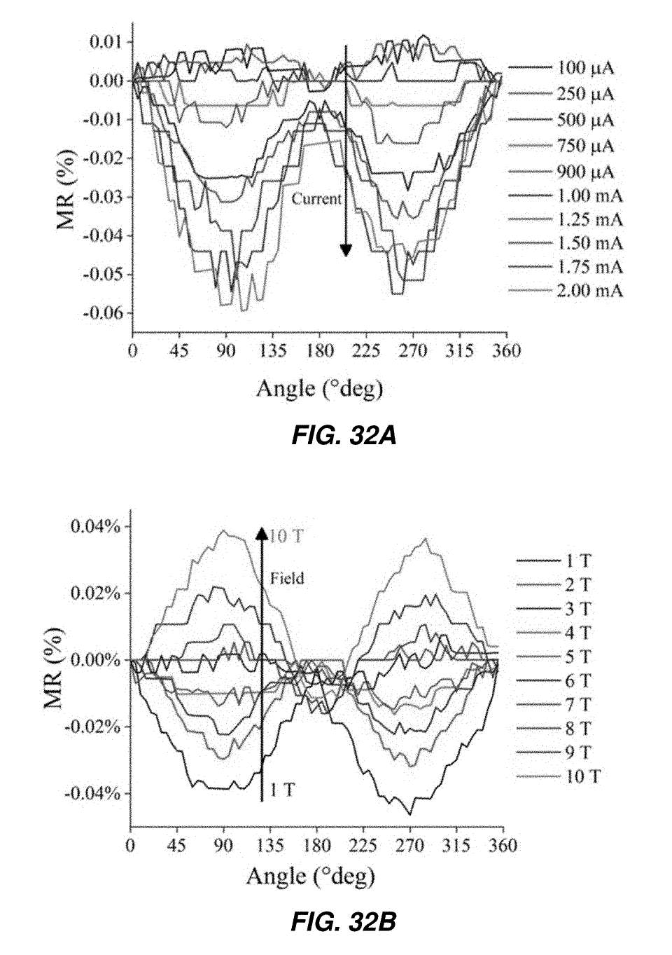

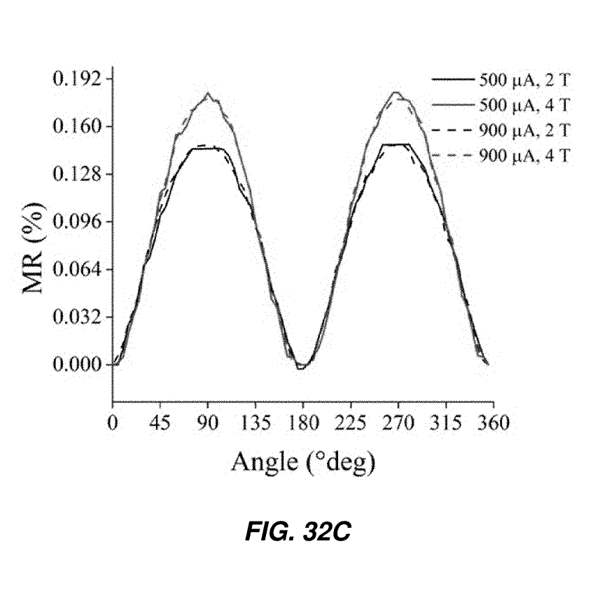

Field rotation measurements are performed at a constant magnetic field of 4 T and at an applied current from the range of 100 μA to 2 mA. The results are illustrated in FIG. 32A. At 100 μA, a weak MR behavior, having polarity similar to OP-AMR, is observed. At 500 μA, the MR behavior diminishes completely and further increase in current leads to change in polarity, which can be attributed to increasing contributions from SMR. Traditionally, SMR is not considered to be function of applied current, which makes this current dependent behavior unexpected.

The competition between SMR and OP-AMR is further seen by measuring specimen resistance at constant current of 900 μA while increasing the magnetic field from 1 T to 10 T, as shown in FIG. 32B. At low fields, the MR behavior displays polarity similar to SMR, indicating weak AMR. The MR behavior again diminishes at 6 T and changes polarity with further increase in strength of the applied magnetic field to 10 T.

Similar angular measurements are undertaken at 200 K to investigate the effects of temperature. The R_{1ω} under combination of 2 T, 4 T and 500 uA, 900 uA are shown in FIG. 32C. At 200 K, R_{1ω} exhibits only AMR behavior, which is (0.17% for 8 T) approximately ten times stronger as compared to 300 K (0.01% for 8 T). In addition, R78 loses its dependency with applied current. This measurement indicates a transition leading to absence of SMR and REMR behavior at 200 K. It is noted that unidirectional SMR and unidirectional REMR is not observed in the second harmonic responses.

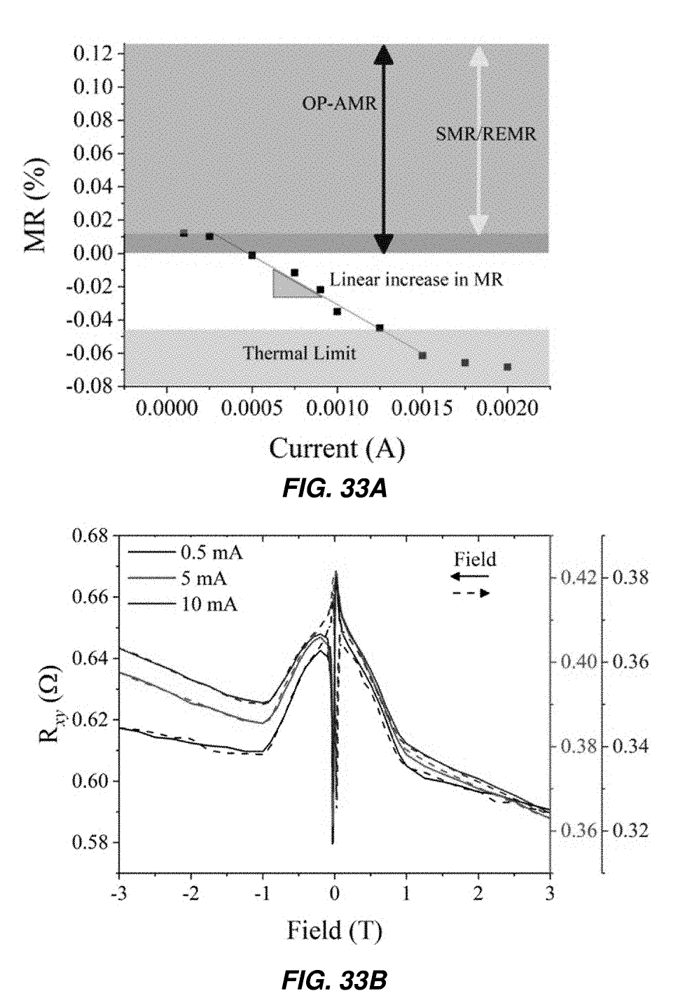

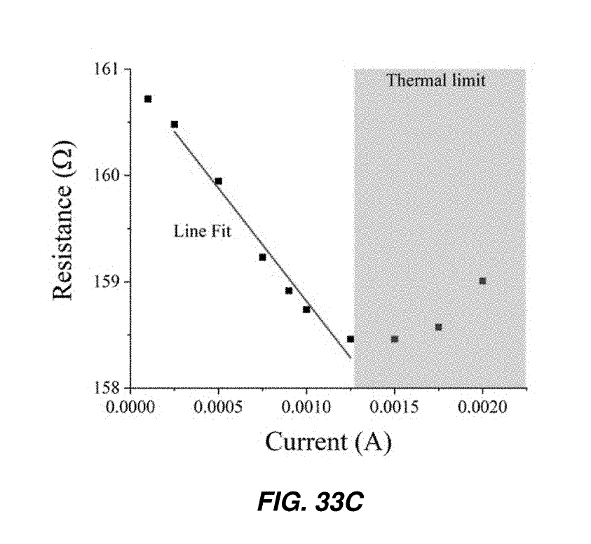

The contribution of SMR can be estimated using thickness dependent measurement. Unlike deposited thin film specimen, single crystal Si layer makes thickness dependent measurement difficult. To quantify the SMR behavior, the current dependent MR measurement is analyzed. The amplitude of MR at each current is calculated using a sine square curve fit. The MR as a function of current is shown in FIG. 33A. The MR shows insignificant change when the current is increase from 100 μA to 250 μA.

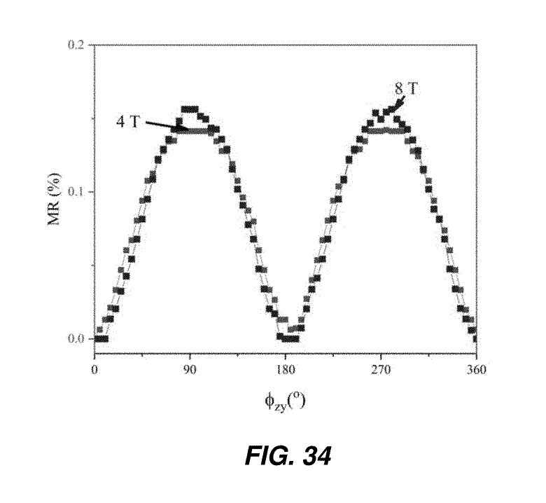

The resulting MR behavior will only be a function of OP-AMR and SMR. The OP-AMR of a Ni80Fe20 control specimen is also measured, and the results are illustrated in FIG. 34. The charge current across Ni80Fe20 and p-Si layers is 0.57% and 0.43% respectively. Assuming two parallel resistors (Ni80Fe20 and p-Si layers), the OP-AMR is estimated to be 0.125% at 4 T for the Pd/Ni₈₀Fe₂₀/MgO/p-Si thin film device. This estimate is consistent with the OP-AMR behavior observed at 200 K. Whereas the observed MR at 100 μA and 250 μA currents is ˜0.01% (FIG. 32A). Based on OP-AMR, the reduction in MR in the Pd/Ni₈₀Fe₂₀/MgO/p-Si thin film device is believed to be due to SMR of magnitude 0.115%. As the current is increased from 500 μA to 1.25 mA, the MR increases almost linearly as a function of current. The calculated SMR value is observed to be significantly larger than the reported for Pt. [6-46]

A saturation in MR is observed when the current is increased from 1.25 mA to 2 mA. This saturation is attributed to enhanced spin relaxation due to Joule heating, as shown in FIG. 32C. The linear increase in the MR as a function of current is not expected for either of the two OP-AMR or SMR. As stated above, Rashba SOC is expected to give rise to the SMR behavior observed herein. The k-linear Rashba SOC results into zero spin Hall conductivity, while cubic Rashba SOC can give rise to SMR behavior. In semiconductors, cubic Rashba SOC is reported to be predominant [6-24]. The cubic Rashba SOC can also give rise to spin accumulation, while k-linear Rashba SOC does not [6-24]. The spin accumulation in the p-Si layer may lead to anomalous Hall effect resistance (RAHE).

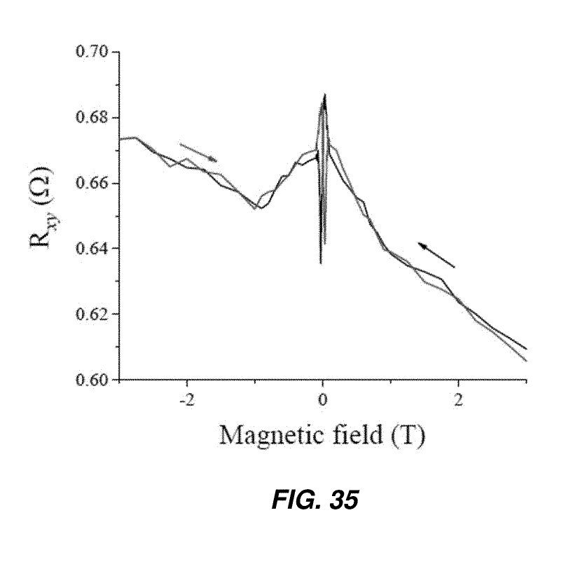

To uncover the quantum of spin accumulation, a device having a Hall bar geometry was fabricated and measurements of RAHE are acquired at 300 K as a function of current (FIG. 33B). The RAHE for 0.5 mA is measured to be 10.8 mΩ, which reduces to 6.12 mΩ at 5 mA and Further to 5.45 mΩ at 10 mA of current. an increase in temperature by 75 K is estimated due to Joule heating at 10 mA, based on change in resistance. The RAHE at 375 K is also measured and found to be 9.62 mΩ, as shown in FIG. 35. Hence, heating cannot give rise to reduction in RAHE and only spin accumulation in p-Si layer is responsible for the observed behavior. The current dependent spin accumulation can only arise due to cubic Rashba SOC. These experimental results presented so far clearly support SHE, cubic Rashba SOC and spin accumulation. The low field switching can be attributed to the Planar Hall effect (PHE).

The longitudinal resistance of the specimen is also a function of applied current, as shown in FIG. 33C. The resistance decreases as the applied electric current is increased from 100 μA to 1.25 mA. After 1.25 mA, the longitudinal resistance starts to increase, which is attributed to the Joule heating effects or thermal limit as shown in FIG. 33C. The current dependent decrease in resistance is not entirely unexpected for Si since it displays strong piezoresistive behavior. For the freestanding specimen, the increase in current may lead to increase in thermal mismatch at the interface causing enhanced strain in this study, which in turn changes the resistance as well. The strain induced cubic Rashba SOC can give rise to intrinsic SHE [6-25 to 6-28], which arises due to band structure, instead of impurities. The change in strain also drives the cubic Rashba SOC leading to linear increase in the SMR behavior observed in current dependent SMR measurement, as shown in FIG. 32B and FIG. 33A.

To uncover the origin of SHE, analysis and review of the literature for different techniques was performed. The extrinsic SHE is isotropic with respect to the crystallographic orientation, while intrinsic SHE is not. Recent work on Si quantum dots reports Rashba SOC at the SiO2/Si interface [6-29]. In this work, Jock et al. used interface-SO coupling for a critical control axis in a double-quantum-dot singlet-triplet qubit. Their measurement demonstrates magnetic field orientation dependence of the g-factors, which is consistent with Rashba and Dresselhaus interface-SOC having maxima in the Si <110> direction.

It is hypothesized that the spin polarization due to cubic Rashba SOC may have a similar maximum when the current is applied along the Si <110> direction as compared to any other direction. In a p-doped Si(100) wafer, the <110> direction is normal to the wafer flat and the <100> direction lies at 45° to it.

In order to ascertain the crystallographic direction dependent behavior, a set of Ni80Fe20 (25 nm)/MgO (1 nm)/p-Si (2 μtm) thin film devices are fabricated. The longitudinal direction of Si layer of the these devices lies along <110>, at 15°, at 30 °, and at 45°, angle with respect to <110> direction. MR is also measured as a function of out of plane magnetic field from 3 T to -3 T. It is hypothesized that the spin orbit torque (SOT) due to Rashba SOC and SHE will lead to changes in out of plane MR.

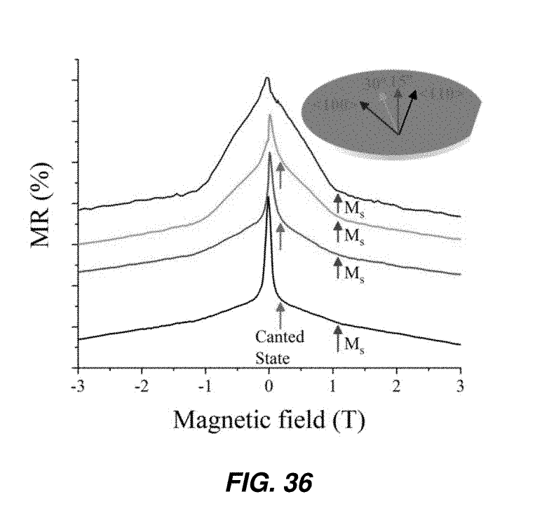

The negative MR for current applied along the Si layer oriented in <110> direction is 1.7% at 3 T magnetic field, as shown in FIG. 36, and it has two kinks due to change in slope. The kink at approximately 1.1 T corresponds to the saturation magnetization (4πMₛ). The kink at approximately 0.2 T and at 1.16% of negative MR is not expected for Ni₈₀Fe₂₀ thin film hard axis magnetization. This kink can be attributed to the canted state due SOT generated from Rashba effect and SHE. The SOT leads to observed switching behavior instead of gradual decrease in MR expected for hard axis behavior. The MR measurement at an angle of 15°, as shown in FIG. 36, exhibits a behavior qualitatively similar to the <110> direction. However, the resistance is lower and the negative MR is calculated to be 1.36%. The kink corresponding to proposed canted state occurs at ˜0.2 T and at negative MR of 0.7%. For a p-doped Si (100) wafer, the mobility is highest for <110> and lowest for <100> direction (30). Hence, the lower resistance observed for 15° from <110> direction is unexpected and is unidentified.

Negative MR of 1.44% for current applied at 30 degrees from <110> direction is also measured, as shown in FIG. 36. In this measurement, the negative MR for the proposed canted state is approximately 0.5%, which clearly indicates reduction in SOT. For measurement along <100> direction or at 45 degrees from <110>, a qualitative change in the MR behavior is observed. The negative MR is approximately 1.6% and the low field kink is absent. The MR response shows a gradual change similar to Ni₈₀Fe₂₀ thin film hard axis behavior, which indicates the absence of any spin current or SOT from the p-Si layer.

The direction dependent behavior can be attributed to the spin polarization in Si. This demonstrates that the spin current is intrinsic to p-Si, since it is a strong function of crystallographic direction. The polarization or SHE occurs only when the current is along the <110> and not when the current is along <100> direction. Based on these results, it is proposed that the strain induced cubic Rashba SOC gives rise to spin polarization and intrinsic SHE in p-Si layer (6-24, 6-25, 6-31). These results can also explain recent observation of giant spin-Seebeck effect in Si (6-32, 6-33).

From the SMR measurement, a transition between 300 K and 200 K is identified. The spin accumulation at the interface may give rise to non-equilibrium emergent spin liquid phase transition. The emergent phase transition behavior due to cubic Rashba SOC can be studied using thermal transport measurements. Thin films thermal transport behavior can be characterized using self-heating 3ω method (6-34) as demonstrated recently(6-35 to 6-37), and as discussed above. The 3ω method is derived from one-dimensional heat conduction equation and leads to the approximate equation of Equation 4.

The V_{3ω} is a function of both thermal conductivity and heat capacity. The heat capacity and thermal conductivity can be considered as a function of resistance and V_{3ω} response

$$( f ( κ , {C}_{p} ) ) = \frac{R}{{V}_{3 ω}} [ 6 \text{-} 33 to 6 \text{-} 35 ] .$$

The second order phase transition leads to diverging behavior in heat capacity [6-38 to 6-44], which leads to diverging behavior in the

$$\frac{R}{{V}_{3 ω}}$$

response as well.

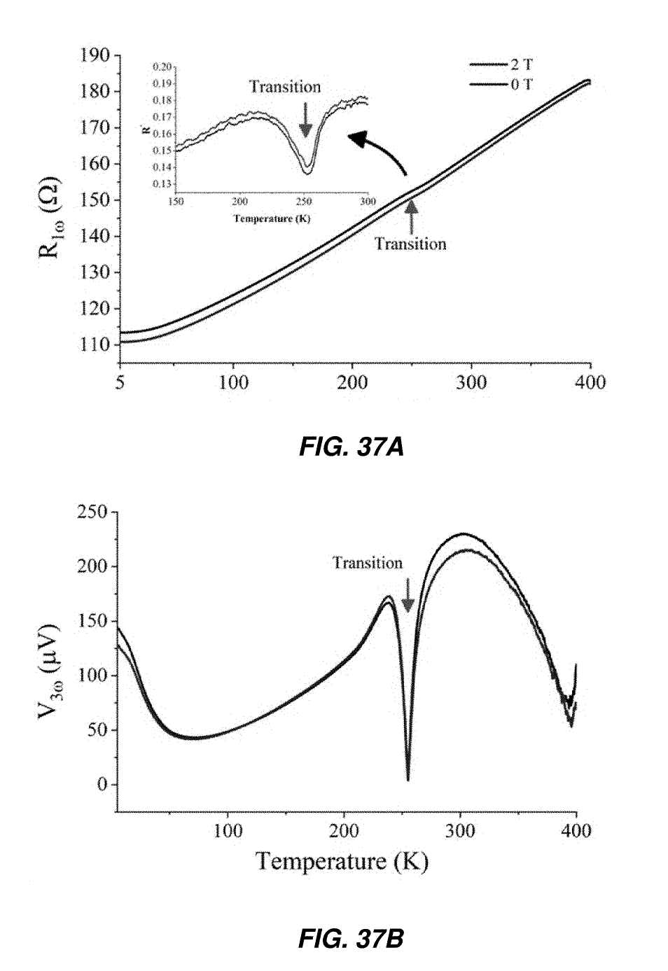

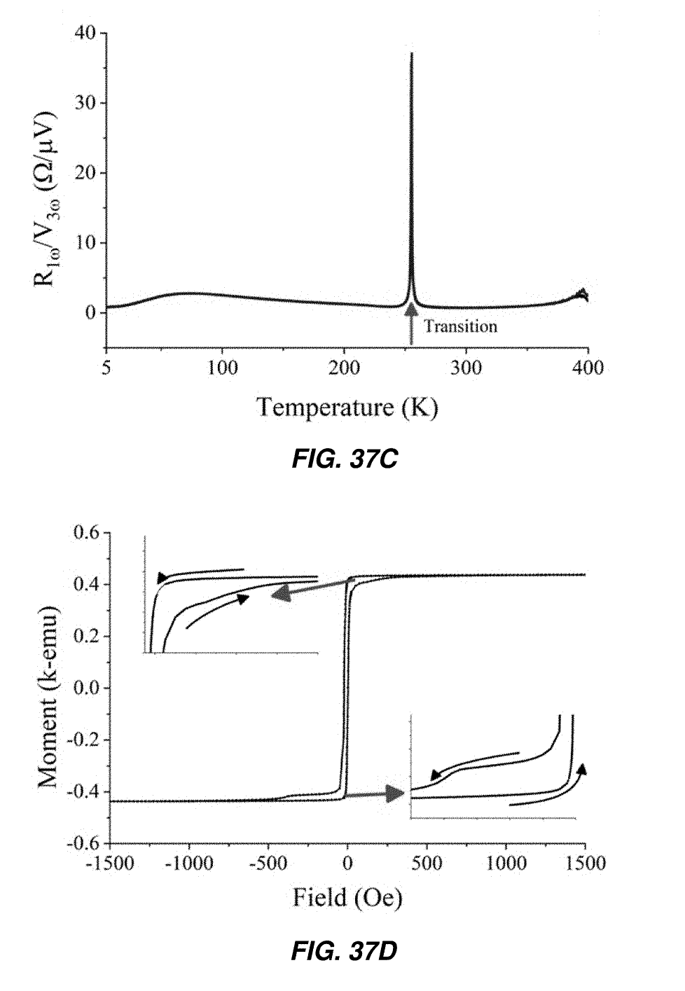

The longitudinal R_{1ω} and V_{3ω} responses are acquired with cooling rate of 0.4 K/min with zero magnetic field and an out-of-plane applied magnetic field of 2 T, as shown in FIGS. 37A-37B. The R_{1ω} as a function of temperature clearly shows metallic behavior, with and without magnetic field. A small inflection is observed at 255 K under an applied external field. This can be clearly seen from the graph of R′, as shown in the inset of FIG. 37A. The thermal transport behavior of the specimen is examined with V_{3ω}, as shown in FIG. 37B. The V_{3ω} response at zero field measures 70 μV at 400 K, increasing to a maxima of 230 μV at 300 K, and decreasing sharply to 4 μV at 255 K, which is the same temperature of inflection in R_{1ω} response. The V_{3ω} response then increases sharply to 167 μV at 240 K, decreases to 43 μV at 70 K and settles at 144 μV at 5 K. The out-of-plane magnetic field does not change the V_{3ω} response significantly.

To uncover the phase transition, the

$$\frac{R}{{V}_{3 ω}}$$

response is analyzed, which shows a diverging behavior at 255 K, as shown in FIG. 37C. The out-of-plane magnetic field shifts the

$$\frac{R}{{V}_{3 ω}}$$

response peak by 0.255 K. This diverging behavior in the

$$\frac{R}{{V}_{3 ω}}$$

response is attributed to the second order phase transition, as hypothesized.

The cubic Rashba SOC due to strain and SIA lead to non-equilibrium spin accumulation, which in turn give rise to the phase transition behavior. The observed phase transition is non-equilibrium phase. While cubic Rashba SOC is clearly supported by the observation of SMR. In order to uncover the ferromagnetic proximity effect, magnetic characterization of another Pd/Ni₈₀Fe₂₀/MgO/p-Si thin film device using Quantum Design's magnetic properties measurement system (MPMS). The magnetic hysteresis behavior is measured at 5 K for an in-plane magnetic field as shown in FIG. 37D. No shift in the hysteresis due to exchange bias is observed, which is attributed to the presence of MgO layer at the interface. However, the magnetic hysteresis behavior clearly demonstrates an effect similar to exchange bias system reported in ferromagnetic/insulator/semiconductor heterostructures [6-45]. The ferromagnetic proximity effect supports the hypothesis of antiferromagnetic interactions leading to spin-liquid phase transition behavior in the Rashba Si layer.

### Spin Seebeck Effect and Thermal Spin-Orbit Torque In Ni₈₀Fe₂₀/p-Si Bilayers

The development of spintronics and spin-caloritronics devices can benefit from efficient generation, detection and manipulation of spin current. The thermal spin current from the spin-Seebeck effect has been reported to be more energy efficient than the electrical spin injection methods. However, spin detection has been the one of the bottlenecks since metals with large spin-orbit coupling is an essential requirement.

As discussed in detail below, systems and methods for efficient thermal generation and interfacial detection of spin current are presented. In one exemplary embodiment, a measurable spin-Seebeck effect is achieved in Ni₈₀Fe₂₀/p-Si bilayers without use of a heavy metal spin detector. The p-Si, possessing the centosymmetric crystal structure, has insignificant intrinsic spin-orbit coupling leading to negligible spin-charge conversion. A giant inverse spin-Hall effect, essential for detection of spin-Seebeck effect, is observed in the Ni₈₀Fe₂₀/p-Si bilayer structure and originates from Rashba spin orbit coupling due to structure inversion asymmetry at the interface. The structure inversion asymmetry can be achieved by a strain gradient present through the thickness of p-Si. Additionally, the thermal spin pumping in p-Si leads to spin current from the p-Si layer to the Ni₈₀Fe₂₀ layer due to tunneling spin galvanic effect and spin-Hall effect, causing spin-orbit torques. The thermal spin-orbit torques lead to collapse of magnetic hysteresis of the Ni₈₀Fe₂₀ layer for a temperature gradient of 20.84 mK across the bilayer specimen. The thermal spin-orbit torques can be used for efficient magnetic switching for memory applications.

The performance of thermoelectric semiconductors, especially those which are commercially available, has been stagnant for years. The materials that show increase in thermoelectric performance require complex and scarce elements (e.g., rare earths). An innovative approach to improving thermoelectric energy storage and conversion is the spin dependent thermoelectric energy conversion using spin Seebeck effect (SSE), anomalous Nernst effect (ANE) and spin Nernst effect (SNE), which will bring new efficiencies because pure spin current, as opposed to charge current, is believed to be dissipationless [3-1]. The discovery of the spin Seebeck effect (SSE) by Uchida et. al. has led to significant progress in ongoing research on generation of pure spin current, a precession of spins or flow of electrons with opposite spins in opposite directions, over a large distance in spintronic devices due to applied temperature gradient in ferromagnetic (FM) materials [4-2, 4-3, 4-4]. The SSE can be an efficient way to produce low cost and large memory spintronics devices [4-5]. The SSE is observed in ferromagnetic metals [4-3, 4-6, 4-7 to 4-11], semiconductors [4-12 to 4-15], insulators [4-16 to 4-22] and even in half metallic Heusler compounds [4-23].

In spin caloritronics studies, homogenous temperature gradient, as well as length scale dependent temperature gradient, is established to study the interplay of spin degrees of freedom and temperature gradient in the magnetic structures [4-22]. There are two universal SSE device configuration, longitudinal spin Seebeck effect (LSSE) and transverse spin Seebeck effect (TSSE) in which in-plane external magnetic field and temperature gradient is applied in the plane of the sample to measure the SSE [4-22]. In LSSE [4-11], a spin current is generated parallel to the temperature gradient as opposed to the spin current is perpendicular to the temperature gradient in TSSE [4-4, 4-5, 4-21]. The spin current generated in a ferromagnetic (FM) material is detected by inverse spin-Hall effect (ISHE) in a high spin orbit coupling metals (e.g., Pt, W, Ta) in contact with the FM [4-3, 4-5, 4-21]. The ISHE voltage E_{ISHE} generated perpendicularly to the magnetization M is given by Equation 8:

E_{ISHE}=(θ_{SH}ρ)Jₛ×σ (Eq. 8)

where, θ_{SH} is spin Hall angle, ρ is electrical resistivity of a paramagnetic metal, Jₛ is longitudinal spin current due to SSE, and σ is spin polarization vector parallel to M [4-3, 4-7].

The thermoelectric energy conversion from spin current depends on efficient spin to charge conversion. Currently, the primary material for spin to charge conversion is Pt due to its large spin Hall angle, which inhibits the further scientific research in spin thermoelectric conversion behavior. The SSE is enhanced due to phonon drag [4-24] and phonons drive the spin redistribution [4-13]. The spin-phonon coupling can provide an able platform to engineer spin dependent thermoelectric conversion. To make the spin mediated thermoelectric energy conversion a reality, earth abundant material/interfaces are desired for giant SSE/ANE/SNE and efficient spin to charge conversion.

As discussed below, experimental measurements of giant SSE and tunneling spin galvanic effect (TSGE) in a device formed from Ni₈₀Fe₂₀/p-Si (poly) bilayers. The spin-phonon coupling in p-Si leads to giant enhancement in SSE at the Ni₈₀Fe₂₀/p-Si (poly) bilayer and SHE in p-Si leads to giant spin-orbit torque (SOT), which can be used for SOT based memory applications.

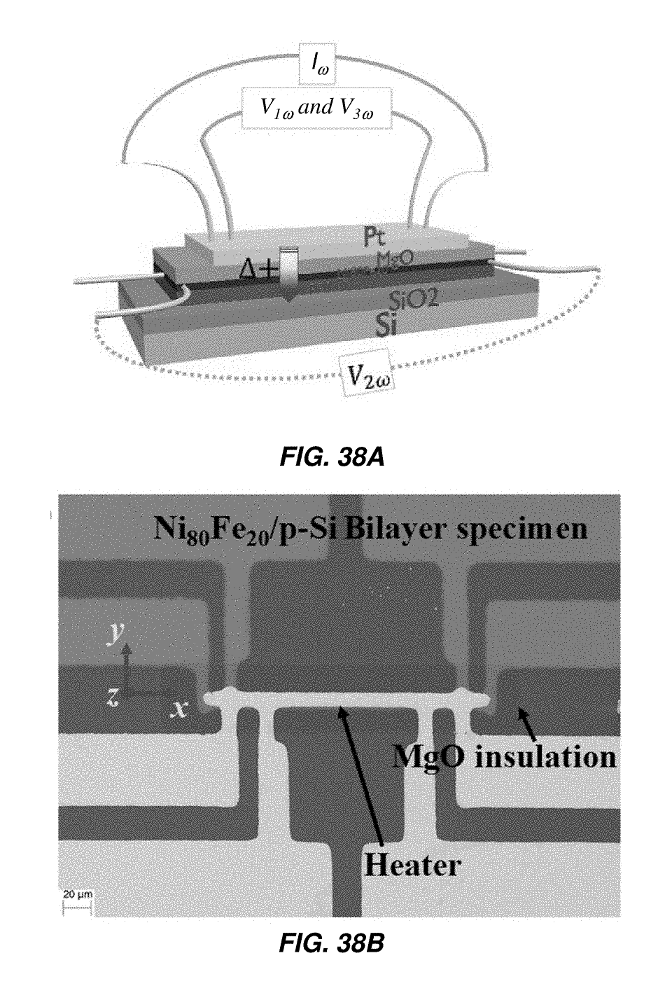

An experimental setup was developed to measure the longitudinal SSE. In the experimental setup, a Pt heater is employed to create the temperature gradient across the Ni₈₀Fe₂₀/p-Si bilayer device specimen as shown in FIG. 38A. This temperature gradient will lead to spin current in the bilayer and will allow measurement of the spin mediated thermoelectric behavior. An AC bias is applied across the Pt heater to create the temperature gradient. The first harmonic and the third harmonic response across the heater are measured to quantify the temperature gradient between the Pt heater and the Si substrate. The SSE, ANE and SNE are measured from the second harmonic response across the Ni₈₀Fe₂₀/p-Si bilayer device.

The Ni₈₀Fe₂₀/p-Si bilayer device can be fabricated using micro/nanofabrication techniques. Silicon dioxide (e.g., 300 nm) is deposited on a Si wafer using plasma enhanced physical vapor deposition (PECVD). The Ni₈₀Fe₂₀/p-Si (poly) bilayer is deposited upon the silicon dioxide using RF sputtering. The p-Si is B-doped and possesses a resistivity from 0.005-0.01 Ω-cm. A magnesium oxide (MgO) layer is deposited upon the Ni₈₀Fe₂₀ layer to electrical isolate the

Pt heater and the specimen. A heater material is subsequently deposited upon the MgO layer. In one embodiment, the heater material can be formed from Ti (e.g., 10 nm) and Pt (e.g., 100 nm).

In certain embodiments, the thickness of the MgO layer relative to the thickness of the p-Si layer can be selected to induce a strain gradient through the thickness of the p-Si layer. Alternatively or additionally, heat supplied by the heater material can be sufficient to produce a temperature gradient through the device. The temperature gradient can further induce a strain gradient within the p-Si layer at and/or adjacent to the Ni₈₀Fe₂₀/p-Si interface. A false color SEM micrograph of the resultant Ni₈₀Fe₂₀/p-Si (poly) bilayer device is illustrated in FIG. 38B.

The experimental measurements are carried inside a quantum design physical property measurement system (PPMS). For energy conversion applications, it is desirable for the thermoelectric behavior to be robust at higher temperatures. A heating current of 20 mA at 5 Hz is applied across the outer two electrodes of the Pt heater, starting at 400 K.

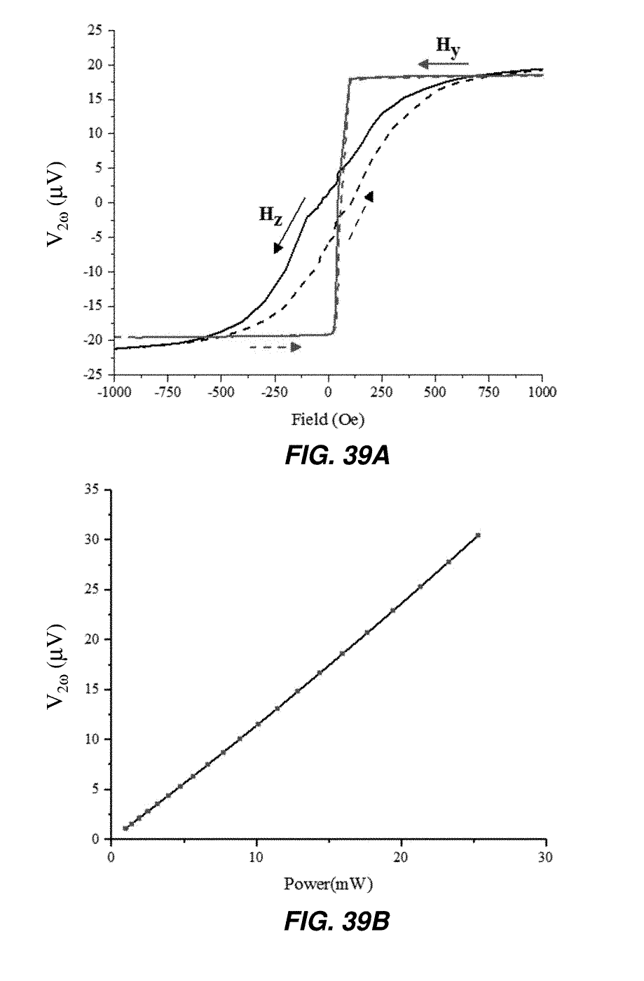

The second harmonic response (V_{2ω}) as a function of applied magnetic field is measured in the z-direction and the y-direction, as shown in FIG. 39A. For the magnetic field in y-direction (magnetic field perpendicular to the direction of the temperature gradient), a large second harmonic response V_{2ω} is observed. This response may be related to the ANE/SSE. However, an equally large signal is observed when the magnetic field is applied along the z-dir (magnetic field parallel to the temperature gradient).

The second harmonic response V_{2ω} as a function of heating power is subsequently measured at 400 K and the results are illustrated in FIG. 39B. A linear relationship is observed between the heating power and the second harmonic response V_{2ω}, as expected [4-25].

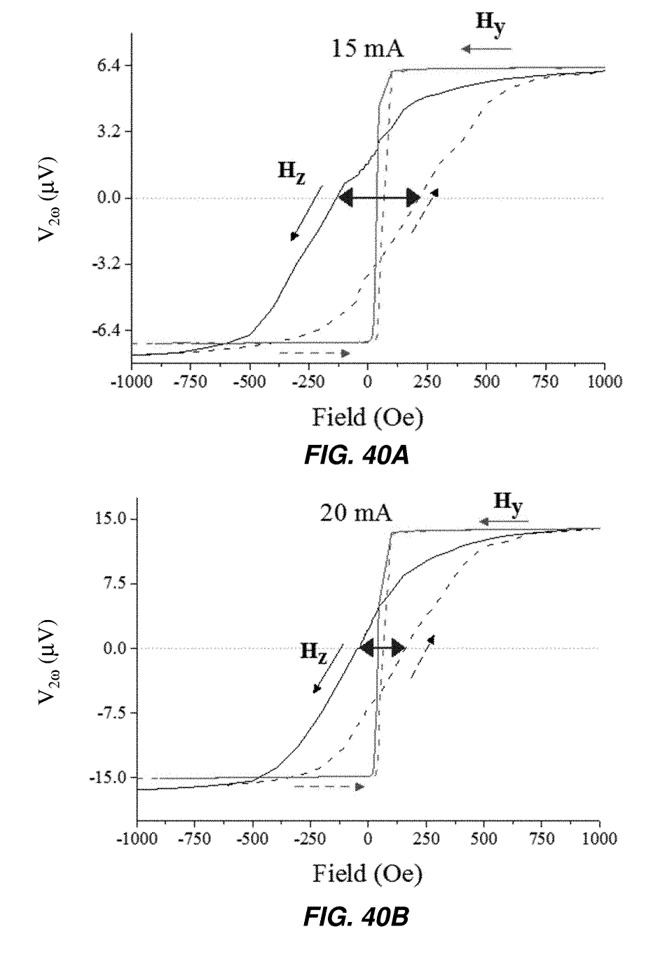

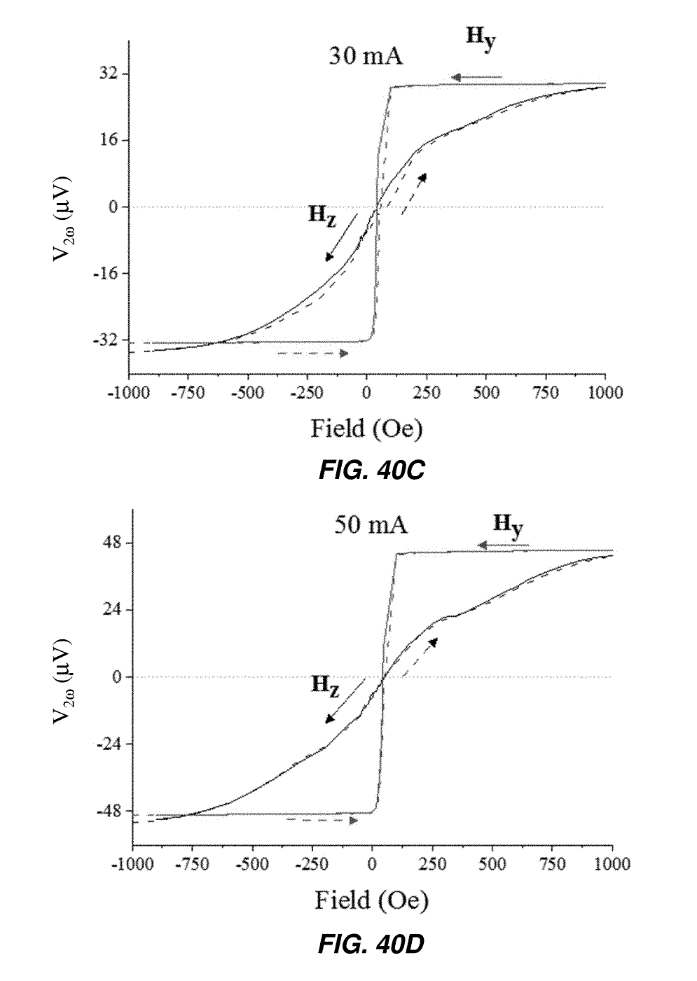

The second harmonic responses V_{2ω} are also measured as a function of magnetic field (from 1000 Oe to −1000 Oe) and applied currents of 15 mA, 20 mA, 30 mA, 50 mA at a constant temperature of 300 K, as shown in FIGS. 40A-40D. A linear second harmonic response (including ANE and SSE) is observed as a function of heating power. Unexpectedly, the magnetic hysteresis of second harmonic response V_{2ω} is observed to collapse as the heating current is raised to 50 mA. This behavior indicates existence of additional spin current from the p-Si (poly) layer to the Ni₈₀Fe₂₀ layer. This additional spin current leads to spin-orbit torque and results in change of the hysteresis behavior. For the magnetization perpendicular to the plane of interface, ANE and SSE will not be observed since M∥ΔT and Jₛ∥σ, respectively.

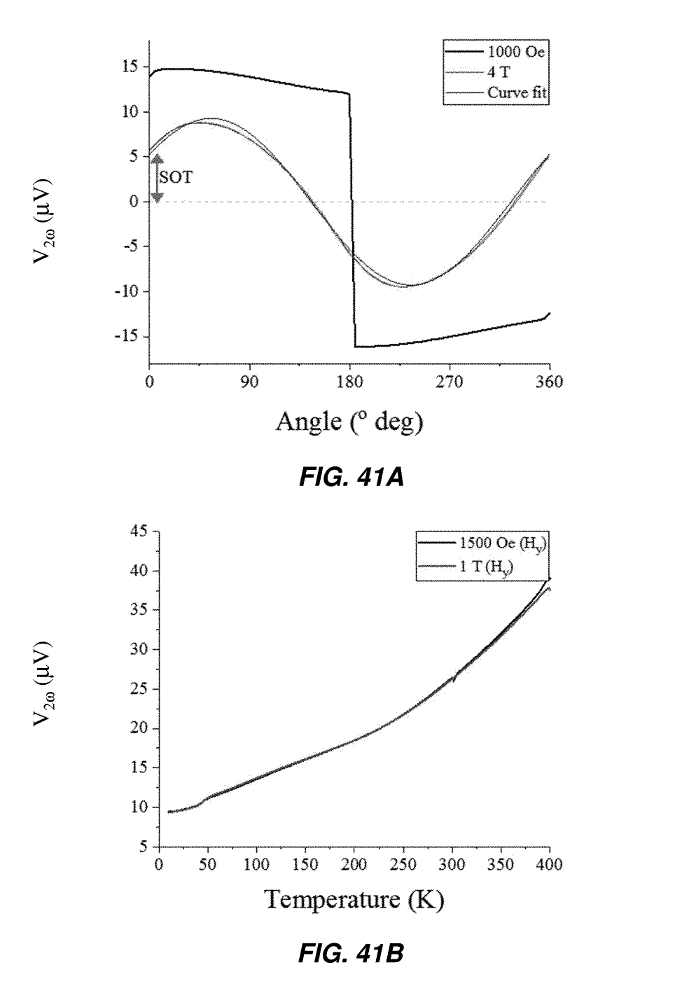

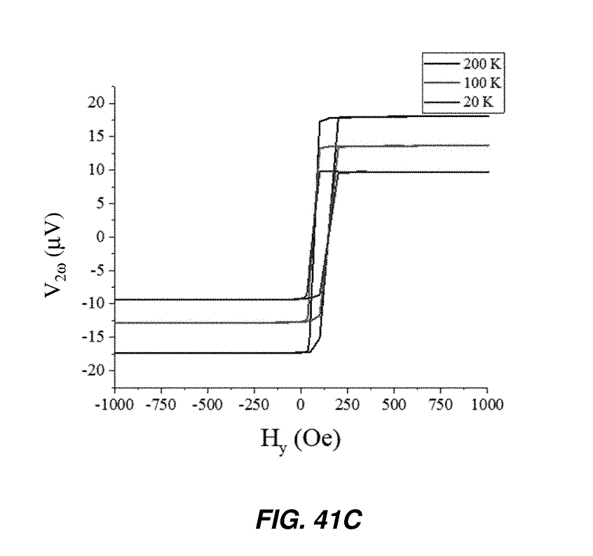

In order to decouple the contributions of ANE, SSE and SOT, the second harmonic response for an applied magnetic field (1000 Oe and 4 T) rotated in the yz-plane is measured, as shown in FIG. 41A, where vertical temperature gradient is along the z-dir. At 1000 Oe, distinct sinusoidal behavior is not observed, since the magnetic field is significantly less than the saturation magnetic field. At 4 T, the second harmonic response V_{2ω} is reduced, as compared to 1000 Oe. This observation leads to the belief that the second harmonic response originates from SSE and ANE, since SSE is suppressed by increased magnetic field and ANE is not. At 4 T, the second harmonic response V_{2ω} includes of two signals. The first signal is a cosine function and the second signal is a sine function. Sine behavior is identified as SSE since the response goes to zero for magnetic field parallel to temperature gradient (z-direction). The cosine behavior is attributed to the SOT.

This measurement leads to two challenges in the interpretation of the results. First, SSE measurement requires inverse spin Hall effect (ISHE) to convert the spin current into voltage. However, the spin Hall angle of p-Si is negligible and may not lead to observable signal. Without being bound by theory, to address the first challenge, it is hypothesized that the ISHE occurs due to Rashba spin orbit coupling at the Ni₈₀Fe₂₀/p-Si interface.

The second challenge is to uncover the origin of the observed SOT. The SOT requires the magnetization to be perpendicular to the spin polarization (M⊥σ), which can occur only due to SHE. However, the SHE requires a charge current across the specimen. In addition, the in-plane thermal transport is symmetric and SNE will also be absent. This contradictions can be resolved by tunneling spin galvanic effect (TSGE) [4-26]. In TSGE, the tunneling of spin polarized electrons leads to charge current parallel to the interface. The interfacial charge current leads to SHE due to Rashba spin-orbit coupling and, in turn, the observed SOT.

The observed SOT is not quantifiable with current techniques, since it is of thermal origin. However, the SOT leads to collapse of hysteresis in a 25 nm Ni₈₀Fe₂₀ thin film, as compared to the few nanometer films used in the SOT studies [4-27 to 4-30] and only earth abundant materials are used.

The LSSE at the Ni₈₀Fe₂₀/p-Si (poly) interface can also be quantified. The efficiency of converting spin current-voltage at interface of bilayer in a LSSE device is given by Equation 9 [4-31]:

$${S}_{LSSE} = \frac{{E}_{ISHE}}{∇ T} = \frac{{V}_{ISHE} {t}_{FM}}{{w}_{NM} Δ T} \qquad ( Eq . 9 )$$

where V_{ISHE} is the electric voltage measured due to ISHE by paramagnetic metal or normal metal (NM), t_{FM} is thickness of the FM material, w_{NM} is the distance between electrical contact in NM, and ΔT is the temperature gradient across the device.

For thin film structures, the temperature gradient is difficult to determine. The temperature gradient is estimated between heater and substrate using the 3ω method and the temperature gradient across the specimen is estimated using finite element modelling (FEM) (COMSOL). The material properties utilized for this FEM modeling are given in Table 1:

TABLE 1
Material Properties

| | Thermal conductivity | Density | Specific heat |
|---|---|---|---|
| Material | (W/mK) | (Kg/m³) | (J/KgK) |
| Platinum | 69.1 | 21450 | 130 |
| MgO | 30 | 3580 | 877 |
| Py | 19.6648 | 8740 | 502.415783 |
| p-Si | 22 | 2328 | 678 |
| Si | 130 | 2328 | 700 |
| SiO₂ | 1.3-1.5 | 2650 | 680-730 |

The temperature gradient between heater and far field temperature using 3ω technique [4-32] is given by Equation 10:

$$Δ T = \frac{4 {V}_{3 ω}}{{R}^{′} {I}_{rms}} \qquad ( Eq . 10 )$$

where V_{3ω} the third harmonic response, R′is the resistance as a function of temperature, and Iᵣₘₛ is the heating current.

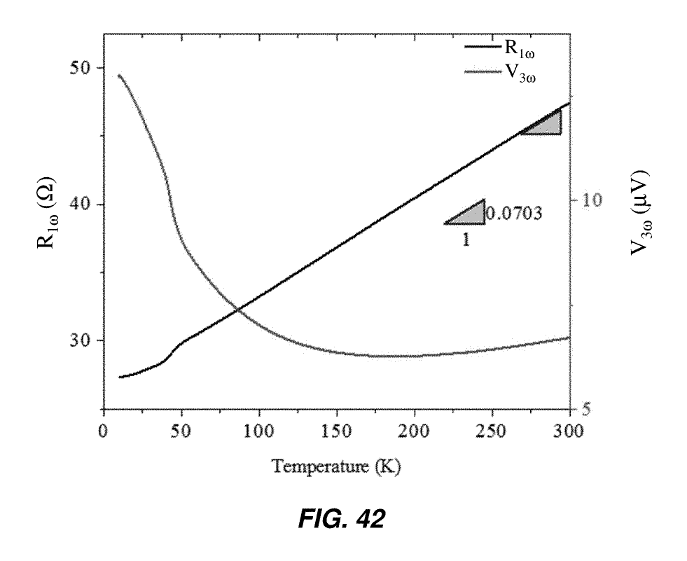

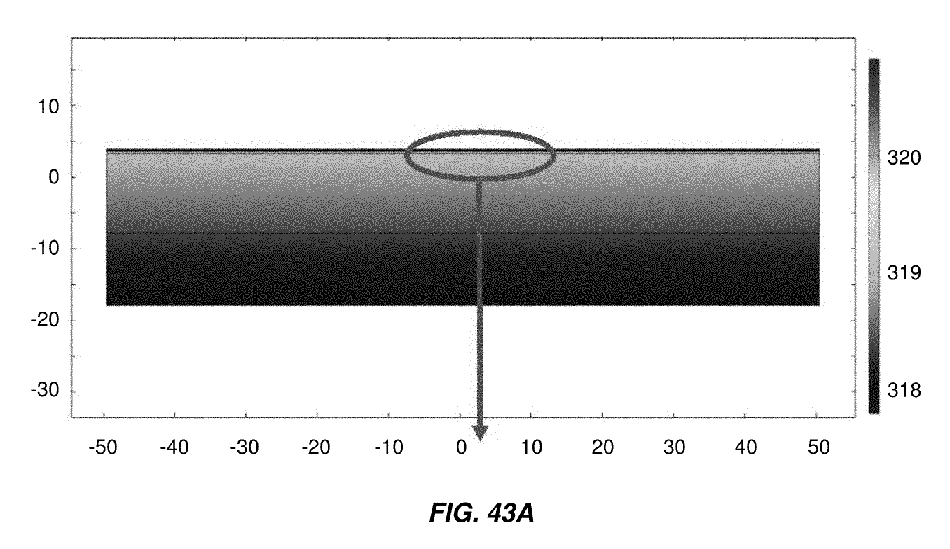

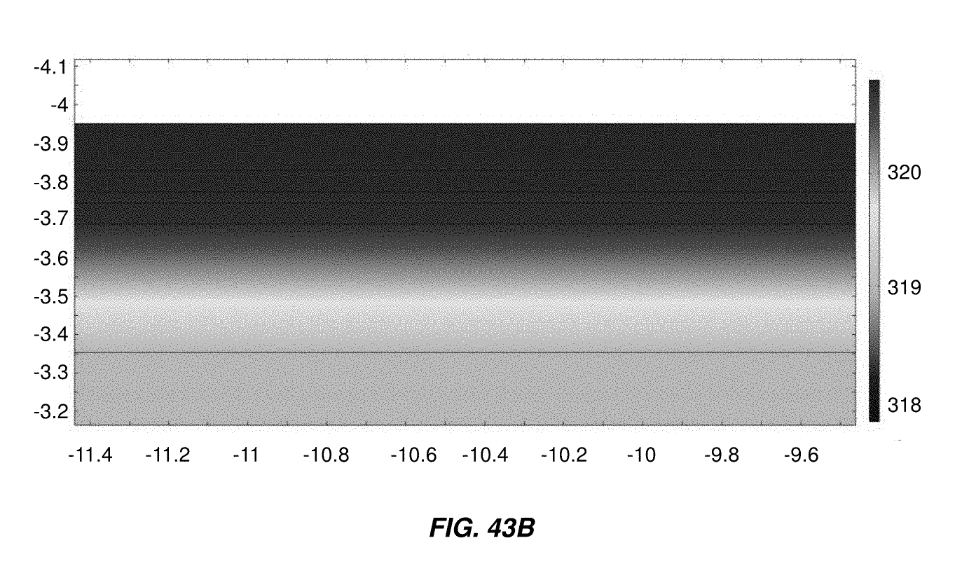

FIG. 42 is a plot of resistance (R_{1ω}) and third harmonic response V_{3ω} as a function of temperature from 10 K to 300 K. From FIG. 42, R′ is measured to be 0.07 Ω/K. Using the 3ω technique, the temperature gradient at the heater is determined to be 4.98 K, 10.9 K, and 20.84 K for 15 mA, 20 mA, and 30 mA heating current, respectively. Using FEM, the temperature gradient between the heater and the substrate and across the specimen is estimated to be about 14.08 mK, corresponding to 20 mA of heating current, as illustrated in FIGS. 43A-43B. For modeling the temperature gradient, the following assumptions are made: κₚ₋ₛᵢ=25 W/mK [4-33, 4-34] and κ_{Ni}_{₈₀}_{Fe}_{₂₀}=20 W/mK [4-35].

For the temperature gradient, the S_{LSSE} is calculated to be approximately 0.355 μV/K. This value is significantly higher than the S_{TSSE} reported for Ni₈₀Fe₂₀ [4-10] thin film but lower than the S_{LSSE} (0.8 μV/K [4-8]) reported for Ni₈₁Fe₁₉ thin films. It is noted that ISHE in the present context is interfacial, while all other reported studies use Pt for spin to charge conversion. From this study, it can be reported that the θ_{SH}^{interfacial} is of the same order as θ_{SH}^{Pt}.

The calculated specimen temperature gradient is a function of κₚ₋ₛᵢ. The calculation is repeated O for κₚ₋ₛᵢ=20 W/mK and 30 W/mK (Table 2) and the S_{LSSE} is calculated to be 0.308 μV/K and 0.395 μV/K respectively.

TABLE 2
Effect of κ - Si on the temperature gradient across the specimen

| Thermal conductivity | Heater Temperature | | |
|---|---|---|---|
| (W/mK) of p-Si | (T1) | | Temperature difference |
| 20 | 304.98 | K | 0.00741716 K |
| | 310.9 | K | 0.01623436 K |
| | 320.84 | K | 0.03103890 K |
| 25 | 304.98 | K | 0.00643506 K |
| | 310.9 | K | 0.01408479 K |
| | 320.84 | K | 0.02692908 K |
| 30 | 304.98 | K | 0.00578012 K |
| | 310.9 | K | 0.01265127 K |
| | 320.84 | K | 0.02418830 K |

Phonons from sample and substrate are the primary component that governs the non-equilibrium state of metallic magnets (Py), on the other end, magnons and phonons are responsible for non-equilibrium states in insulating magnets [4-36]. The SSE in semiconductors has been proposed to occur due to phonon drag. However, large SSE is observed herein at 400 K.

In order to ascertain the effect of phonons, the second harmonic response V_{2ω} is measured as a function of temperature from 10 K to 400 K for an applied transverse in-plane magnetic field of 1500 Oe and 1 T, as shown in FIG. 41B for a second Ni₈₀Fe₂₀/p-Si (poly) bilayer device. As shown, no effects of phonon drag and Si phonons are observed in this measurement.

SSE is also measured as a function of applied magnetic field at temperatures of 200 K, 100 K and 20 K (FIG. 41C). As shown, SSE is reducing gradually as the temperature is lowered.

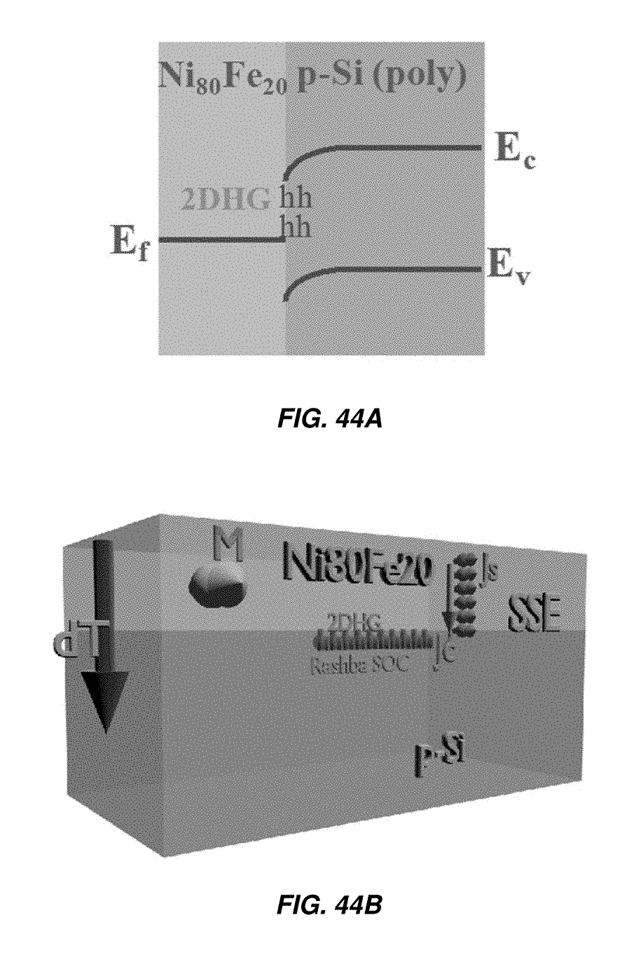

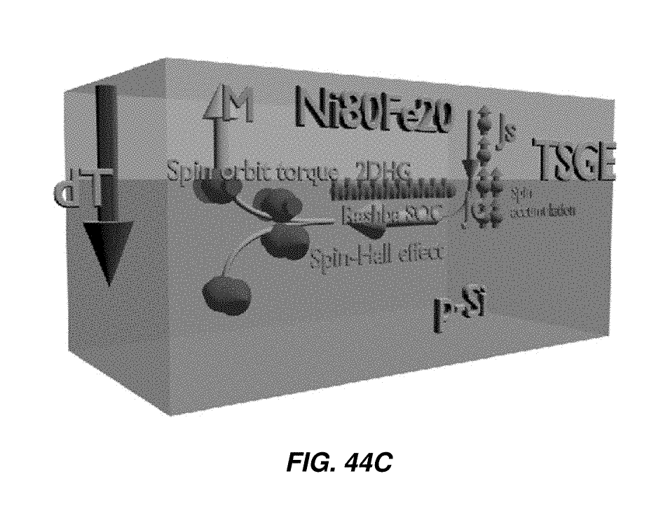

From the temperature dependent study, it is proposed that the observed second harmonic response V_{2ω} is attributed to the magnon mediated SSE. From the experimental studies, the SSE is observed for transverse in-plane magnetic field and TSGE is observed for out of plane magnetization. The metal-semiconductor interface will lead to hole accumulation and two-dimensional hole gas (2DHG) at the interface as shown in FIG. 44A. This 2DHG gives rise to strong Rashba SOC, which is the underlying cause of SSE and SOT observed herein. For the in-plane transverse magnetic field, the temperature gradient will generate a spin current leading to SSE at the interface as shown in FIG. 44B. While the out of plane magnetization will lead to spin accumulation causing a charge current across the interface due to TSGE. This charge current leads to SHE and resulting observed SOT, as shown in FIG. 44C.

### Giant Enhancement In Rashba Spin Seebeck Effect In NiFe/p-Si Thin Film

The spin-Seebeck effect mediated thermoelectric energy conversion can provide efficient alternative to traditional thermoelectrics for waste heat recovery. To achieve this goal, efficient spin to charge conversion using earth-abundant materials is desirable. Proximity induced Rashba effect mediated spin to charge conversion (inverse spin-Hall effect) has been reported in Si thin films. Rashba effect arises from the charge potential mediated by structural inversion asymmetry. This charge potential can be manipulated by controlling the thickness of Rashba layer.

As discussed in detail below, a giant Rashba spin-Seebeck effect is demonstrated in NiFe/p-Si (polycrystalline) bilayer thin films. The bilayer thin film specimens can include p-Si layer thickness of 5 nm, 25 nm, and 100 nm, while keeping the NiFe layer thickness constant (e.g., 25 nm). The Rashba spin Seebeck coefficient has been estimated to be 0.266 μV/K for 100 nm p-Si, and increases by an order of magnitude to 2.11 μV/K for 5 nm p-Si. The measured spin-Seebeck coefficient in a 5 nm p-Si specimen is the largest coefficient ever reported. The measured voltage of 100.3 μV is one of the largest reported spin-Seebeck voltage, with smallest area of approximately 160×10 μm² used in any spin-Seebeck measurement.

Since the discovery of spin-Seebeck effect (SSE) by Uchida et al. [5-1], the spin mediated thermoelectric energy conversion has been extensively investigated for ferromagnetic metals, ferromagnetic insulators, antiferromagnetic materials and oxides [5-2 to 5-9]. The SSE is an interface effect that generally occurs between a spin polarized ferromagnet (FM) and a normal metal (NM). In SSE, the thermal transport takes place due to the two-step spin dependent process. In the first step, the thermal gradient leads to generation of heat current from the phonon-magnon or phonon-electron interactions [5-10, 5-11]. The heat current leads to generation of spin currents in the spin-polarized material [5-12]. Spin current is in the form of either magnons or spin-polarized current due to electron or combination of both [11]. In the second step, spin current is injected across the interface from FM into NM due the spin potential gradient between FM and NM at the interface. The spin to charge conversion takes place in the NM (usually heavy metal) due to inverse spin-Hall effect. The FM is spin source and the NM is the spin sink [3]. Thus, the advantage of SSE compared to conventional thermoelectric effect is that it uses the properties of two or more materials that can be independently optimized [13]. The spin Seebeck effect and inverse spin-Hall effect (ISHE) produce an electric field given by Equation 11:

E_{ISHE}=−sσ×□T (Eq. 11)

where S is spin Seebeck coefficient and σ is the spin polarization vector. Since Equation 11 is similar to equation of anomalous Nernst effect (ANE) voltage (where σ is replaced by magnetization M) and thus both SSE and ANE have identical symmetry. One of the controlling factors in spin mediated thermoelectric energy conversion is spin to charge conversion due to spin-orbit coupling in NM. The spin Hall Angle (SHA) is the measure of efficiency in conversion of charge current to spin current given by ratio of generated charge current to the injected spin current [5-14] and vice versa. Pt is the primary material for spin to charge conversion due to its large SHA, which can be enhanced by defects and impurities. Extensive research has been reported in methods to enhance the spin-Hall angle for inverse spin Hall effect. These methods include alloying [5-15] and metastable phases [5-16, 5-17].

As discussed above and reported by Bhardwaj et. al. [5-18] , SSE and thermal spin galvanic effect (SGE) have been achieved in a Ni₈₀Fe₂₀ (poly) bilayer thin film device without any heavy metal detector. It is proposed that the spin to charge conversion in p-Si layer in the bilayer specimen is due to structure inversion asymmetry of sandwich structure and proximity effect. The spin-Seebeck coefficient in the bilayer is observed to be of the same order as Pt. However, larger values of spin Seebeck Coefficient (S_{LEEE}) is required to make the efficient spin mediated thermoelectric technologies into reality.

As further discussed above, the Rashba spin-orbit coupling (SOC) relies on the charge potential due to structure inversion asymmetry (SIA), which can be controlled by reducing the thickness of the sandwiched layer. The Rashba effect mediated spin-Hall magnetoresistance is demonstrated in Ni₈₁Fe₁₉/MgO/p-Si [5-19 to 5-21] and Ni₈₁Fe₁₉/MgO/n-Si [5-22] thin films as well. The spin-Hall magnetoresistance arises due to ISHE, which is essential for SSE. Without being bound by theory, it is hypothesized that the reduction in thickness of p-Si can increase Rashba SOC, leading to efficient spin to charge conversion.

To explore the thickness dependent SSE behavior, three specimens having p-Si layer thickness of 5 nm, 25 nm and 100 nm are investigated which keep the thickness of NiFe constant (e.g., 25 nm). Giant enhancement in spin mediated thermoelectric energy conversion is demonstrated due to efficient spin to charge conversion from Rashba effect.

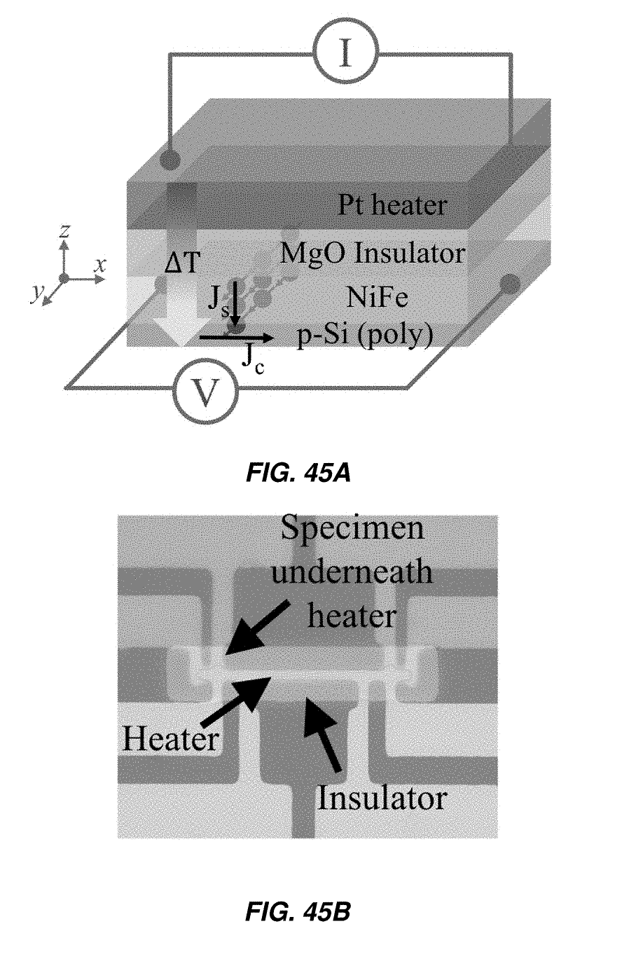

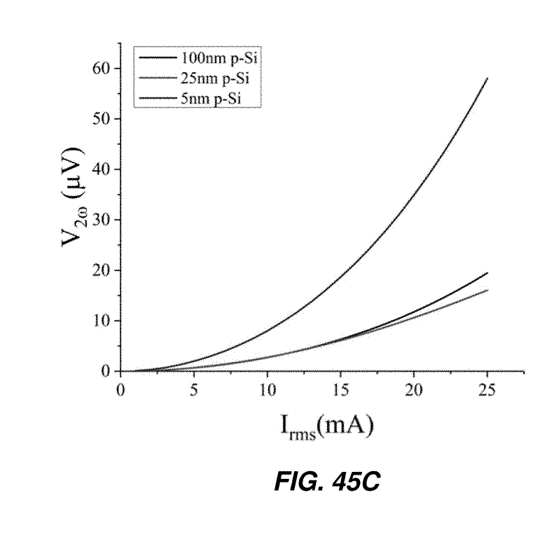

The SSE is commonly characterized using two universal device configurations-longitudinal spin Seebeck effect (LSSE) and transverse spin Seebeck effect (TSSE) [5-23]. Spin current is parallel to the temperature gradient in LSSE [5-24] while it is perpendicular to the temperature gradient in TSSE [5-9, 5-25, 5-26]. As discussed herein, the LSSE configuration are utilized to discover the spin mediated thermoelectric energy conversion behavior in NiFe/p-Si bilayers, shown in FIG. 45A. In the LSSE configuration, the temperature gradient across the thin film specimen creates a spin current (Jₛ), which then get converted into a charge current (J_{c}) as shown in FIG. 45A.

To fabricate the experimental setup, a thermal silicon oxide is deposited upon a Si wafer by chemical vapor deposition (CVD). The NiFe/p-Si (poly) bilayers are then deposited on the thermal oxide using RF sputtering as shown in FIG. 45B. Three sets of bilayers are deposited, with different thicknesses of p-Si selected from the range of 5 nm to 100 nm (e.g., 5 nm, 25 nm and 100 nm), while keeping the NiFe thickness at a constant value from the range of 25 nm to 75 nm (e.g., 25 nm, 75 nm). Three quarters of the wafer is hidden and each of the bilayers is deposited individually. The p-Si target is B-doped having resistivity of 0.005-0.01 Ω-cm. An MgO layer is deposited upon the NiFe to electrically isolate the heater and the specimen. Subsequently, a heater composed of Ti (10 nm)/Pt (100 nm) is deposited upon the MgO layer. The thickness of the MgO layer can be selected from 50 nm to 200 nm (e.g., 50 nm). The insulator and heater deposition are common to all the bilayers devices, which reduces the fabrication induced measurement variations.

In certain embodiments, the thickness of the MgO layer relative to the thickness of the p-Si layer can be selected to induce a strain gradient through the thickness of the p-Si layer. Heat supplied by the heater can be sufficient to produce a temperature gradient through the device. The temperature gradient can further induce a strain gradient within the p-Si layer sufficient to promote structural inversion symmetry within the p-Si layer at and/or adjacent to the NiFe/p-Si interface.

Experimental data is acquired inside a Quantum design Physical property measurement system (PPMS). To ascertain the thermal response characteristics, the second harmonic response V_{2ω} is measured as a function of current at an applied magnetic field of 1500 Oe as shown in FIG. 45C. It is observed that the V_{2ω} response shows a relationship having both quadratic and linear terms with respect to the applied heating current. This behavior suggests that the temperature rise across the specimen do not have linear relationship with the square of heating current, which may be due to temperature drop across MgO (top) and thermal oxide layers (bottom).

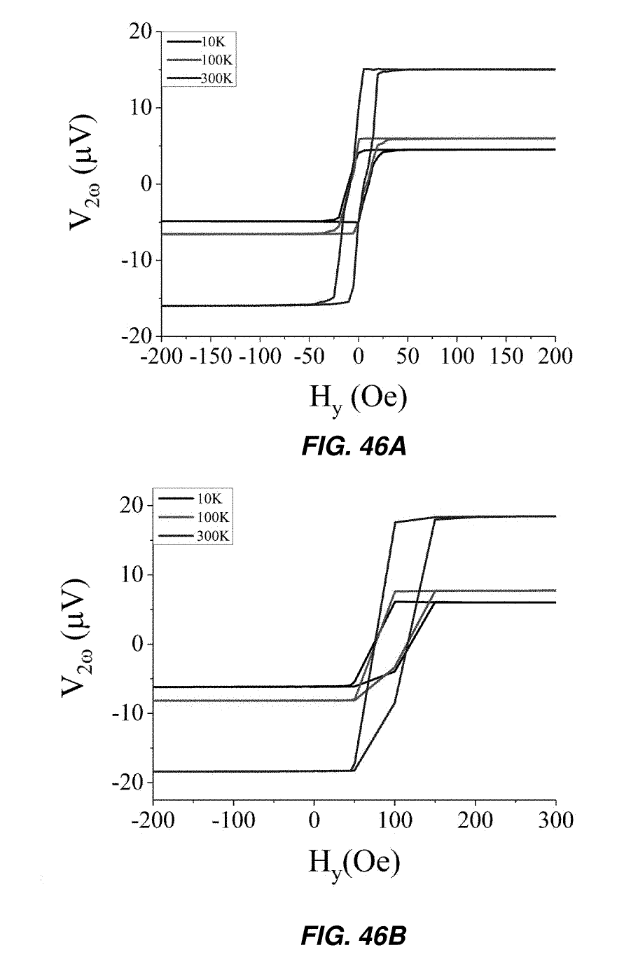

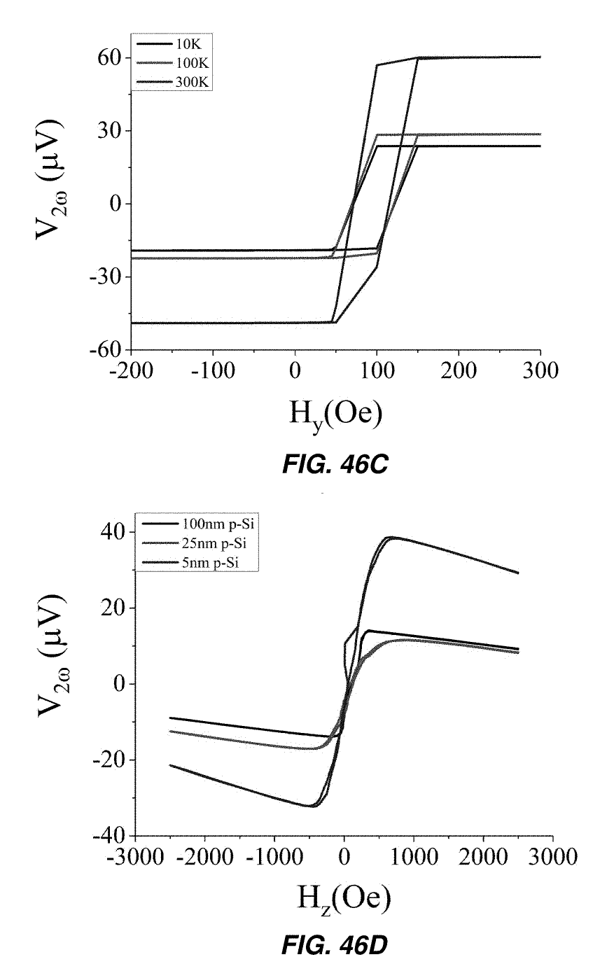

To investigate the SSE behavior, the V_{2ω} response is measured as a function of magnetic field (1500 Oe to −1500 Oe) applied in the y-direction (normal to the temperature gradient) for all three specimens. The data is acquired at 10 K, 100 K and 300 K, as shown in FIGS. 46A-46C. The observed behavior demonstrates magnetic switching behavior for all the thicknesses, which is consistent with SSE and ANE. At 300 K, the V_{2ω} for the 5 nm, 25 nm and 100 nm are 31.08 μV, 36.77 μV, and 100.3 μV, respectively. Although the V_{2ω} response for the 25 nm and 100 nm specimens is similar in magnitude, the V_{2ω} response for 5 nm is extremely large. This behavior eliminates ANE as an underlying mechanism for the observed behavior since the NiFe layer thickness is same across all the specimens.

For specimen with 5 nm p-Si layer thickness, the V_{SSE} is 100.3 μV at 300 K, which is significantly larger as compared to any other SSE measurement reported in the literature. In addition, the SSE specimen area is 160×10 μm² in the instant measurements, which is an order of magnitude smaller than the other reported experiments. Notably, this efficient spin mediated thermoelectric energy conversion is achieved without utilizing any heavy metal for spin to charge conversion. This giant enhancement in SSE is attributed to the proximity induced Rashba SOC in p-Si layer, which increases significantly with reduction in p-Si layer due to structure inversion asymmetry, resulting in the observed behavior. The Rashba SOC may also give rise to spin-galvanic effect (SGE).

In the recent work, Bhardwaj et al. [5-18] reported thermal SGE for an out of plane magnetic field, where its magnitude is reported to be similar to SSE. Here, a similar experiment is performed to uncover the thermal SGE behavior. The V_{2ω} response as a function of magnetic field (from −2500 Oe to 2500 Oe) applied in the z-direction (parallel to temperature gradient) at 300 K for a heating current a 20 mA as shown in FIG. 46D. The observed V_{2ω} response is similar to SSE measurement. The V_{2ω} response for the device having a 5 nm p-Si layer (FIG. 46C) is very large as compared to specimens having 25 nm and 100 nm p-Si thick layer. It is proposed that this out-of-plane V_{2ω} response is due to thermal SGE.

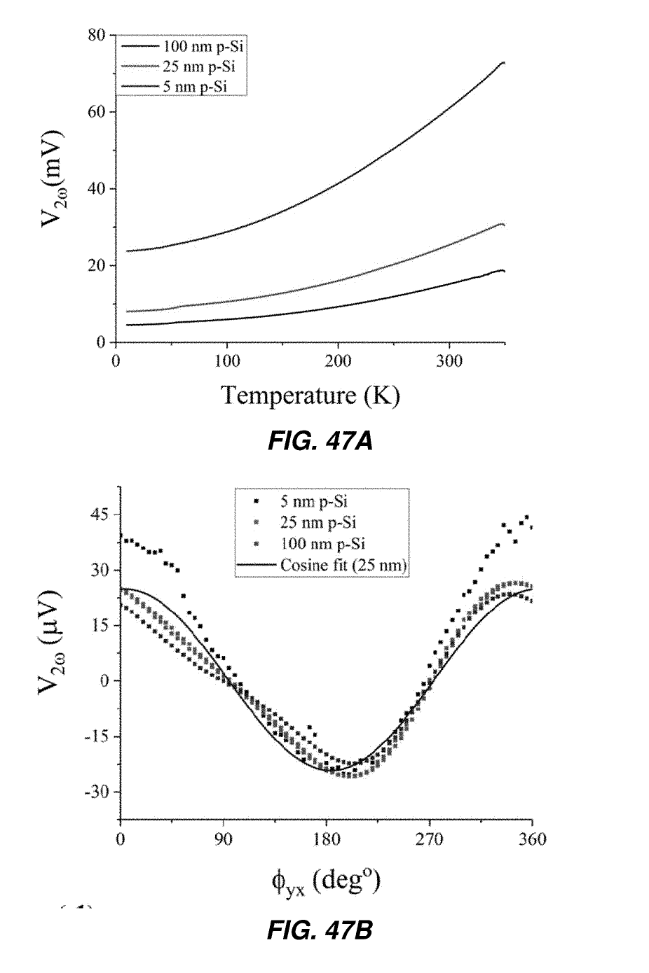

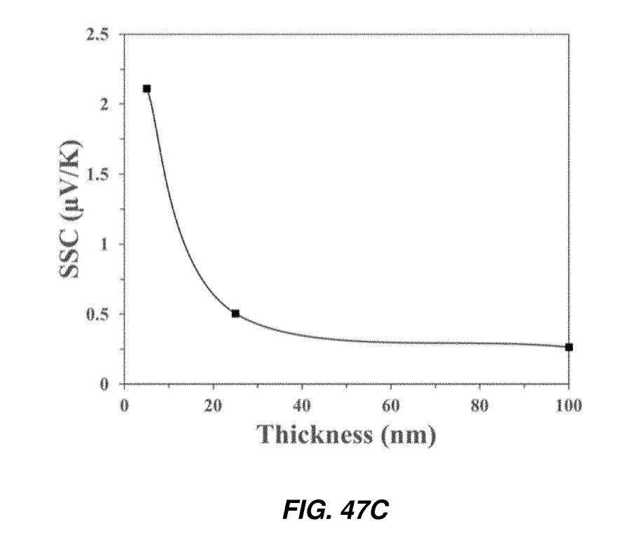

The measurement of V_{2ω} response as a function of magnetic field leads to confirmation of the SSE and thermal SGE behavior. To uncover the underlying mechanism of SSE mediated energy conversion behavior, V_{2ω} response as a function of temperature from 350 K to 10 K under a magnetic field of 1000 Oe applied along the y-direction, as shown in FIG. 47A. A gradual decrease in the V_{2ω} response is observed as the temperature is lowered to 10 K. The temperature dependent behavior signifies that the observed V_{2ω} response is due to magnon mediated SSE.

To further support this hypothesis, angular dependence of the V_{2ω} response for a constant applied magnetic field of 2 T rotated in the yx-plane is illustrated in FIG. 47B. For all the devices, an embedded cosine behavior attributed to SSE is observed. The deviation from the cosine behavior can arise from the thermal SGE contributions.

To quantify the SSE in this study, the longitudinal spin Seebeck coefficient is estimated according to Equation 9 [5-18, 5-27], as discussed above. Using the 3ω technique, the temperature gradient between heater and the far field substrate temperature can further be calculated experimentally according to Equation 10. In this manner, the heater temperature is estimated to be approximately 313.7 K for the Ni₈₀Fe₂₀/p-Si (poly) bilayer device having a 25 nm thick p-Si layer and 313.4 K in case of 100 nm thick p-Si for R′of 0.07 W/K [5-18].

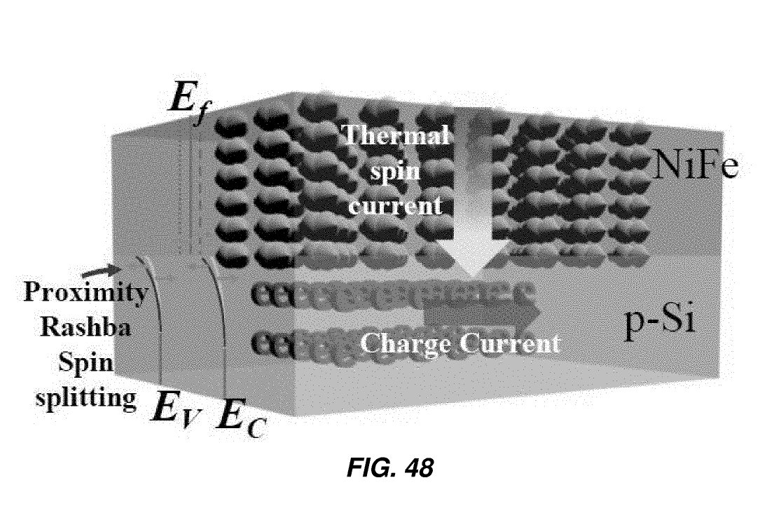

As discussed above, finite element simulations can be employed to simulate the temperature gradient across the bilayer specimen, which is essential for spin-Seebeck coefficient. For modeling the temperature gradient, κ_{p-Si} is assumed to be 15 W/mK, 20 W/mK and 35 W/mK [5-29, 5-30] for p-Si layer thickness of 5 nm, 25 nm and 100 nm respectively and κ_{NiFe} is assumed to be 20 W/mK [5-31]. It is observed that the simulated temperature gradient across the NiFe layer is similar for all the p-Si layers. This observation reinforces that the ANE is not the underlying reason of observed V_{2ω} response. Using the simulated temperature gradient across the bilayer, the S_{LSSE} is calculated to be 2.11 μV/K, 0.506 μV/K, and 0.266 μV/K for 5 nm, 25 nm and 100 nm thick p-Si layer thickness, respectively, as shown in FIG. 47C. As stated earlier, the observed SSE behavior is proposed to occur due to proximity Rashba SOC. An exemplary embodiment of the mechanism of observed Rashba SSE behavior is illustrated in FIG. 48.

The thickness dependent LSSE measurement can be used to calculate the spin-Hall angle and spin diffusion length. Qu et al. [5-32] used the LSSE measurement to uncover the spin-Hall angles according to Equation 12:

$$Δ {V}_{th} or {V}_{SSE} = [ 2 CL Δ T ] [ ρ ( t ) {θ}_{SH} ] [ \frac{{λ}_{SF}}{t} tanh ( \frac{t}{2 {λ}_{SF}} ) ] \qquad ( Eq . 12 )$$

where ΔVₜₕ is the thermal voltage due to SSE, the first factor on the right-hand side [CLΔT] relates to spin injection efficiency, the length of the wire, and temperature gradient respectively. The second factor on the right-hand side [ρ(t)θ_{SH}], material specific quantity and relates to the spin conductivity. The last factor relates to the spin diffusion length (λ_{SF}) and thickness. Note that Equation 12 assumes that the intrinsic spin diffusion length and spin-Hall angle are independent of material thickness. Although this assumption may be true for the intrinsic spin orbit coupling in case of 5 d heavy metals [5-15, 5-32] but the Rashba SOC that is responsible for the ISHE is thickness dependent. Hence, Equation 12 cannot quantify the spin transport behavior in the disclosed NiFe/p-Si bilayer thin films presented herein.

Instead of quantitative analysis, a comparative study of the observed SSE in the NiFe/p-Si bilayer specimen is performed. Specifically, reported LSSE measurements previously reported for various materials are analyzed. To demonstrate the quantum of spin-Seebeck behavior observed in the present study, the reported V_{SSE}>10 μN are listed in Table 3.

TABLE 3
Summary of Largest Seebeck Voltages and Corresponding Spin Source, Spin
Detector, Specimen Dimensions, and Spin-Seebeck coefficient

| | Spin | | | SSC | Dimensional | |
|---|---|---|---|---|---|---|
| ΔV (μV) | source | Detector | Specimen (L × B) | (μV/K) | Normalization | Ref |
| ~175 | YIG | (BiₓSb₁₋ₓ)₂Te₃ | 900 μm × 100 μm | Not | N/A | [5-33] |
| | | | | reported | | |
| 100.3 | NiFe | p-Si (poly) | 160 μm × 10 μm | 0.2-2.2 | Yes | This |
| | | | (smallest) | | | study |
| ~100 | Fe₃O₄ | Pt | Spin-Hall | Not | N/A | [5-34] |
| | | | thermopile (7 mm × | reported | | |
| | | | 2 mm) | | | |
| ~26 | YIG | Pt | 6 mm × 2 mm | 0.100 | No | [5-26] |
| ~25 and | Fe₃O₄ | Pt | 7 mm × 2 mm | 0.03 and | Yes | [5-13] |
| ~12 | | | | 0.7 | | |
| ~18 | YIG | Pt | 10 mm × 2.3 mm | 1.500 | No | [5-36] |
| ~12 | NiFe₂O₄ | Pt | 8 mm × 5 mm | 0.030 | No | [5-37] |
| | | | | −0.020 | | |

Two articles report spin-Seebeck voltage of more than 100 μV [5-33, 5-34]. Jiang et al. reported a spin-Seebeck voltage of 175 μN in Bi doped topological insulator (Sb₂Te₃), which is the highest V_{SSE} reported in the literature. While the V_{SSE} reported in present study is smaller, the area of the specimen in present study is approximately 56.25 times smaller as well. In addition, the heating power used to achieve the 175 μV is 500 mW, while the heating power of 17.6 mW is used in this study to generate 100.3 μV. This observation clearly demonstrates the superiority of the thermoelectric efficiency in the NiFe/p-Si bilayer system.

Ramos et al. demonstrated a giant spin-Seebeck voltage in Fe₃O₄/Pt system using a spin-Hall thermopile setup. However, the specimen area is 3 orders of magnitude larger than the specimen area in this study. In addition, the spin-Hall thermopile configuration can be applied to NiFe/p-Si bilayer system as well to achieve even higher voltages. Other reports of large spin-Seebeck voltage are listed in Table 3 as well. All specimens in the listed studies included areas that are three orders of magnitude larger, with spin-Seebeck voltages that are an order of magnitude smaller than presented in this work.

### Conclusions

in one aspect, generation of intrinsic dissipationless spin current in MgO/Si thin film devices (p-Si and n-Si) is demonstrated without use of a ferromagnetic source. Efficient spin to charge conversion is achieved by having structure inversion asymmetry at the MgO/Si interface. Site inversion asymmetry is also demonstrated in a centosymmetric diamond cubic lattice of Si. Local antiferromagnetic interactions are also shown to lead to dissipationless spin current.

In another aspect, emergent antiferromagnetic and metal insulator phase transformation (MIT) in nanoscale p-Si thin films (e.g., Pd/Ni₈₁Fe₁₉/MgO/p-Si) is demonstrated. The high temperature antiferromagnetic phase transformation is evidenced through magneto-electro-thermal transport measurements. The phase transition is confirmed from the diverging behavior in resistance and V_{3ω} measurement. The SHE induces spin polarization and the lattice site inversion asymmetry in diamond cubic Si is proposed to be the underlying cause of emergent antiferromagnetic behavior in p-Si. The SHE is confirmed by SMR measurement and interfacial Rashba spin-orbit coupling is the mechanism of ISHE. The spin mediated emergent phase transition is a function of charge carrier concentration in p-Si. At low carrier density, p-Si behaves as a semiconductor and AFM interactions lead to AFM phase transformation. For high doping concentration, p-Si exhibits AFM transition at higher temperature and distinct MIT at low temperatures.

In a further aspect, a spin mediated emergent phase transition is observed at 270 K in a freestanding Pd/Ni₈₀Fe₂₀/MgO/n-Si thin film device. The emergent phase transition is uncovered from the diverging behavior in

$$\frac{R}{{V}_{3 ω}} ,$$

which is related to the thermal transport/properties. The magnetic field-dependent V_{3ω} response support the transition behavior. In addition, the magnetoresistance behavior reveals existence of SOT transfer from n-Si to Ni₈₀Fe₂₀ layer, which diminishes as temperature decreased. The angular rotation of magnetic field in yz-plane shows existence of SMR behavior at 300 K and 200 K, and AMR is observed at and below 170 K. The AMR originates from Ni80Fe20 layer and SMR originates from the SHE in n-Si coupled with interfacial ISHE due to Rashba effect. With n-Si having long spin diffusion length, it is proposed that SHE leads to non-equilibrium spin accumulation. The spin accumulation leads to an antiferromagnetic emergent phase transition. The emergent behavior can only be observed in thermal response behavior due to spin-phonon interactions in n-Si and phonons being the primary heat carrier in n-Si.

In an additional aspect, simultaneous existence of spin-Hall magnetoresistance in a Pd/Ni₈₀Fe₂₀/MgO/p-Si thin film device is demonstrated. The interfacial strain, ferromagnetic proximity effect and structural inversion asymmetry lift the degeneracy of valence band maxima, which is the underlying cause of intrinsic spin-Hall effect. The strain effects are uncovered by current dependent resistance change attributed to the thermal mismatch and piezoresistance behavior of p-Si. The spin polarization predominantly occurs along the <110> direction, indicating that the cubic Rashba leads to intrinsic spin-Hall effect. The Rashba SOC and SHE cause non-equilibrium spin polarization in the p-Si layer. The spin accumulation leads to antiferromagnetic spin-spin interactions and phase transition behavior. The phase transition behavior is uncovered using the 3ω method. These embodiments demonstrate the first experimental evidence of manipulation of Rashba SOC in Si structures using strain.

In an additional aspect, the giant spin-Seebeck effect and spin-orbit torques are observed in a Ni₈₀Fe₂₀/p-Si (poly) bilayer device. This experimental study represents a significant advance in the field of spin-caloritronics, as these measurements do not require any heavy metal for the spin to charge conversion. Instead, the inverse spin-Hall effect occurs at the Ni₈₀Fe₂₀/p-Si (poly) interface due to Rashba spin orbit coupling. This is the first experimental evidence of Rashba spin-Seebeck effect. The Rashba spin-orbit coupling is proposed to occur due to two-dimensional hole gas at the interface. The two-dimensional hole gas behavior can be controlled using the Si semiconductor physics. This may allow Si interfaces with giant spin-orbit coupling which opens the possibility to eclipse Pt as a primary spin detector. This may also lead to enhanced spin-Seebeck coefficient and in turn efficient thermal energy conversion. While the longitudinal spin-Seebeck coefficient measured herein is similar to the values reported in literature, the room temperature V_{SSE} observed in this study is one of the largest reported values[4-3, 4-4, 4-11, 4-25], especially for a small temperature gradient of 10.9 mK. In addition to spin-Seebeck effect, the giant spin-orbit torque is also discovered, which is attributed to the tunneling spin galvanic effect due to thermal spin pumping. While there has been extensive research on spin transfer torque in magnetic tunnel junctions, this is the first report of thermal spin-orbit torque. The thermal spin-orbit torques lead to collapse of out-of-plane magnetic hysteresis of the thick Ni₈₀Fe₂₀film (e.g., 25 nm). The thermal spin-orbit torques can be used to develop energy efficient memory devices utilizing the magnetization reversal behavior. In addition, these results will give impetus to the interfacial behavior at light elements having insignificant intrinsic spin-orbit coupling.

In another aspect, a NiFe (25 nm)/p-Si (polycrystalline) bilayer thin film device having p-Si thickness of 5 nm, 25 nm and 100 nm is shown to exhibit a giant increase in SSE in. The spin-Seebeck voltage shows a three-fold increase in case of 5 nm p-Si, as compared to the 25 nm and 100 nm. The inverse spin-Hall effect is proposed to occur due to proximity induced Rashba spin orbit coupling at the NiFe/p-Si interface. This observation eliminates the requirement of heavy metal (e.g., Pt, Ta) for spin to charge conversion. The largest spin-Seebeck coefficient reported in this study is a technological breakthrough, which may help in realization of waste heat recovery applications using spin-Seebeck effect.

All references throughout this application, for example patent documents including issued or granted patents or equivalents; patent application publications; and non-patent literature documents or other source material; are hereby incorporated by reference herein in their entireties, as though individually incorporated by reference, to the extent each reference is at least partially not inconsistent with the disclosure in this application (for example, a reference that is partially inconsistent is incorporated by reference except for the partially inconsistent portion of the reference).

The terms and expressions which have been employed herein are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments, exemplary embodiments and optional features, modification and variation of the concepts herein disclosed may be resorted to by those skilled in the art, and that such modifications and variations are considered to be within the scope of this invention as defined by the appended claims. The specific embodiments provided herein are examples of useful embodiments of the present invention and it will be apparent to one skilled in the art that the present invention may be carried out using a large number of variations of the devices, device components, methods steps set forth in the present description. As will be obvious to one of skill in the art, methods and devices useful for the present methods can include a large number of optional composition and processing elements and steps.

All patents and publications mentioned in the specification are indicative of the levels of skill of those skilled in the art to which the invention pertains. References cited herein are incorporated by reference herein in their entirety to indicate the state of the art as of their publication or filing date and it is intended that this information can be employed herein, if needed, to exclude specific embodiments that are in the prior art. For example, when composition of matter are claimed, it should be understood that compounds known and available in the art prior to Applicant's invention, including compounds for which an enabling disclosure is provided in the references cited herein, are not intended to be included in the composition of matter claims herein.

As used herein and in the appended claims, the singular forms “a”, “an”, and “the” include plural reference unless the context clearly dictates otherwise. Thus, for example, reference to “a cell” includes a plurality of such cells and equivalents thereof known to those skilled in the art, and so forth. As well, the terms “a” (or “an”), “one or more” and “at least one” can be used interchangeably herein. It is also to be noted that the terms “comprising”, “including”, and “having” can be used interchangeably. The expression “of any of claims XX-YY” (wherein XX and YY refer to claim numbers) is intended to provide a multiple dependent claim in the alternative form, and in some embodiments is interchangeable with the expression “as in any one of claims XX-YY.”

Unless defined otherwise, all technical and scientific terms used herein have the same meanings as commonly understood by one of ordinary skill in the art to which this invention belongs. Although any methods and materials similar or equivalent to those described herein can be used in the practice or testing of the present invention, the preferred methods and materials are now described. Nothing herein is to be construed as an admission that the invention is not entitled to antedate such disclosure by virtue of prior invention.

Every formulation or combination of components described or exemplified herein can be used to practice the invention, unless otherwise stated.

Whenever a range is given in the specification, for example, a temperature range, a time range, or a composition or concentration range, all intermediate ranges and sub-ranges, as well as all individual values included in the ranges given are intended to be included in the disclosure. As used herein, ranges specifically include the values provided as endpoint values of the range. For example, a range of 1 to 100 specifically includes the end point values of 1 and 100. It will be understood that any sub-ranges or individual values in a range or sub-range that are included in the description herein can be excluded from the claims herein.

As used herein, the term “comprising” is synonymous with “including,” “containing,” or “characterized by,” and is inclusive or open-ended and does not exclude additional, unrecited elements or method steps. As used herein, the phrase “consisting of” excludes any element, step, or ingredient not specified in the claim element. As used herein, the phrase “consisting essentially of” does not exclude materials or steps that do not materially affect the basic and novel characteristics of the claim. In each instance herein any of the terms “comprising”, “consisting essentially of” and “consisting of” may be replaced with either of the other two terms. The embodiments illustratively described herein suitably may be practiced in the absence of any element or elements, limitation or limitations which is not specifically disclosed herein.

One of ordinary skill in the art will appreciate that starting materials, biological materials, reagents, synthetic methods, purification methods, analytical methods, assay methods, and biological methods other than those specifically exemplified can be employed in the practice of the disclosed embodiments without resort to undue experimentation. All art-known functional equivalents, of any such materials and methods are intended to be included in this invention. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

### REFERENCES

Each of the following references is incorporated by reference in their entirety
1-1 André Dankert, Ravi S. Dulal, and Saroj P. Dash, Sci. Rep. 3 (2013).
1-2 Berend T. Jonker, George Kioseoglou, Aubrey T. Hanbicki, Connie H. Li, and Phillip E. Thompson, Nat Phys 3 (8), 542 (2007).
1-3 Saroj P. Dash, Sandeep Sharma, Ram S. Patel, Michel P. de Jong, and Ron Jansen, Nature 462 (7272), 491 (2009).
1-4 Ian Appelbaum, Biqin Huang, and Douwe J. Monsma, Nature 447 (7142), 295 (2007).
1-5 Shixiong Zhang, Shadi A. Dayeh, Yan Li, Scott A. Crooker, Darryl L. Smith, and S. T. Picraux, Nano Letters 13 (2), 430 (2013).
1-6 Kazuya Ando and Eiji Saitoh, Nat Commun 3, 629 (2012).
1-7 J. E. Hirsch, Physical Review Letters 83 (9), 1834 (1999).
1-8 Jairo Sinova, Sergio O. Valenzuela, J. Wunderlich, C. H Back, and T. Jungwirth, Reviews of Modern Physics 87 (4), 1213 (2015).
1-9 Jairo Sinova, Dimitrie Culcer, Q. Niu, N. A. Sinitsyn, T. Jungwirth, and A. H. MacDonald, Physical Review Letters 92 (12), 126603 (2004).
1-10 Shuichi Murakami, Naoto Nagaosa, and Shou-Cheng Zhang, Science 301 (5638), 1348 (2003).
1-11 Y. K. Kato, R. C. Myers, A. C. Gossard, and D. D. Awschalom, Science 306 (5703), 1910 (2004).
1-12 J. Wunderlich, B. Kaestner, J. Sinova, and T. Jungwirth, Physical Review Letters 94 (4), 047204 (2005).
1-13 D. A. Abanin, R. V. Gorbachev, K. S. Novoselov, A. K. Geim, and L. S. Levitov, Physical Review Letters 107 (9), 096601 (2011).
1-14 D. A. Abanin, A. V. Shytov, L. S. Levitov, and B. I. Halperin, Physical Review B 79 (3), 035304 (2009).
1-15 E. Lesne, Yu Fu, S. Oyarzun, J. C. Rojas-Sanchez, D. C. Vaz, H. Naganuma, G. Sicoli, J. P. Attane, M. Jamet, E. Jacquet, J. M. George, A. Barthelemy, H. Jaffres, A. Fert, M. Bibes, and L. Vila, Nat Mater advance online publication (2016).
1-16 Kohei Fujiwara, Yasuhiro Fukuma, Jobu Matsuno, Hiroshi Idzuchi, Yasuhiro Niimi, YoshiChika Otani, and Hidenori Takagi, Nature Communications 4, 2893 (2013).
1-17 F. Rortais, C. Vergnaud, C. Ducruet, C. Beigné, A. Marty, J. P. Attané, J. Widiez, H. Jaffrès, J. M. George, and M. Jamet, Physical Review B 94 (17), 174426 (2016).
1-18 G. Mihajlović, J. E. Pearson, M. A. Garcia, S. D. Bader, and A. Hoffmann, Physical Review Letters 103 (16), 166601 (2009).
1-19 Version 4.1 (National Institute of Standards and Technology NIST X-ray Photoelectron Spectroscopy Database, Gaithersburg, 2012); http://srdata.nist.gov/xps/.
1-20 N C Haider, J Alonso, and W E Swartz, Zeitschrift fur Naturforschung A 30 (11), 1485 (1975).
1-21 B. Andrei Bernevig and Shou-Cheng Zhang, Physical Review Letters 95 (1), 016801 (2005).
1-22 Won Young Choi, Hyung-jun Kim, Joonyeon Chang, Suk Hee Han, Hyun Cheol Koo, and Mark Johnson, Nat Nano 10 (8), 666 (2015).
1-23 Paul Lou, Laura de Sousa Oliveira, Chi Tang, Javier Garay, Alex Greaney, and Sandeep Kumar, arXiv:1701.01377 (2017).
1-24 Xiuwen Zhang, Qihang Liu, Jun-Wei Luo, Arthur J. Freeman, and Alex Zunger, Nat Phys 10 (5), 387 (2014).
1-25 T. Jungwirth, X. Marti, P. Wadley, and J. Wunderlich, Nat Nano 11 (3), 231 (2016).
2-1 Song, Y. & Dery, H. Analysis of phonon-induced spin relaxation processes in silicon. Physical Review B 86, 085201 (2012).
2-2 Zhang, X., Liu, Q., Luo, J.-W., Freeman, A. J. & Zunger, A. Hidden spin polarization in inversion-symmetric bulk crystals. Nat Phys 10, 387-393, doi:10.1038/nphys2933 http://www.nature.com/nphys/journal/v10/n5/abs/nphys2933.html—supplementary-information (2014).
2-3 Jungwirth, T., Marti, X., Wadley, P. & Wunderlich, J. Antiferromagnetic spintronics. Nat Nano 11, 231-241, doi:10.1038/nnano.2016.18 (2016).
2-4 Hwang, H. Y. et al. Emergent phenomena at oxide interfaces. Nat Mater 11, 103-113 (2012).
2-5 Manchon, A., Koo, H. C., Nitta, J., Frolov, S. M. & Duine, R. A. New perspectives for Rashba spin-orbit coupling. Nat Mater 14, 871-882, doi:10.1038/nmat4360 (2015).
2-6 Soumyanarayanan, A., Reyren, N., Fert, A. & Panagopoulos, C. Emergent phenomena induced by spin-orbit coupling at surfaces and interfaces. Nature 539, 509-517, doi:10.1038/nature19820 (2016).
2-7 Dan'kov, S. Y., Tishin, A. M., Pecharsky, V. K. & Gschneidner, K. A. Magnetic phase transitions and the magnetothermal properties of gadolinium. Physical Review B 57, 3478-3490 (1998).
2-8 Cohn, J. L., Neumeier, J. J., Popoviciu, C. P., McClellan, K. J. & Leventouri, T. Local lattice distortions and thermal transport in perovskite manganites. Physical Review B 56, R8495-R8498 (1997).
2-9 Chiba, D. et al. Electrical control of the ferromagnetic phase transition in cobalt at room temperature. Nat Mater 10, 853-856, doi:http://www.nature.com/nmat/journal/v10/n11/nmat3130.html—supplementary-information (2011).
2-10 Selbach, S. M., Tybell, T., Einarsrud, M.-A. & Grande, T. The Ferroic Phase Transitions of BiFeO3. Advanced Materials 20, 3692-3696, doi:10.1002/adma.200800218 (2008).
2-11 Shi, Y. et al. A ferroelectric-like structural transition in a metal. Nat Mater 12, 1024-1027, doi:10.1038/nmat3754 http://www.nature.com/nmat/journal/v12/n11/abs/nmat3754.html—supplementary-information(2013).
2-12 Tishin, A. M., Gschneidner, K. A. & Pecharsky, V. K. Magnetocaloric effect and heat capacity in the phase-transition region. Physical Review B 59, 503-511 (1999).
2-13 Kittel, C. Introduction to solid state physics. (Wiley, 2005).
2-14 Ando, K. & Saitoh, E. Observation of the inverse spin Hall effect in silicon. Nat Commun 3, 629 (2012).
2-15 Althammer, M. et al. Quantitative study of the spin Hall magnetoresistance in ferromagnetic insulator/normal metal hybrids. Physical Review B 87, 224401 (2013).
2-16 Chen, Y.-T. et al. Theory of spin Hall magnetoresistance. Physical Review B 87, 144411 (2013).
2-17 Liu, W. & Asheghi, M. Phonon-boundary scattering in ultrathin single-crystal silicon layers. Applied Physics Letters 84, 3819-3821, doi:10.1063/1.1741039 (2004).
2-18 Asheghi, M., Leung, Y. K., Wong, S. S. & Goodson, K. E. Phonon-boundary scattering in thin silicon layers. Applied Physics Letters 71, 1798-1800, doi:10.1063/1.119402 (1997).
2-19 Zou, J. & Balandin, A. Phonon heat conduction in a semiconductor nanowire. Journal of Applied Physics 89, 2932-2938, doi:10.1063/1.1345515 (2001).
2-20 Ju, Y. S. & Goodson, K. E. Phonon scattering in silicon films with thickness of order 100 nm. Applied Physics Letters 74, 3005-3007, doi:10.1063/1.123994 (1999).

02-21 Dash, S. P., Sharma, S., Patel, R. S., de Jong, M. P. & Jansen, R. Electrical creation of spin polarization in silicon at room temperature. Nature 462, 491-494, doi:http://www.nature.com/nature/journal/v462/n7272/suppinfo/nature08570_S1.html (2009).
2-22 Vlietstra, N. et al. Simultaneous detection of the spin-Hall magnetoresistance and the spin-Seebeck effect in platinum and tantalum on yttrium iron garnet. Physical Review B 90, 174436 (2014).
2-23 Schreier, M. et al. Current heating induced spin Seebeck effect. Applied Physics Letters 103, 242404, doi:doi:http://dx.doi.org/10.1063/1.4839395 (2013).
2-24 Fang, C. et al. Determination of spin relaxation times in heavy metals via 2nd harmonic spin injection magnetoresistance. arXiv preprint arXiv: 1705.03149 (2017).
2-25 Lu, L., Yi, W. & Zhang, D. L. 3 omega method for specific heat and thermal conductivity measurements. Review of Scientific Instruments 72, 2996-3003 (2001).
2-26 Dames, C. & Chen, G. 1 omega, 2 omega, and 3 omega methods for measurements of thermal properties. Rev. Sci. Instrum. 76, 124902-124914 (2005).
2-27 Dames, C. Measuring the thermal conductivity of thin films: 3 omega and related electrothermal methods. Annual Review of Heat Transfer 16 (2013).
2-28 Avery, A. D., Mason, S. J., Bassett, D., Wesenberg, D. & Zink, B. L. Thermal and electrical conductivity of approximately 100-nm permalloy, Ni, Co, Al, and Cu films and examination of the Wiedemann-Franz Law. Physical Review B 92, 214410 (2015).
2-29 Mott, N. The metal-insulator transition in extrinsic semiconductors. Advances in Physics 21, 785-823 (1972).
2-30 Mott, N. On metal-insulator transitions. Journal of Solid State Chemistry 88, 5-7, doi: http://dx.doi.org/10.1016/0022-1596(90)90201-8 (1990).
2-31 Mott, N., Pepper, M., Pollitt, S., Wallis, R. H. & Adkins, C. J. The Anderson Transition. Proceedings of the Royal Society of London. Series A, Mathematical and Physical Sciences 345, 169-205 (1975).
2-32 Sagasta, E. et al. Tuning the spin Hall effect of Pt from the moderately dirty to the superclean regime. Physical Review B 94, 060412 (2016).
2-33 Uchida, K. et al. Thermal spin pumping and magnon-phonon-mediated spin-Seebeck effect. Journal of Applied Physics 111, 103903, doi:10.1063/1.4716012 (2012).
3-1. Murakami S, Nagaosa N, Zhang S-C. Dissipationless Quantum Spin Current at Room Temperature. Science 2003, 301(5638): 1348-1351.
3-2. Qu D, Huang S Y, Hu J, Wu R, Chien C L. Intrinsic Spin Seebeck Effect in Au/YIG. Physical Review Letters 2013, 110(6): 067206.
3-3. Uchida K, Takahashi S, Harii K, Ieda J, Koshibae W, Ando K, et al. Observation of the spin Seebeck effect. Nature 2008, 455(7214): 778-781.
3-4. Uchida K, Xiao J, Adachi H, Ohe J, Takahashi S, Ieda J, et al. Spin Seebeck insulator. Nat Mater 2010, 9(11): 894-897.
3-5. Uchida K-i, Nonaka T, Ota T, Saitoh E. Longitudinal spin-Seebeck effect in sintered polycrystalline (Mn, Zn) Fe 2 O 4. Applied Physics Letters 2010, 97(26): 262504.
3-6. Dejene F K, Flipse J, Van Wees B J. Spin-dependent Seebeck coefficients of Ni 80 Fe 20 and Co in nanopillar spin valves. Physical Review B 2012, 86(2): 024436.
3-7. Huang S Y, Wang W G, Lee S F, Kwo J, Chien C L. Intrinsic Spin-Dependent Thermal Transport. Physical Review Letters 2011, 107(21): 216604.
3-8. Kikkawa T, Uchida K, Daimon S, Shiomi Y, Adachi H, Qiu Z. Separation of longitudinal spin Seebeck effect from anomalous Nernst effect: Determination of origin of transverse thermoelectric voltage in metal/insulator junctions. PHYSICAL REVIEW B 2013, 88(21): 214403.
3-9. Ramos R, Kikkawa T, Uchida K, Adachi H, Lucas I, Aguirre M H, et al. Observation of the spin Seebeck effect in epitaxial Fe3O4 thin films. Applied Physics Letters 2013, 102(7): 072413.
3-10. Schmid M, Srichandan S, Meier D, Kuschel T, Schmalhorst J M, Vogel M, et al. Transverse Spin Seebeck Effect versus Anomalous and Planar Nernst Effects in Permalloy Thin Films. Physical Review Letters 2013, 111(18): 187201.
3-11. Uchida K, Ishida M, Kikkawa T, Kirihara A, Murakami T, Saitoh E. Longitudinal spin Seebeck effect: from fundamentals to applications. Journal of Physics: Condensed Matter 2014, 26(34): 343202.
3-12. Boona S R, Myers R C, Heremans J P. Spin caloritronics. Energy & Environmental Science 2014, 7(3): 885-910.
3-13. Jaworski C M, Yang J, Mack S, Awschalom D D, Myers R C, Heremans J P. Spin-Seebeck Effect: A Phonon Driven Spin Distribution. Physical Review Letters 2011, 106(18): 186601.
3-14. Jaworski C M, Myers R C, Johnston-Halperin E, Heremans J P. Giant spin Seebeck effect in a non-magnetic material. Nature 2012, 487(7406): 210-213.
3-15. Jaworski C M, Yang J, Mack S, Awschalom D D, Heremans J P, Myers R C. Observation of the spin-Seebeck effect in a ferromagnetic semiconductor. Nat Mater 2010, 9(11): 898-903.
3-16. Chang P H, Mahfouzi F, Nagaosa N, Nikolic B K. Spin-Seebeck effect on the surface of a topological insulator due to nonequilibrium spin-polarization parallel to the direction of thermally driven electronic transport. Physical Review B 2014, 89(19): 195418.
3-17. Flipse J, Dejene F K, Wagenaar D, Bauer G E W, Youssef J B, Van Wees B J. Observation of the spin Peltier effect for magnetic insulators. Physical review letters 2014, 113(2): 027601.
3-18. Jin H, Boona S R, Yang Z, Myers R C, Heremans J P. Effect of the magnon dispersion on the longitudinal spin Seebeck effect in yttrium iron garnets. PHYSICAL REVIEW B 2015, 62(5): 054436.
3-19. Kehlberger A, Ritzmann U, Hinzke D, Guo E-J, Cramer J, Jakob G, et al. Length Scale of the Spin Seebeck Effect. Physical Review Letters 2015, 115(9): 096602.
3-20. Siegel, Gene, Prestgard, Megan Campbell, Teng S, Tiwari A. Robust longitudinal spin-Seebeck effect in Bi-YIG thin films. Scientific reports 2014, 4.
3-21. Sola A, Kuepferling M, Basso V, Pasquale M, Kikkawa T, Uchida K. Evaluation of thermal gradients in longitudinal spin Seebeck effect measurements. JOURNAL OF APPLIED PHYSICS 2015, 117(17): 17C510.
3-22. Weiler M, Althammer M, Czeschka F D, Huebl H, Wagner M S, Opel M. Local Charge and Spin Currents in Magnetothermal Landscapes. Physical review letters 2012, 108(10): 106602.
3-23. Bosu S, Sakuraba Y, Uchida K, Saito K, Ota T, Saitoh E, et al. Spin Seebeck effect in thin films of the Heusler compound Co2MnSi. Physical Review B 2011, 83(22): 224401.
3-24. Adachi H, Uchida K-i, Saitoh E, Ohe J-i, Takahashi S, Maekawa S. Gigantic enhancement of spin Seebeck effect by phonon drag. Applied Physics Letters 2010, 97(25): -.
3-25. Jiang Z, Chang C-Z, Masir M R, Tang C, Xu Y, Moodera J S, et al. Enhanced spin Seebeck effect signal due to spin-momentum locked topological surface states. Nat Commun 2016, 7: 11458
3-26. Tarasenko S A, Perel V I, Yassievich I N. In-Plane Electric Current Is Induced by Tunneling of Spin-Polarized Carriers. Physical Review Letters 2004, 93(5): 056601.
3-27. Brataas A, Hals K M D. Spin-orbit torques in action. Nat Nano 2014, 9(2): 86-88.
3-28. Fan Y, Upadhyaya P, Kou X, Lang M, Takei S, Wang Z, et al. Magnetization switching through giant spin-orbit torque in a magnetically doped topological insulator heterostructure. Nat Mater 2014, 13(7): 699-704.
3-29. Lau Y-C, Betto D, Rode K, Coey J M D, Stamenov P. Spin-orbit torque switching without an external field using interlayer exchange coupling. Nat Nano 2016, 11(9): 758-762.
3-30. Fukami S, Zhang C, DuttaGupta S, Kurenkov A, Ohno H. Magnetization switching by spin-orbit torque in an antiferromagnet-ferromagnet bilayer system. Nat Mater 2016, 15(5): 535-541.
3-31. Sola A, Bougiatioti P, Kuepferling M, Meier D, Reiss G, Pasquale M, et al. Longitudinal spin Seebeck coefficient: heat flux vs. temperature difference method. Scientific Reports 2017, 7.
3-32. Cahill DG. Thermal conductivity measurement from 30 to 750 K: the 3 omega method. Rev Sci Instrum 1990, 61(2): 802-808.
3-33. Hopkins PE, Phinney LM. Thermal Conductivity Measurements on Polycrystalline Silicon Microbridges Using the 3ω Technique. J Heat Transfer 2009, 131(4): 043201-043201-043208.
3-34. Liu W, Asheghi M. Thermal conduction in ultrathin pure and doped single-crystal silicon layers at high temperatures. J Appl Phys 2005, 98(12): 123523.
3-35. Avery A D, Mason S J, Bassett D, Wesenberg D, Zink B L. Thermal and electrical conductivity of approximately 100-nm permalloy, Ni, Co, Al, and Cu films and examination of the Wiedemann-Franz Law. Physical Review B 2015, 92(21): 214410.
3-36. Uchida K, Ota T, Adachi H, Xiao J, Nonaka T, Kajiwara Y, et al. Thermal spin pumping and magnon-phonon-mediated spin-Seebeck effect. Journal of Applied Physics 2012, 111(10): -.
4-1 M. Ishikawa, T. Oka, Y. Fujita, H. Sugiyama, Y. Saito, K. Hamaya, Spin relaxation through lateral spin transport in heavily doped n-type silicon, Physical Review B, 95 (2017) 115302.
4-2 R. Jansen, Silicon spintronics, Nat Mater, 11 (2012) 400-408.
4-3 S. P. Dash, S. Sharma, R. S. Patel, M. P. de Jong, R. Jansen, Electrical creation of spin polarization in silicon at room temperature, Nature, 462 (2009) 491-494.
4-4 S. Zhang, S. A. Dayeh, Y. Li, S. A. Crooker, D. L. Smith, S. T. Picraux, Electrical Spin Injection and Detection in Silicon Nanowires through Oxide Tunnel Barriers, Nano Letters, 13 (2013) 430-435.
4-5 L. Lu, W. Yi, D. L. Zhang, 3 omega method for specific heat and thermal conductivity measurements, Review of Scientific Instruments, 72 (2001) 2996-3003.
4-6 C. Dames, Measuring the thermal conductivity of thin films: 3 omega and related electrothermal methods, Annual Review of Heat Transfer, 16 (2013).
4-7 P.E. Hopkins, L. M. Phinney, Thermal Conductivity Measurements on Polycrystalline Silicon Microbridges Using the 3ω Technique, J. Heat Transfer, 131 (2009) 043201-043201-043208.
4-8 W. Liu, M. Asheghi, Thermal conduction in ultrathin pure and doped single-crystal silicon layers at high temperatures, J. Appl. Phys., 98 (2005) 123523.
4-9 P. C. Lou, S. Kumar, Spin mediated enhanced negative magnetoresistance in Ni80Fe20 and psilicon bilayer, Solid State Communications, 259 (2017) 24-28.
4-10 P. C. Lou, W. P. Beyermann, S. Kumar, Spin mediated magneto-electro-thermal transport behavior in Ni80Fe20/MgO/p-Si thin films, Journal of Applied Physics, 122 (2017) 123905.
4-11 M. Schreier, N. Roschewsky, E. Dobler, S. Meyer, H. Huebl, R. Gross, S. T. B. Goennenwein, Current heating induced spin Seebeck effect, Applied Physics Letters, 103 (2013) 242404.
4-12 C. O. Avci, K. Garello, A. Ghosh, M. Gabureac, S. F. Alvarado, P. Gambardella, Unidirectional spin Hall magnetoresistance in ferromagnet/normal metal bilayers, Nature Physics, 11 (2015) 570-575.
4-13 A.D. Avery, S. J. Mason, D. Bassett, D. Wesenberg, B. L. Zink, Thermal and electrical conductivity of approximately 100-nm permalloy, Ni, Co, Al, and Cu films and examination of the Wiedemann-Franz Law, Physical Review B, 92 (2015) 214410.
4-14 M. Asheghi, K. Kurabayashi, R. Kasnavi, K. E. Goodson, Thermal conduction in doped single-crystal silicon films, J. Appl. Phys., 91 (2002) 5079-5088.
4-15 S. Y. Dan'kov, A. M. Tishin, V. K. Pecharsky, K. A. Gschneidner, Magnetic phase transitions and the magnetothermal properties of gadolinium, Physical Review B, 57 (1998) 3478-3490.
4-16 J. L. Cohn, J. J. Neumeier, C. P. Popoviciu, K. J. McClellan, T. Leventouri, Local lattice distortions and thermal transport in perovskite manganites, Physical Review B, 56 (1997) R8495-R8498.
4-17 D. Chiba, S. Fukami, K. Shimamura, N. Ishiwata, K. Kobayashi, T. Ono, Electrical control of the ferromagnetic phase transition in cobalt at room temperature, Nat Mater, 10 (2011) 853-856.
4-18 S. M. Selbach, T. Tybell, M.-A. Einarsrud, T. Grande, The Ferroic Phase Transitions of BiFeO₃, Advanced Materials, 20 (2008) 3692-3696.
4-19 Y. Shi, Y. Guo, X. Wang, A. J. Princep, D. Khalyavin, P. Manuel, Y. Michiue, A. Sato, K. Tsuda, S. Yu, M. Arai, Y. Shirako, M. Akaogi, N. Wang, K. Yamaura, A. T. Boothroyd, A ferroelectric-like structural transition in a metal, Nat Mater, 12 (2013) 1024-1027.
4-20 A. M. Tishin, K. A. Gschneidner, V. K. Pecharsky, Magnetocaloric effect and heat capacity in the phase-transition region, Physical Review B, 59 (1999) 503-511.
4-21 C. Kittel, Introduction to solid state physics, Wiley, 2005.
4-22 M. Althammer, S. Meyer, H. Nakayama, M. Schreier, S. Altmannshofer, M. Weiler, H. Huebl, S. Geprags, M. Opel, R. Gross, D. Meier, C. Klewe, T. Kuschel, J.-M. Schmalhorst, G. Reiss, L. Shen, A. Gupta, Y.-T. Chen, G. E. W. Bauer, E. Saitoh, S. T. B. Goennenwein, Quantitative study of the spin Hall magnetoresistance in ferromagnetic insulator/normal metal hybrids, Physical Review B, 87 (2013) 224401.
4-23 J. Kim, P. Sheng, S. Takahashi, S. Mitani, M. Hayashi, Spin Hall Magnetoresistance in Metallic Bilayers, Physical Review Letters, 116 (2016) 097201.
4-24 Y.-T. Chen, S. Takahashi, H. Nakayama, M. Althammer, S. T. B. Goennenwein, E. Saitoh, G. E. W. Bauer, Theory of spin Hall magnetoresistance, Physical Review B, 87 (2013) 144411.
4-25 N. Vlietstra, J. Shan, B. J. van Wees, M. Isasa, F. Casanova, J. Ben Youssef, Simultaneous detection of the spin-Hall magnetoresistance and the spin-Seebeck effect in platinum and tantalum on yttrium iron garnet, Physical Review B, 90 (2014) 174436.
4-4-26 J. Sinova, S. O. Valenzuela, J. Wunderlich, C. H. Back, T. Jungwirth, Spin Hall effects, Reviews of Modern Physics, 87 (2015) 1213-1260.
4-27 C. López-Monis, A. Matos-Abiague, J. Fabian, Tunneling anisotropic thermopower and Seebeck effects in magnetic tunnel junctions, Physical Review B, 90 (2014) 174426.
4-28 X. Zhang, Q. Liu, J.-W. Luo, A. J. Freeman, A. Zunger, Hidden spin polarization in inversionsymmetric bulk crystals, Nat Phys, 10 (2014) 387-393.
D29 J. M. Riley, F. Mazzola, M. Dendzik, M. Michiardi, T. Takayama, L. Bawden, C. Granerod, M. Leandersson, T. Balasubramanian, M. Hoesch, T. K. Kim, H. Takagi, W. Meevasana, P. Hofmann, M. S. Bahramy, J. W. Wells, P. D. C. King, Direct observation of spin-polarized bulk bands in an inversion-symmetric semiconductor, Nat Phys, 10 (2014) 835-839.
4-30 A. Manchon, H. C. Koo, J. Nitta, S. M. Frolov, R. A. Duine, New perspectives for Rashba spinorbit coupling, Nat Mater, 14 (2015) 871-882.
4-31 E. Lesne, Y. Fu, S. Oyarzun, J. C. Rojas-Sanchez, D. C. Vaz, H. Naganuma, G. Sicoli, J.P. Attane, M. Jamet, E. Jacquet, J. M. George, A. Barthelemy, H. Jaffres, A. Fert, M. Bibes, L. Vila, Highly efficient and tunable spin-to-charge conversion through Rashba coupling at oxide interfaces, Nat Mater, advance online publication (2016).
4-32 T. Matsuyama, R. Kürsten, C. Meißner, U. Merkt, Rashba spin splitting in inversion layers on p-type bulk InAs, Physical Review B, 61 (2000) 15588-15591.
4-33 P. Schwab, R. Raimondi, Magnetoconductance of a two-dimensional metal in the presence of spin-orbit coupling, The European Physical Journal B—Condensed Matter and Complex Systems, 25 (2002) 483-495
4-34 V. T. Dolgopolov, A. A. Shashkin, S. V. Kravchenko, Spin polarization and exchange correlation effects in transport properties of two-dimensional electron systems in silicon, Physical Review B, 96 (2017) 075307.
4-35 J. M. Broto, M. Goiran, H. Rakoto, A. Gold, V. T. Dolgopolov, Magnetoresistance of a Si-MOSFET structure in a parallel magnetic field, Physica B: Condensed Matter, 346 (2004) 493-497.
4-36 T. Okamoto, M. Ooya, K. Hosoya, S. Kawaji, Spin polarization and metallic behavior in a silicon two-dimensional electron system, Physical Review B, 69 (2004) 041202.
5-1 K. Uchida, S. Takahashi, K. Harii, J. Ieda, W. Koshibae, K. Ando, S. Maekawa, E. Saitoh, Nature 2008, 455, 778.
5-2 A. Kirihara, K.-i. Uchida, Y. Kajiwara, M. Ishida, Y. Nakamura, T. Manako, E. Saitoh, S. Yorozu, Nat Mater 2012, 11, 686.
5-3 S. R. Boona, R. C. Myers, J. P. Heremans, Energy & Environmental Science 2014, 7, 885.
5-4 A. B. Cahaya, O. A. Tretiakov, G. E. W. Bauer, Appl. Phys. Lett. 2014, 104, 042402.
5-5 A. B. Cahaya, O. A. Tretiakov, G. E. W. Bauer, IEEE Trans. Ma . 2015, 51, 1.
5-6 Q. Zhiyong, H. Dazhi, K. Takashi, U. Ken-ichi, S. Eiji, Applied Physics Express 2015, 8, 083001.
5-7 S. M. Wu, W. Zhang, A. KC, P. Borisov, J. E. Pearson, J. S. Jiang, D. Lederman, Phys. Rev. Lett. 2016, 116, 097204.
5-8 P. Sheng, Y. Sakuraba, Y.-C. Lau, S. Takahashi, S. Mitani, M. Hayashi, Science Advances 2017, 3.
5-9 K. Uchida, J. Xiao, H. Adachi, J. Ohe, S. Takahashi, J. Ieda, T. Ota, Y. Kajiwara, H. Umezawa, H. Kawai, G. E. W. Bauer, S. Maekawa, E. Saitoh, Nat Mater 2010, 9, 894.
5-10 H. Adachi, K.-i. Uchida, E. Saitoh, J.-i. Ohe, S. Takahashi, S. Maekawa, Appl. Phys. Lett. 2010, 97.
5-11 J. Xiao, G. E. W. Bauer, K.-c. Uchida, E. Saitoh, S. Maekawa, Phys. Rev. B 2010, 81, 214418.
5-12 K. Uchida, T. Ota, H. Adachi, J. Xiao, T. Nonaka, Y. Kajiwara, G. E. W. Bauer, S. Maekawa, E. Saitoh, J Appl. Phys. 2012, 111, 103903.
5-13 R. Ramos, T. Kikkawa, K. Uchida, H. Adachi, I. Lucas, M. H. Aguirre, P. Algarabel, L. Morellon, S. Maekawa, E. Saitoh, M. R. Ibarra, Appl. Phys. Lett. 2013, 102, 072413.
5-14 L. Wang, R. J. H. Wesselink, Y. Liu, Z. Yuan, K. Xia, P. J. Kelly, Phys. Rev. Lett. 2016, 116, 196602.
5-15 D. Qu, S. Y. Huang, G. Y. Guo, C. L. Chien, Phys. Rev. B 2018, 97, 024402.
5-16 L. Liu, C.-F. Pai, Y. Li, H. W. Tseng, D. C. Ralph, R. A. Buhrman, Science (New York, N.Y) 2012, 336, 555.
5-17 Q. Hao, W. Chen, G. Xiao, Appl. Phys. Lett. 2015, 106, 182403.
5-18 R. G. Bhardwaj, P. C. Lou, S. Kumar, Appl. Phys. Lett. 2018, 112, 042404.
5-19 P. C. Lou, S. Kumar, physica status solidi (b) 2017, DOI: 10.1002/pssb.2017005451700545.
5-20 P. C. Lou, S. Kumar, Solid State Commun. 2017, 259, 24.
5-21 P. C. Lou, W. P. Beyermann, S. Kumar, J. Appl. Phys. 2017, 122, 123905.
5-22 P. C. Lou, S. Kumar, Journal of Magnetism and Magnetic Materials 2018, 452, 129.
5-23 M. Weiler, M. Althammer, F. D. Czeschka, H. Huebl, M. S. Wagner, M. Opel, Phys. Rev. Lett. 2012, 108, 106602.
5-24 K. Uchida, M. Ishida, T. Kikkawa, A. Kirihara, T. Murakami, E. Saitoh, Journal of Physics: Condensed Matter 2014, 26, 343202.
5-25 A. Sola, M. Kuepferling, V. Basso, M. Pasquale, T. Kikkawa, K. Uchida, J. Appl. Phys. 2015, 117, 17C510.
5-26 K.-i. Uchida, T. Nonaka, T. Ota, E. Saitoh, Appl. Phys. Lett. 2010, 97, 262504.
5-27 A. Sola, P. Bougiatioti, M. Kuepferling, D. Meier, G. Reiss, M. Pasquale, T. Kuschel, V. Basso, Scientific Reports 2017, 7.
5-28 D. G. Cahill, Rev. Sci. Instrum. 1990, 61, 802.
5-29 P. E. Hopkins, L. M. Phinney, J. Heat Transfer 2009, 131, 043201.
5-30 W. Liu, M. Asheghi, J. Appl. Phys. 2005, 98, 123523.
5-31 A. D. Avery, S. J. Mason, D. Bassett, D. Wesenberg, B. L. Zink, Phys. Rev. B 2015, 92, 214410.
5-32 D. Qu, S. Y. Huang, B. F. Miao, S. X. Huang, C. L. Chien, Phys. Rev. B 2014, 89, 140407.
5-33 Z. Jiang, C.-Z. Chang, M. R. Masir, C. Tang, Y. Xu, J. S. Moodera, A. H. MacDonald, J. Shi, Nat Commun 2016, 7, 11458.
5-34 R. Ramos, A. Anadón, I. Lucas, K. Uchida, P. A. Algarabel, L. Morellén, M. H. Aguirre, E. Saitoh, M. R. Ibarra, APL Materials 2016, 4, 104802.
5-35 R. Ramos, T. Kikkawa, A. Anadón, I. Lucas, K. Uchida, P. A. Algarabel, L. Morellón, M. H. Aguirre, E. Saitoh, M. R. Ibarra, AIP Advances 2017, 7, 055915.
5-36 S. M. Rezende, R. L. Rodríguez-Suárez, R. O. Cunha, A. R. Rodrigues, F. L. A. Machado, G. A. Fonseca Guerra, J. C. Lopez Ortiz, A. Azevedo, Phys. Rev. B 2014, 89, 014416.
5-37 D. Meier, T. Kuschel, L. Shen, A. Gupta, T. Kikkawa, K. Uchida, E. Saitoh, J. M. Schmalhorst, G. Reiss, Phys. Rev. B 2013, 87, 054421.
6-1 A. Manchon, H. C. Koo, J. Nitta, S. M. Frolov, R. A. Duine, New perspectives for Rashba spin-orbit coupling. Nat Mater 14, 871-882 (2015).
6-2 A. Soumyanarayanan, N. Reyren, A. Fert, C. Panagopoulos, Emergent phenomena induced by spin-orbit coupling at surfaces and interfaces. Nature 539, 509-517 (2016).
6-3 J. Sinova et al., Universal Intrinsic Spin Hall Effect. Phys. Rev. Lett. 92, 126603 (2004).
6-4 C. Liu, T. L. Hughes, X.-L. Qi, K. Wang, S.-C. Zhang, Quantum Spin Hall Effect in Inverted Type-II Semiconductors. Phys. Rev. Lett. 100, 236601 (2008).
6-5 S. Nakosai, Y. Tanaka, N. Nagaosa, Topological Superconductivity in Bilayer Rashba System.Phys. Rev. Lett. 108, 147003 (2012).
6-6 L. P. Gor'kov, E. I. Rashba, Superconducting 2D System with Lifted Spin Degeneracy: Mixed Singlet-Triplet State. Phys. Rev. Lett. 87, 037004 (2001).
6-7 E. Cappelluti, C. Grimaldi, F. Marsiglio, Topological Change of the Fermi Surface in Low-Density Rashba Gases: Application to Superconductivity. Phys. Rev. Lett. 98, 167002 (2007).
6-8 D. F. Agterberg, R. P. Kaur, Magnetic-field-induced helical and stripe phases in Rashba superconductors. Phys. Rev. B 75, 064511 (2007).
6-9 E. Lesne et al., Highly efficient and tunable spin-to-charge conversion through Rashba coupling at oxide interfaces. Nature Materials 15, 1261 (2016).
6-10 K. Fujiwara et al., 5d iridium oxide as a material for spin-current detection. Nature Communications 4, 2893 (2013).
6-11 M. S. Bahramy, N. Ogawa, Bulk Rashba Semiconductors and Related Quantum Phenomena. Advanced Materials 29, (2017).
6-12 H. Murakawa et al., Detection of Berry's Phase in a Bulk Rashba Semiconductor. Science 342, 1490 (2013).
6-13 K. Ishizaka et al., Giant Rashba-type spin splitting in bulk BiTeI. Nature Materials 10, 521 (2011).
6-14 I. Gierz et al., Silicon Surface with Giant Spin Splitting. Phys. Rev. Lett. 103, 046803 (2009).
6-15 S. Y. Matsushita et al., Anisotropic electronic band structure of intrinsic Si(110) studied by angle-resolved photoemission spectroscopy and first-principles calculations. Phys. Rev. B 96, 125302 (2017).
6-16 P. Schwab, R. Raimondi, Magnetoconductance of a two-dimensional metal in the presence of spin-orbit coupling. The European Physical Journal B—Condensed Matter and Complex Systems 25, 483-495 (2002).
6-17 V. T. Dolgopolov, A. A. Shashkin, S. V. Kravchenko, Spin polarization and exchange-correlation effects in transport properties of two-dimensional electron systems in silicon. Phys. Rev. B 96, 075307 (2017).
6-18 J. M. Broto, M. Goiran, H. Rakoto, A. Gold, V. T. Dolgopolov, Magnetoresistance of a Si-MOSFET structure in a parallel magnetic field. Physica B: Condensed Matter 346, 493-497 (2004).
6-19 T. Okamoto, M. Ooya, K. Hosoya, S. Kawaji, Spin polarization and metallic behavior in a silicon two-dimensional electron system. Phys. Rev. B 69, 041202 (2004).
6-20 K. Ono et al., Hole Spin Resonance and Spin-Orbit Coupling in a Silicon Metal-Oxide-Semiconductor Field-Effect Transistor. Phys. Rev. Lett. 119, 156802 (2017).
6-21 K. Ando, E. Saitoh, Observation of the inverse spin Hall effect in silicon. Nat Commun 3, 629 (2012).
6-22 Y. Lv et al., Unidirectional spin-Hall and Rashba-Edelstein magnetoresistance in topological insulator-ferromagnet layer heterostructures. Nature Communications 9, 111 (2018).
6-23 H. Nakayama et al., Rashba-Edelstein Magnetoresistance in Metallic Heterostructures. Phys. Rev. Lett. 117, 116602 (2016).
6-24 R. Winkler, Spin-orbit coupling effects in two-dimensional electron and hole systems. (2003).
6-25 R. Moriya et al., Cubic Rashba Spin-Orbit Interaction of a Two-Dimensional Hole Gas in a Strained-Ge/SiGe Quantum Well. Phys. Rev. Lett. 113, 086601 (2014).
6-26 O. Bleibaum, S. Wachsmuth, Spin Hall effect in semiconductor heterostructures with cubic Rashba spin-orbit interaction. Phys. Rev. B 74, 195330 (2006).
6-27 H. Nakamura, T. Koga, T. Kimura, Experimental Evidence of Cubic Rashba Effect in an Inversion-Symmetric Oxide. Physical Review Letters 108, 206601 (2012).
6-28 B. A. Bernevig, S.-C. Zhang, Quantum Spin Hall Effect. Phys. Rev. Lett. 96, 106802 (2006).
6-29 R. M. Jock et al., A silicon metal-oxide-semiconductor electron spin-orbit qubit. Nature Communications 9, 1768 (2018).
6-30 G. Sun, Y. Sun, T. Nishida, S. E. Thompson, Hole mobility in silicon inversion layers: Stress and surface orientation. J. Appl. Phys. 102, 084501 (2007).
6-31 Y. Sun, S. E. Thompson, T. Nishida, Physics of strain effects in semiconductors and metal-oxide-semiconductor field-effect transistors. J. Appl. Phys. 101, 104503 (2007).
6-32 R. G. Bhardwaj, P. C. Lou, S. Kumar, Spin Seebeck effect and thermal spin galvanic effect in Ni80Fe20/p-Si bilayers. Appl. Phys. Lett. 112, 042404 (2018).
6-33 R. G. Bhardwaj, P. C. Lou, S. Kumar, Giant Enhancement in Rashba Spin-Seebeck Effect in NiFe/p-Si Thin Films. physica status solidi (RRL)—Rapid Research Letters 0.
6-34 L. Lu, W. Yi, D. L. Zhang, 3 omega method for specific heat and thermal conductivity measurements. Rev. Sci. Instrum. 72, 2996-3003 (2001).
6-35 P. C. Lou, S. Kumar, Spin-Driven Emergent Antiferromagnetism and Metal-Insulator Transition in Nanoscale p-Si. physica status solidi (b), 1700545 (2017).
6-36 P. C. Lou, W. P. Beyermann, S. Kumar, Spin mediated magneto-electro-thermal transport behavior in Ni80Fe20/MgO/p-Si thin films. J. Appl. Phys. 122, 123905 (2017).
6-37 P. C. Lou, S. Kumar, Spin-Hall effect and emergent antiferromagnetic phase transition in n-Si. Journal of Magnetism and Magnetic Materials 452, 129-133 (2018).
6-38 S. Y. Dan'kov, A. M. Tishin, V. K. Pecharsky, K. A. Gschneidner, Magnetic phase transitions and the magnetothermal properties of gadolinium. Physical Review B 57, 3478-3490 (1998).
6-39 J. L. Cohn, J. J. Neumeier, C. P. Popoviciu, K. J. McClellan, T. Leventouri, Local lattice distortions and thermal transport in perovskite manganites. Physical Review B 56, R8495-R8498 (1997).
6-40 D. Chiba et al., Electrical control of the ferromagnetic phase transition in cobalt at room temperature. Nat Mater 10, 853-856 (2011).
6-41 S. M. Selbach, T. Tybell, M.-A. Einarsrud, T. Grande, The Ferroic Phase Transitions of BiFeO3. Advanced Materials 20, 3692-3696 (2008).
6-42 Y. Shi et al., A ferroelectric-like structural transition in a metal. Nat Mater 12, 1024-1027 (2013).
6-43 A. M. Tishin, K. A. Gschneidner, V. K. Pecharsky, Magnetocaloric effect and heat capacity in the phase-transition region. Physical Review B 59, 503-511 (1999).
6-44 C. Kittel, Introduction to solid state physics. (Wiley, 2005).
6-45 F. Magnus et al., Long-range magnetic interactions and proximity effects in an amorphous exchange-spring magnet. Nature Communications 7, ncomms11931 (2016).
6-46 M. Althammer, et al., “Quantitative study of the spin Hall magnetoresistance in ferromagnetic insulator/normal metal hybrids,” Physical Review B, 2013. 87(22): p. 224401.

1. A device, comprising:
a doped silicon layer; and
a magnesium oxide (MgO) layer positioned upon the doped silicon layer; and
wherein a strain gradient is present in the doped silicon layer in a thickness direction such that a structural inversion asymmetry is present within a portion of the doped silicon layer adjacent to the MgO/doped silicon interface.

2. The device of claim 1, wherein a thickness of the MgO layer relative to the doped silicon layer is configured to induce at least a portion of the strain gradient within the doped silicon layer.

3. The device of claim 1, wherein the doped silicon layer is n-type silicon.

4. The device of claim 1, wherein the doped silicon layer is p-type silicon.

5. The device of claim 1, wherein the doped silicon layer has a thickness selected from 2 nm to 3 μm.

6. The device of claim 1, wherein the MgO layer has a non-zero thickness less than 2 nm.

7. The device of claim 1, wherein a portion of the doped silicon layer and the magnesium oxide layer is freestanding.

8. A device, comprising:
a doped silicon layer;
a magnesium oxide (MgO) layer positioned upon the doped silicon layer;
a Ni₈₀₊ₓFe₂₀₋ₓ layer positioned upon the MgO layer, wherein x is 0 or 1; and
wherein a strain gradient is present in the doped silicon layer in a thickness direction such that a structural inversion asymmetry is present within the portion of the doped silicon layer adjacent to the MgO/doped silicon interface.

9. The device of claim 8, further comprising a heating layer overlying the Ni₈₀₊ₓFe₂₀₋ₓ layer.

10. The device of claim 8, further including a temperature gradient extending through the thickness of the doped silicon layer, the temperature gradient being configured to induce at least a portion of the strain gradient within the doped silicon layer.

11. The device of claim 8, wherein a thickness of the MgO layer relative to the doped silicon layer is configured to induce at least a portion of the strain gradient within the doped silicon layer.

12. The device of claim 8, wherein doped silicon layer is configured to undergo a second order phase transformation at a temperature between 200 K and 400 K.

13. The device of claim 12, wherein the second order phase transformation is a metal insulator transition.

14. The device of claim 8, wherein the doped silicon layer is n-type silicon.

15. The device of claim 8, wherein the doped silicon layer is p-type silicon.

16. The device of claim 8, wherein a portion of the doped silicon layer and the magnesium oxide layer is freestanding.

17. A device, comprising:
a doped polysilicon layer;
a layer of NiFe or Ni₈₀Fe₂₀ positioned upon the doped polysilicon layer; and
an insulating layer positioned upon the NiFe or the Ni₈₀Fe₂₀ layer;
wherein a strain gradient is present in the doped polysilicon layer in a thickness direction such that a structural inversion asymmetry is present within the portion of the doped polysilicon layer adjacent to the NiFe/p-Si interface or Ni₈₀Fe₂₀/p-Si interface.

18. The device of claim 17, further comprising a heating layer overlying the MgO layer .

19. The device of claim 17, further including a temperature gradient extending through the thickness of the doped polysilicon layer, the temperature gradient being configured to induce at least a portion of the strain gradient within the doped polysilicon layer.

20. The device of claim 17, wherein the doped polysilicon layer is p-type.
